(19) United States
(12) Patent Application Publication
(10) Pub. No.: US 2025/0234077 A1
(43) Pub. Date: Jul. 17, 2025

(54) CAMERA DEVICE AND OPTICAL DEVICE

(71) Applicant: LG INNOTEK CO., LTD., Seoul (KR)

(72) Inventors: Sang Ok PARK, Seoul (KR); Deok Yong LEE, Seoul (KR); Sung Il LEE, Seoul (KR)

(21) Appl. No.: 18/703,069

(22) PCT Filed: Oct. 18, 2022
(86) PCT No.: PCT/KR2022/015811

§ 371 Date: Apr. 19, 2024

(30) Foreign Application Priority Data
Oct. 19, 2021 (KR) 10-2021-0139529
Oct. 28, 2021 (KR) 10-2021-0145457

(51) Int. Cl. H04N 23/52; G03B 13/36; H04N 23/68

(52) U.S. Cl. CPC H04N 23/52; H04N 23/6812; H04N 23/685; G03B 13/36

(57) ABSTRACT

An embodiment comprises: a cover member; a moving unit which is arranged on the inside of the cover member, and which includes a first substrate and an image sensor arranged in the first substrate; a fixing unit including a second substrate spaced from the first substrate; a support substrate for supporting the moving unit so that the moving unit moves in the direction vertical to an optical axis direction with respect to the fixing unit, and electrically connecting the first substrate and the second substrate; and a control unit arranged in the second substrate and on the outside of the cover member.

### CROSS-REFERENCE TO RELATED APPLICATIONS

This application is the U.S. national stage application of International Patent Application No. PCT/KR2022/015811, filed Oct. 18, 2022, which claims the benefit under 35 U.S.C. § 119 of Korean Application Nos. 10-2021-0139529, filed Oct. 19, 2021; and 10-2021-0145457, filed Oct. 28, 2021, the disclosures of each of which are incorporated herein by reference in their entirety.

### TECHNICAL FIELD

Embodiments relate to a camera device and an optical instrument including the same.

### BACKGROUND ART

Voice coil motor (VCM) technology, which is used in conventional general camera devices, is difficult to apply to a micro-scale camera device, which is intended to exhibit low power consumption, and study related thereto has been actively conducted.

There is increasing demand for, and production of, electronic products such as smartphones and cellular phones equipped with cameras. Cameras for cellular phones have been increasing in resolution and decreasing in size, and accordingly, actuators therefor are also becoming smaller, larger in diameter, and more multifunctional. In order to realize a high-resolution cellular phone camera, improvement in the performance of the cellular phone camera and additional functions, such as autofocus, shutter shaking prevention, and zooming in and out, are required.

### DISCLOSURE

### Technical Problem

Embodiments provide a camera device capable of inhibiting deterioration in quality of an image of an image sensor, which is caused by heat generated from a heat source, and an optical instrument including the same.

In addition, embodiments provide a camera device capable of inhibiting deterioration in performance of insulating and protecting terminals of a terminal unit and improving soldering efficiency and conductive connection characteristics and an optical instrument including the same.

### Technical Solution

A camera device according to an embodiment includes a cover member, a moving unit disposed inside the cover member and including a first board and an image sensor disposed on the first board, a fixed unit including a second board spaced apart from the first board, a support board configured to support the moving unit so that the moving unit moves relative to the fixed unit in a direction perpendicular to an optical-axis direction and to conductively connect the first board to the second board, and a controller disposed outside the cover member. The controller may be disposed on the second board.

The controller may not overlap the cover member in the optical-axis direction.

The second board may include an extension region not overlapping the cover member in the optical-axis direction, and the controller may be disposed on the extension region.

The second board may include a first region corresponding to the cover member in the optical-axis direction, a second region on which a connector is disposed, a third region connecting the first region to the second region, and an extension region extending from the first region, and the controller may be disposed on an upper surface of the extension region.

The extension region may extend from a first side portion of the first region, and the third region may connect the first side portion of the first region to the second region.

The extension region may extend from a first side portion of the first region, and the third region may extend from the first side portion of the first region and may be spaced apart from the extension region.

The camera device may include a cover disposed on the extension region to accommodate the controller. The camera device may include a heat dissipation member provided in contact with the extension region.

The heat dissipation member may be disposed on a lower surface of the extension region.

The camera device may include a heat dissipation layer disposed on at least one of an upper surface or a side surface of the controller. The heat dissipation layer may be formed of heat dissipation epoxy.

The camera device may include a coil conductively connected to the first board and a position sensor disposed on the first board and configured to detect movement or displacement of the moving unit, and the controller may be conductively connected to the coil and the position sensor.

The camera device may include a magnet disposed on the fixed unit so as to oppose the coil and configured to move the moving unit in a direction perpendicular to the optical-axis direction through interaction with the coil.

The second board may include a first terminal, a second terminal, a first wire conductively connecting the first terminal to the controller, and a second wire conductively connecting the second terminal to the control, and the support board may include a third terminal conductively connected to the first terminal and a fourth terminal conductively connected to the second terminal.

The second board may include a third wire conductively connecting the third terminal to the coil and a fourth wire conductively connecting the fourth terminal to the position sensor.

The line width of the first wire may be greater than the line width of the second wire. The line width of the third wire may be greater than the line width of the fourth wire.

The second board may include a first region corresponding to the cover member in the optical-axis direction, a second region in which a connector is disposed, and a third region connecting the first region to the second region, and the controller may be disposed in the second region.

A camera device according to another embodiment includes a moving unit including a first board and an image sensor disposed on the first board, a fixed unit including a second board spaced apart from the first board and including a first terminal, and a support board configured to support the moving unit so that the moving unit moves relative to the fixed unit in a direction perpendicular to an optical-axis direction and to conductively connect the first board to the second board, wherein the support board includes a terminal unit, the terminal unit includes a first insulating layer, a second terminal disposed on the first insulating layer, a second insulating layer spaced apart from the second terminal and disposed on the first insulating layer, and a third insulating layer disposed on the first insulating layer and configured to expose at least a portion of the second terminal, and the third insulating layer includes solder resist.

The third insulating layer may be photo solder resist (PSR) or dry-film-type solder resist (DFSR). The second insulating layer may be coverlay. The coverlay may include a lens and an adhesive.

The support board may include a body connected to the first board and an extension portion extending from the body and configured to move when the moving unit moves, the extension portion may include a portion extending toward the second board, and the terminal unit may be disposed on the extension portion.

The terminal unit may include a first area in which the second terminal is formed and located adjacent to the second board and a second area connecting the first area to the body, the second insulating layer may be disposed in the second area, and the third insulating layer may be disposed in the first area.

A portion of the third insulating layer may be disposed on the second insulating layer. In addition, a portion of the third insulating layer may be disposed on the second terminal. The third insulating layer may include a first overlapping area overlapping the second insulating layer in a direction perpendicular to the third insulating layer. A portion of the third insulating layer may be disposed on a portion of the second insulating layer adjacent to a boundary between the first area and the second area.

The second terminal may include a plurality of second terminals, and the third insulating layer may include a portion disposed on an area between the plurality of second terminals.

The third insulating layer may include a second overlapping area overlapping the second terminal in a direction perpendicular to the third insulating layer, and the second overlapping area may have a predetermined line width from an edge of the second terminal.

The length of the third insulating layer in a vertical direction may be greater than the length of the second terminal in the vertical direction, and the vertical direction may be a direction from one end of the terminal unit on which the second terminal is disposed toward the other end of the terminal unit connected to the body.

The value obtained by dividing the length of the third insulating layer in a vertical direction by the length of the second terminal in the vertical direction may be greater than 1 and less than or equal to 2.16, and the vertical direction may be a direction from one end of the terminal unit on which the second terminal is disposed toward the other end of the terminal unit connected to the body.

The third insulating layer may include a first overlapping area overlapping the second insulating layer in a direction perpendicular to the third insulating layer and a second overlapping area overlapping the second terminal in a direction perpendicular to the third insulating layer, the line width of the second overlapping area may be less than or equal to the length of the first overlapping area in a vertical direction, and the vertical direction may be a direction from one end of the terminal unit on which the second terminal is disposed toward the other end of the terminal unit connected to the body.

The camera device may include a solder coupling the first terminal to the second terminal.

### Advantageous Effects

According to embodiments, since a controller, which is a heat source, is disposed outside a cover member and a base, heat generated from the controller may be easily dissipated, and deterioration in quality of images of an image sensor due to increase in temperature may be inhibited.

According to embodiments, since a cover can surrounding the controller is provided, heat from the controller may be blocked, increase in the temperature of the image sensor may be inhibited, and accordingly, deterioration in performance of the image sensor may be inhibited.

According to embodiments, since a heat dissipation layer is disposed on the surface of the controller, heat dissipation efficiency of the controller may be improved, increase in the temperature of the image sensor may be inhibited, and accordingly, deterioration in performance of the image sensor may be inhibited.

According to embodiments, since a heat dissipation member is disposed on a lower surface of a board unit on which the controller is disposed, heat dissipation efficiency of the controller may be improved, increase in the temperature of the image sensor may be inhibited, and accordingly, deterioration in performance of the image sensor may be inhibited.

According to embodiments, since solder resist is formed instead of coverlay on a portion or the entirety of a terminal unit of a support board, eccentricity due to mismatch between a terminal and a bore may be inhibited, and deterioration in insulation and protection performance caused by the eccentricity may be inhibited.

In addition, according to embodiments, misalignment between positions for soldering between the terminal of the support board and a terminal of a second board unit may be inhibited, and thus soldering efficiency and conductive connection characteristics may be improved.

In addition, according to embodiments, since a bore in a third insulating layer that matches the terminal of the terminal unit is formed through exposure, development, and etching, it is possible to inhibit reduction in the soldering area of the terminal due to leakage of resin of coverlay, thereby improving soldering efficiency and conductive connection characteristics.

### DESCRIPTION OF DRAWINGS

FIG. 1 is a perspective view of a camera device according to an embodiment.

FIG. 2 is a perspective view of the camera device with a cover member removed therefrom.

FIG. 3 is an exploded perspective view of the camera device in FIG. 1.

FIG. 4A is a cross-sectional view taken along line AB in the camera device in FIG. 1.

FIG. 4B is a cross-sectional view taken along line CD in the camera device in FIG. 1.

FIG. 4C is a cross-sectional view taken along line EF in the camera device in FIG. 1.

FIG. 5 is an exploded perspective view of an AF driving unit in FIG. 3.

FIG. 6 is a perspective view of a bobbin, a sensing magnet, a balancing magnet, a first coil, a circuit board, a first position sensor, and a capacitor.

FIG. 7A is a perspective view of the bobbin, a housing, the circuit board, an upper elastic member, the sensing magnet, and the balancing magnet.

FIG. 7B is a perspective view of the configuration shown in FIG. 7A with a wire added thereto.

FIG. 8 is a bottom perspective view of the housing, the bobbin, a lower elastic member, a magnet, and the circuit board.

FIG. 9 is a perspective view of an image sensor unit.

FIG. 10A is a first exploded perspective view of the image sensor unit in FIG. 9.

FIG. 10B is a second exploded perspective view of the image sensor unit in FIG. 9.

FIG. 10C is an enlarged view of a groove in a holder in FIG. 10A.

FIG. 10D is an enlarged view of a terminal unit in FIG. 10A.

FIG. 10E is an enlarged view of a recess in a base in FIG. 10A.

FIG. 10F is an enlarged view of a recess in the holder, in which the terminal unit in FIG. 10B is disposed.

FIG. 11 is a bottom perspective view of the holder, the terminal unit, a first board unit, a support board, the base, and a second board unit in FIG. 10A.

FIG. 12 is a plan view of the holder, the first board unit, the image sensor, a second coil, and an OIS position sensor.

FIG. 13 is a rear perspective view of the holder and the first board unit.

FIG. 14 is a perspective view of the base, the terminal unit, and the wire.

FIG. 15 is a bottom view of the first board unit, the support board, and a first heat dissipation member.

FIG. 16 is a perspective view of the first board unit, the support board, and the first heat dissipation member.

FIG. 17A is a first perspective view of the support board coupled to the holder and to the base.

FIG. 17B is a second perspective view of the support board coupled to the holder and to the base.

FIG. 18A is a view for explaining movement of an OIS moving unit in an X-axis direction.

FIG. 18B is a view for explaining movement of the OIS moving unit in a y-axis direction.

FIG. 18C is a view for explaining rotation of the OIS moving unit in the clockwise direction in a four-channel drive mode.

FIG. 18D is a view for explaining rotation of the OIS moving unit in the counterclockwise direction in the four-channel drive mode.

FIG. 19A shows an embodiment of the magnet in FIG. 5.

FIG. 19B shows another embodiment of the magnet in FIG. 5.

FIG. 20A is a view showing an embodiment of placement of first to third regions of the second board unit, an extension region, an AF moving unit, an OIS moving unit, and a controller.

FIG. 20B is a schematic cross-sectional view of the lens module, the first board unit, the image sensor, the first heat dissipation member, the second board unit, and the second heat dissipation member in FIG. 10A.

FIG. 21 is a block diagram showing the configuration of the controller and first to third sensors 240A to 240C.

FIG. 22A shows a plurality of terminals of the second board unit conductively connected to the controller.

FIG. 22B shows an embodiment of wires of the second board unit conductively connecting the controller to the plurality of terminals of the second board unit.

FIG. 22C is a schematic conceptual diagram of a first wire and a second wire of the second board unit.

FIG. 22D shows placement of wires connected to terminals of the support board.

FIG. 23 shows a modified example of placement of the controller in FIG. 20A.

FIG. 24 shows another modified example of placement of the controller in FIG. 20A.

FIG. 25A is an exploded perspective view of a camera device according to another embodiment.

FIG. 25B is a coupled perspective view of the camera device in FIG. 25A.

FIG. 26A is a perspective view of the first board unit, the support board, and the second board unit.

FIG. 26B is an enlarged view of terminals 311 of the support board and terminals of the second board unit.

FIG. 26C shows solders coupling the terminals of the support board to the terminals of the second board unit.

FIG. 27 is a schematic cross-sectional view taken along line AB in a first circuit board and the support board shown in FIG. 26A.

FIG. 28 is a front view of terminal units of the support board.

FIGS. 29A to 29C show a method of forming the terminal unit of the support board.

FIG. 30A is a cross-sectional view taken along line AB in FIG. 29A.

FIG. 30B is a cross-sectional view taken along line CD in FIG. 29B.

FIG. 30C is a cross-sectional view taken along line EF in FIG. 29C before formation of a bore.

FIG. 30D is a cross-sectional view taken along line EF in FIG. 29C after formation of the bore.

FIG. 30E is a cross-sectional view taken along line GH in FIG. 29C.

FIG. 30F shows a modified example of FIG. 30E.

FIGS. 31A and 31B show a case in which a coverlay sheet is normally attached and a case in which eccentricity occurs.

FIG. 32 shows a modified example of FIG. 29C.

FIG. 33 shows a support board according to still another modified example of FIG. 29C.

FIG. 34 shows terminal units according to another embodiment.

FIG. 35A is a perspective view of an optical instrument according to an embodiment.

FIG. 35B is a perspective view of an optical instrument according to another embodiment.

FIG. 35C is a perspective view of an optical instrument according to still another embodiment.

FIG. 36 is a configuration diagram of the optical instruments shown in FIGS. 35A to 35C.

### BEST MODE

Hereinafter, embodiments of the present disclosure will be described in detail with reference to the accompanying drawings.

The technical spirit of the disclosure is not limited to the embodiments to be described, and may be implemented in various other forms, and one or more of the components may be selectively combined and substituted for use without exceeding the scope of the technical spirit of the disclosure.

In addition, terms (including technical and scientific terms) used in the embodiments of the disclosure, unless specifically defined and described explicitly, are to be interpreted as having meanings that may be generally understood by those having ordinary skill in the art to which the disclosure pertains, and meanings of terms that are commonly used, such as terms defined in a dictionary, should be interpreted in consideration of the context of the relevant technology.

Further, the terms used in the embodiments of the disclosure are for explaining the embodiments and are not intended to limit the disclosure. In this specification, the singular forms may also include plural forms unless otherwise specifically stated in a phrase, and in the case in which “at least one (or one or more) of A, B, or C” is stated, it may include one or more of all possible combinations of A, B, and C.

In addition, in describing the components of the embodiments of the disclosure, terms such as “first”, “second”, “A”, “B”, “(a)”, and “(b)” can be used. Such terms are only for distinguishing one component from another component, and do not determine the nature, sequence, or procedure of the corresponding constituent elements.

In addition, when it is described that a component is “connected”, “coupled” or “joined” to another component, the description may include not only being directly “connected”, “coupled” or “joined” to the other component but also being “connected”, “coupled” or “joined” by another component between the component and the other component. In addition, in the case of being described as being formed or disposed “above (on)” or “below (under)” another component, the description includes not only the case where the two components are in direct contact with each other, but also the case where one or more other components are formed or disposed between the two components. In addition, when expressed as “above (on)” or “below (under)”, it may refer to a downward direction as well as an upward direction with respect to one element.

Hereinafter, an AF driving unit may alternatively be referred to as a lens driving device, a lens driving unit, a voice coil motor (VCM), an actuator, or a lens moving device. Hereinafter, a “coil” may alternatively be referred to as a coil unit, and an “elastic member” may alternatively be referred to as an elastic unit or a spring.

In addition, in the following description, a “terminal” may alternatively be referred to as a pad, an electrode, a conductive layer, or a bonding unit.

In the following description, the terms “board unit”, “printed circuit board”, “circuit board”, and “board” may be used interchangeably.

For convenience of description, a camera device according to an embodiment will be described using the Cartesian coordinate system (x,y,z), but the embodiments are not limited thereto, and may be described using other coordinate systems. In the respective drawings, the x-axis and the y-axis may be directions perpendicular to the z-axis, which is an optical-axis direction, the z-axis direction, which is the direction of the optical axis OA, may be referred to as a “first direction”, the x-axis direction may be referred to as a “second direction”, and the y-axis direction may be referred to as a “third direction”. In addition, for example, the x-axis direction may be referred to as “any one of the first horizontal direction and the second horizontal direction”, and the y-axis direction may be referred to as “the other of the first horizontal direction and the second horizontal direction”.

In addition, for example, the optical axis may be an optical axis of a lens mounted to a lens barrel. The first direction may be a direction perpendicular to an imaging area of an image sensor. In addition, for example, the optical-axis direction may be a direction parallel to the optical axis.

The camera device according to the embodiment may perform an “autofocus function”. Here, the autofocus function is a function of automatically focusing an image of a subject on the surface of an image sensor.

Hereinafter, the camera device may alternatively be referred to as a “camera module”, a “camera assembly”, a “camera unit”, a “camera”, an “image-capturing device”, or a “lens moving device”.

In addition, the camera device according to the embodiment may perform a “hand-tremor compensation function”. Here, the hand-tremor compensation function is a function of inhibiting the contour of a captured still image from being blurred due to vibration caused by shaking of a hand of a user when capturing the still image.

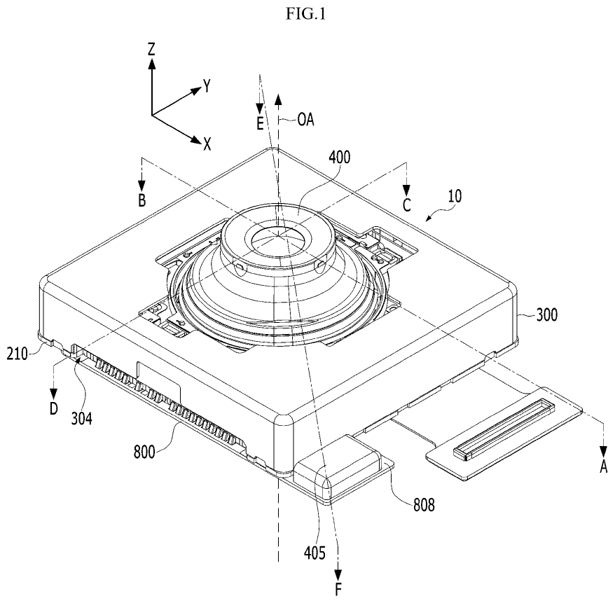

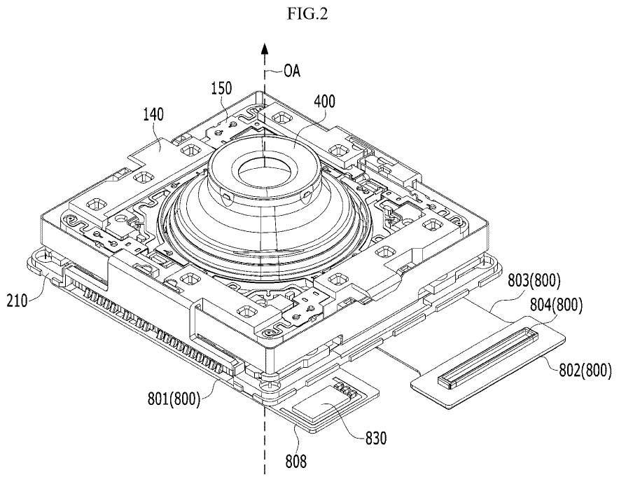

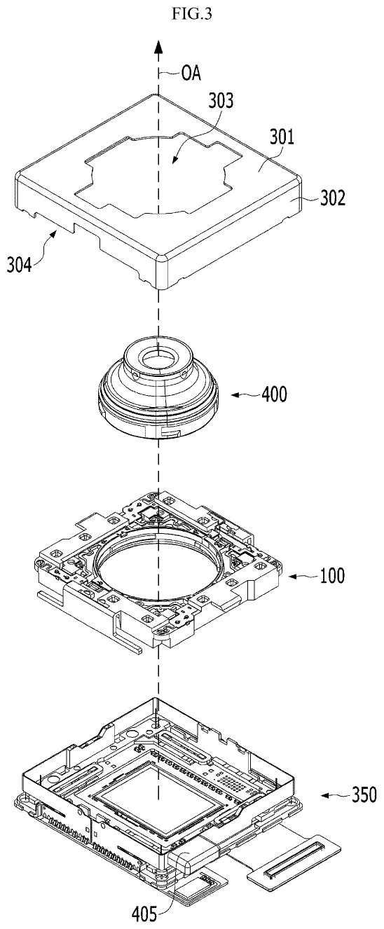

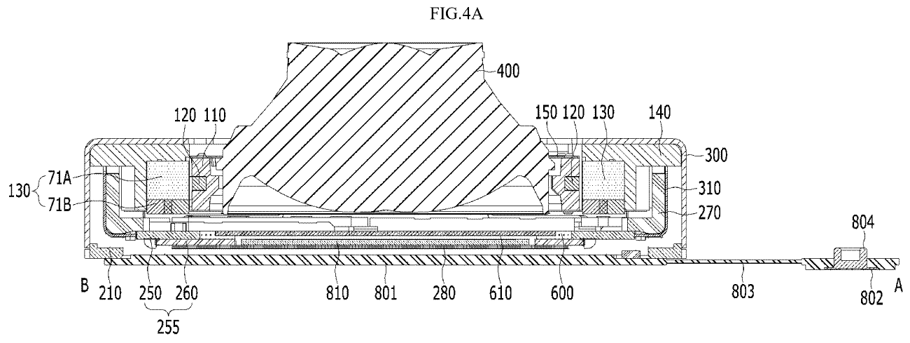

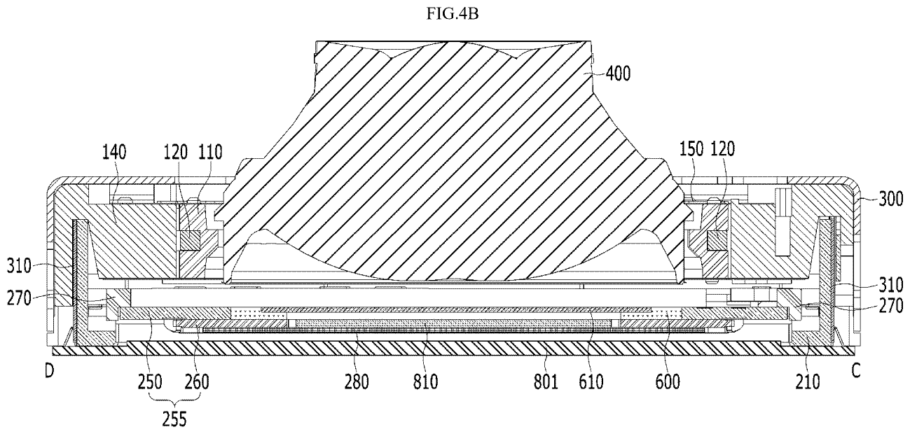

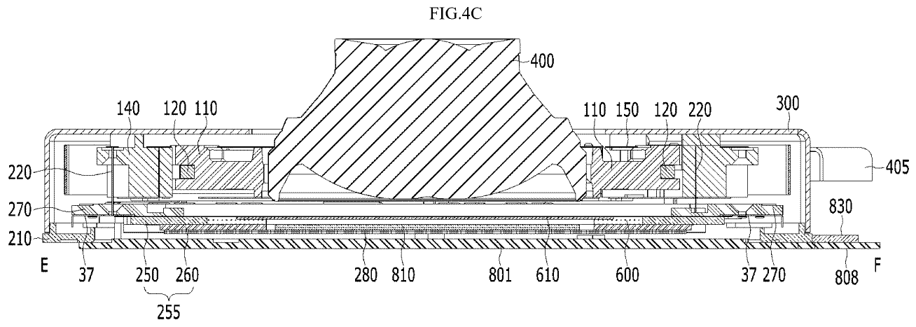

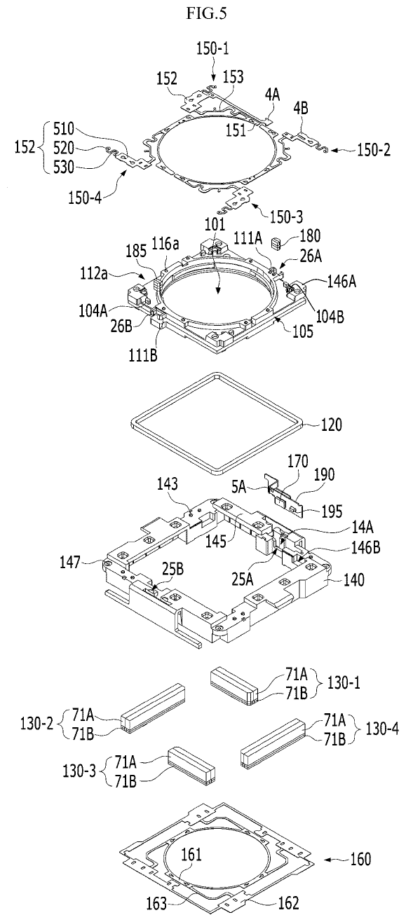

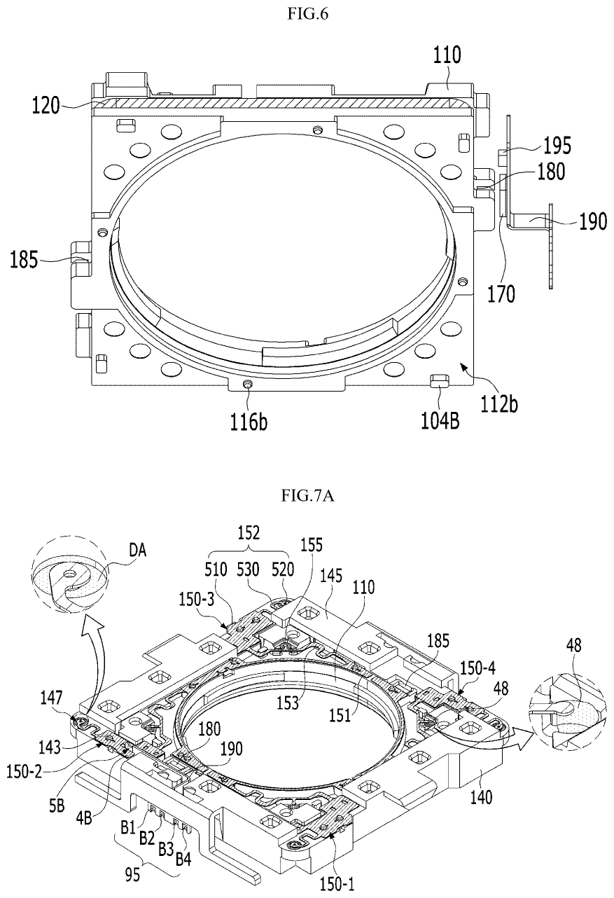

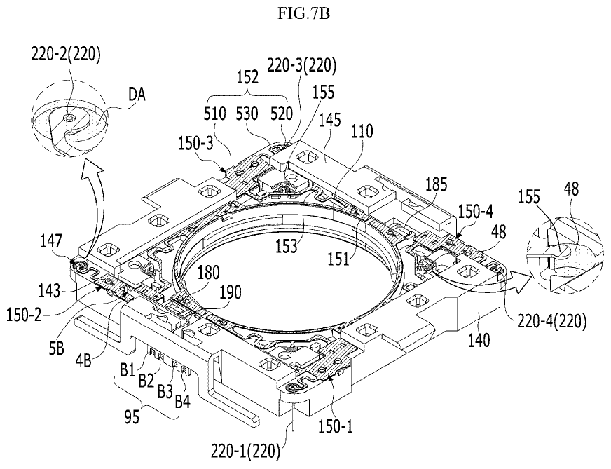

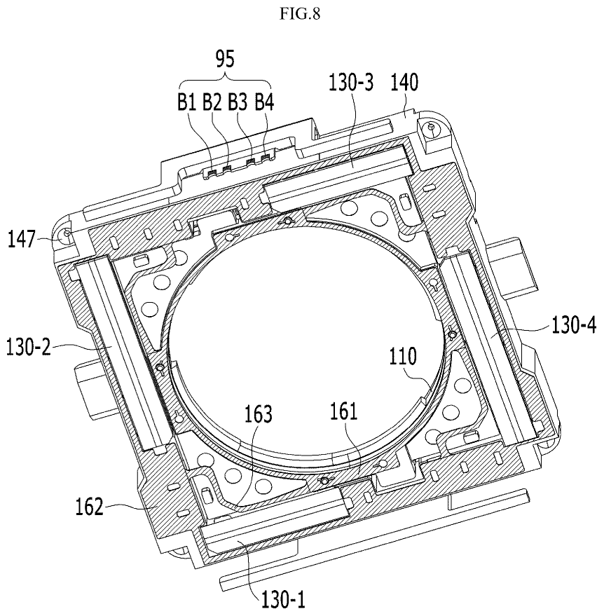

FIG. 1 is a perspective view of a camera device 10 according to an embodiment, FIG. 2 is a perspective view of the camera device 10, with a cover member 300 removed therefrom, FIG. 3 is an exploded perspective view of the camera device 10 in FIG. 1, FIG. 4A is a cross-sectional view taken along line AB in the camera device 10 in FIG. 1, FIG. 4B is a cross-sectional view taken along line CD in the camera device 10 in FIG. 1, FIG. 4C is a cross-sectional view taken along line EF in the camera device 10 in FIG. 1, FIG. 5 is an exploded perspective view of an AF driving unit 100 in FIG. 3, FIG. 6 is a perspective view of a bobbin 110, a sensing magnet 180, a balancing magnet 185, a first coil 120, a circuit board 190, a first position sensor 170, and a capacitor 195, FIGS. 7A and 7B are perspective views of the bobbin 110, a housing 140, the circuit board 190, an upper elastic member 150, the sensing magnet 180, and the balancing magnet 185, and FIG. 8 is a bottom perspective view of the housing 140, the bobbin 110, a lower elastic member 160, a magnet 130, and the circuit board 190.

Referring to FIGS. 1 to 8, the camera device 10 may include an AF driving unit 100 and an image sensor unit 350. The AF driving unit 100 may include an AF moving unit. The image sensor unit 350 may include an OIS driving unit. The OIS driving unit may include an OIS moving unit. One of the AF moving unit and the OIS moving unit may be a first moving unit, and the other of the AF moving unit and the OIS moving unit may be a second moving unit.

The camera device 10 may further include at least one of a cover member 300 or a lens module 400. The cover member 300 and a base 210 to be described later may constitute a case.

The AF driving unit 100 may be coupled to a lens module 400, and may move the lens module in the direction of the optical axis OA or a direction parallel to the optical axis, thereby performing the autofocus function of the camera device 10.

The image sensor unit 350 may include an image sensor 810. For example, the image sensor unit 350 (or OIS driving unit) may include an OIS moving unit including the image sensor 810. For example, the image sensor unit 350 may move the OIS moving unit (e.g., image sensor 810) in a direction perpendicular to the optical axis. In addition, the image sensor unit 350 may tilt or rotate (or roll) the OIS moving unit (e.g., image sensor 810) with respect to the optical axis or about the optical axis. The hand-tremor compensation function of the camera device 10 may be performed by the image sensor unit 350.

In an example, the image sensor 810 may include an imaging area for sensing of light that has passed through the lens module 400. Here, the imaging area may alternatively be referred to as an effective area, a light-receiving area, an active area, or a pixel area. For example, the imaging area of the image sensor 810 may be a portion into which light that has passed through a filter 610 is introduced so as to form an image contained in the light, and may include at least one unit pixel. In an example, the imaging area may include a plurality of unit pixels.

The AF driving unit 100 may alternatively be referred to as a “lens moving unit” or a “lens driving device”. Alternatively, the AF driving unit 100 may be referred to as a “first moving unit (or second moving unit)”, a “first actuator (or second actuator)”, or an “AF driving unit”.

In addition, the image sensor unit 350 may alternatively be referred to as an “image sensor moving unit”, an “image sensor shift unit”, a “sensor moving unit”, or a “sensor shift unit”. Alternatively, the image sensor unit 350 may be referred to as a “second moving unit (or first moving unit)” or a “second actuator (or first actuator)”.

Referring to FIGS. 5 and 6, the AF driving unit 100 may move a lens module 400 in the optical-axis direction. In an example, the AF driving unit 100 may move a bobbin 110 in the optical-axis direction. In an example, the AF driving unit 100 may include the bobbin 110, a first coil 120, a magnet 130, and a housing 140. The AF driving unit 100 may further include an upper elastic member 150 and a lower elastic member 160.

In addition, the AF driving unit 100 may further include a first position sensor 170, a circuit board 190, and a sensing magnet 180 in order to implement AF feedback. In addition, the AF driving unit 100 may further include at least one of a balancing magnet 185 or a capacitor 195.

The bobbin 110 may be disposed in the housing 140, and may be moved in the direction of the optical axis OA or the first direction (e.g., the Z-axis direction) by electromagnetic interaction between the first coil 120 and the magnet 130.

The bobbin 110 may have a bore formed therein in order to be coupled to the lens module 400 or to mount the lens module 400 therein. In an example, the bore in the bobbin 110 may be a through-hole formed through the bobbin 110 in the optical-axis direction and may have a circular shape, an elliptical shape, or a polygonal shape. However, the disclosure is not limited thereto.

The lens module 400 may include at least one lens and/or a lens barrel. In an example, the lens module 400 may include one or more lenses and a lens barrel accommodating the one or more lenses. However, the disclosure is not limited thereto, and any of various holding structures may be used in place of the lens barrel, so long as the same is capable of supporting one or more lenses.

In an example, the lens module 400 may be screwed to the bobbin 110. Alternatively, in another example, the lens module 400 may be coupled to the bobbin 110 by means of an adhesive (not shown). Meanwhile, light that has passed through the lens module 400 may pass through the filter 610, and may be introduced into the image sensor 810.

The bobbin 110 may include at least one protruding portion 111A or 111B provided on an outer surface thereof. In an example, the at least one protruding portion 111A or 111B may protrude in a direction parallel to a straight line perpendicular to the optical axis OA. However, the disclosure is not limited thereto. In an example, the bobbin 110 may include two protruding portions 111A and 111B located opposite each other.

The protruding portions 111A and 111B of the bobbin 110 may correspond to recessed portions 25A and 25B in the housing 140 to be inserted into or disposed in the recessed portions 25A and 25B in the housing 140, and may suppress or inhibit the bobbin 110 from rotating beyond a predetermined range about the optical axis.

The bobbin 110 may include a protruding portion 146A protruding in a direction perpendicular to the optical axis. In an example, the protruding portion 146A of the bobbin 110 may be disposed on a corner portion of the bobbin 110. In another embodiment, the protruding portion 146A may be disposed on a side portion of the bobbin 110.

The housing 140 may include a recess 146B formed therein so as to correspond to, face, or overlap the protruding portion 146A of the bobbin 110. At least part of the protruding portion 146A of the bobbin 110 may be disposed in the recess 146B in the housing 140.

The protruding portion 146A of the bobbin 110 may serve as a stopper that allows the bobbin 110 to move within a prescribed range in the optical-axis direction (e.g., the direction from the upper elastic member 150 toward the lower elastic member 160).

The bobbin 110 may include a first escape recess 112a formed in an upper surface thereof in order to avoid spatial interference with a first frame connection portion 153 of the upper elastic member 150. In addition, the bobbin 110 may include a second escape recess 112b formed in a lower surface thereof in order to avoid spatial interference with a second frame connection portion 163 of the lower elastic member 160.

The bobbin 110 may include a first coupling portion 116a in order to be coupled or fixed to the upper elastic member 150. For example, the first coupling portion 116a of the bobbin 110 may take the form of a protrusion. However, the disclosure is not limited thereto. In another embodiment, the first coupling portion may take the form of a flat surface or a recess. In addition, the bobbin 110 may include a second coupling portion 116b in order to be coupled or fixed to the lower elastic member 160. For example, the second coupling portion 116b may take the form of a protrusion. However, the disclosure is not limited thereto. In another embodiment, the second coupling portion may take the form of a flat surface or a recess.

Referring to FIG. 5, the bobbin 110 may include a recess 105 formed in the outer surface thereof to allow the first coil 120 to be seated therein, inserted thereinto, or disposed therein. For example, the recess 105 in the bobbin 110 may have a closed curve shape (e.g., ring shape), which coincides with the shape of the first coil 120.

In addition, the bobbin 110 may include a first seating recess 26a formed therein to allow the sensing magnet 180 to be seated therein, inserted thereinto, fixed thereto, or disposed therein. In addition, the bobbin 110 may include a second seating recess 26b formed in the outer surface thereof to allow the balancing magnet 185 to be seated therein, inserted thereinto, fixed thereto, or disposed therein.

In an example, the first and second seating recesses 26a and 26b in the bobbin 110 may be formed in the outer surfaces of the bobbin 110 that face each other. In an example, the first seating recess 26a may be formed in the first protruding portion 111A of the bobbin 110, and the second seating recess 26b may be formed in the second protruding portion 111B of the bobbin 110.

Referring to FIGS. 5, 7A, and 7B, a damper may be disposed between the bobbin 110 and the upper elastic member 150. In an example, the damper 48 may be disposed between the bobbin 110 and the first frame connection portion 153 of the upper elastic member 150 so as to be in contact therewith, coupled thereto, or attached thereto.

In addition, a damper 48 may be disposed between the upper elastic member 150 and the housing 140. In an example, the damper 48 may be disposed between the housing 140 and the first frame connection portion 153 of the upper elastic member 150 so as to be in contact therewith, coupled thereto, or attached thereto.

In an example, the upper elastic member 150 may include an extension portion (or protruding portion) 155 extending from the first frame connection portion 153. The extension portion 155 may be spaced apart from each of an outer frame 152 and an inner frame 151. In addition, the extension portion 155 may be spaced apart from one end of the first frame connection portion 153 that is connected to the inner frame 151 and the other end of the first frame connection portion 153 that is connected to the outer frame 152. The extension portion 155 may extend above the upper surface of the bobbin 110. In an example, a part (or end) of the extension portion 155 may be disposed on the damper 48 disposed on the upper surface of the bobbin 110 and may overlap the damper 48.

In an example, the bobbin 110 may include a receiving portion 104B formed therein to allow the damper 48 to be received or disposed therein. For example, the receiving portion 104B may be a recess. The receiving portion 104B may be depressed in the bottom surface of the escape portion 112a of the bobbin 110.

In an example, the extension portion 155 may extend toward the recess 104B in the bobbin 110, may be located above the recess 104B in the bobbin 110, and may overlap the recess 104B in the bobbin 110 in the optical-axis direction.

The damper 48 may be disposed between the bobbin 110 (e.g., the upper surface thereof) and the extension portion 155 of the upper elastic member 150 so as to be in contact therewith, coupled thereto, or attached thereto. Because the damper 48 is in contact with or attached to the extension portion 155 and the bobbin 110, the damper 48 may serve to alleviate or absorb vibration of the bobbin 110. For example, the damper 48 may be formed as a damping member (e.g., silicone). The recess 104B in the bobbin 110 may serve to receive or store the damper 48 to inhibit the damper 48 from flowing down. For example, the damper 48 may be formed as a damping member (e.g., silicone).

A lens driving device according to another embodiment may include a damper disposed between the extension portion 155 of the upper elastic member 150 and the housing 140 so as to be in contact with, coupled to, or attached to the extension portion 155 and the housing 140. In this case, a recess in which the damper is received may be formed in the upper surface of the housing 140.

The first coil 120 is disposed on or coupled to the bobbin 110. In an example, the first coil 120 may be disposed on or coupled to the outer surface of the bobbin 110. In an example, the first coil 120 may surround the outer surface of the bobbin 110 in the direction of rotation about the optical axis OA. However, the disclosure is not limited thereto.

The first coil 120 may be directly wound around the outer surface of the bobbin 110. However, the disclosure is not limited thereto. In another embodiment, the first coil 120 may be wound around the bobbin 110 using a coil ring or may be implemented as a coil block having an angled ring shape.

Power or a driving signal may be supplied to the first coil 120. The power or the driving signal supplied to the first coil 120 may be a direct current signal, an alternating current signal, or a signal containing direct current and alternating current components, and may be of a voltage type or a current type.

When a driving signal (e.g., driving current) is supplied to the first coil 120, electromagnetic force may be generated by electromagnetic interaction with the magnet 130, and the bobbin 110 may be moved in the direction of the optical axis OA by the generated electromagnetic force.

At the initial position of the AF driving unit, the bobbin 110 may be moved upward or downward, which is referred to as bidirectional driving of the AF driving unit. Alternatively, at the initial position of the AF driving unit, the bobbin 110 may be moved upward, which is referred to as unidirectional driving of the AF driving unit.

At the initial position of the AF driving unit, the first coil 120 may be disposed so as to correspond to or overlap the magnet 130, which is disposed in the housing 140, in a direction parallel to a straight line that is perpendicular to the optical axis OA and extends through the optical axis.

In an example, the AF driving unit may include the bobbin 110 and components coupled to the bobbin 110 (e.g., the first coil 120, the sensing magnet 180, and the balancing magnet 185). In addition, the AF driving unit may further include the lens module 400.

In addition, the initial position of the AF driving unit may be the original position of the AF driving unit in a state in which no power is supplied to the first coil 120 or a position at which the AF driving unit is located as a result of the upper and lower elastic members 150 and 160 being elastically deformed due only to the weight of the AF driving unit. In addition, the initial position of the bobbin 110 may be a position at which the AF driving unit is located when gravity acts in a direction from the bobbin 110 toward the base 210 or when gravity acts in a direction from the base 210 toward the bobbin 110.

The sensing magnet 180 may provide a magnetic field, which is to be detected by the first position sensor 170, and the balancing magnet 185 may serve to cancel out the influence of the magnetic field of the sensing magnet 180 and to establish weight equilibrium with the sensing magnet 180.

The sensing magnet 180 may alternatively be referred to as a “sensor magnet” or a “second magnet”. The sensing magnet 180 may be disposed on the bobbin 110 or may be coupled to the bobbin 110. The sensing magnet 180 may be disposed so as to face the first position sensor 170. The balancing magnet 185 may be disposed on the bobbin 110 or may be coupled to the bobbin 110. In an example, the balancing magnet 185 may be disposed opposite the sensing magnet 180.

In an example, each of the sensing magnet 180 and the balancing magnet 185 may be a monopolar-magnetized magnet, which has one N pole and one S pole. However, the disclosure is not limited thereto. In another embodiment, each of the sensing magnet 180 and the balancing magnet 185 may be a bipolar-magnetized magnet or a 4-pole magnet, which includes two N poles and two S poles.

The sensing magnet 180 may be moved in the optical-axis direction together with the bobbin 110, and the first position sensor 170 may detect the intensity of the magnetic field or the magnetic force of the sensing magnet 180, which is moved in the optical-axis direction, and may output an output signal corresponding to a result of the detection.

In an example, the intensity of the magnetic field or the magnetic force detected by the first position sensor 170 may vary depending on displacement of the bobbin 110 in the optical-axis direction, the first position sensor 170 may output an output signal proportional to the detected intensity of the magnetic field, and the displacement of the bobbin 110 in the optical-axis direction may be detected using the output signal from the first position sensor 170.

The housing 140 is disposed inside the cover member 300. In an example, the housing 140 may be disposed on the image sensor unit 350.

The housing 140 may accommodate therein the bobbin 110 and may support the magnet 130, the first position sensor 170, and the circuit board 190.

Referring to FIGS. 5 and 7A-8, the housing 140 may be formed in the overall shape of a hollow column. In an example, the housing 140 may include a polygonal (e.g., quadrangular or octagonal) or circular bore formed therein, and the bore in the housing 140 may take the form of a through-hole formed through the housing 140 in the optical-axis direction.

The housing 140 may include side portions, which correspond to or face side plates 302 of the cover member 300, and corners, which correspond to or face the corners of the cover member 300.

The housing 140 may be provided on the upper portion, upper surface, or upper end thereof with a stopper 145 in order to avoid direct collision with the inner surface of an upper plate 301 of the cover member 300.

Referring to FIG. 5, the housing 140 may include a mounting groove (or groove) 14A formed therein to accommodate the circuit board 190. The mounting groove 14A may have a shape coinciding with the shape of the circuit board 190.

Referring to FIGS. 7A and 7B, the housing 140 may include an opening formed therein to expose terminals B1 to B4 of a terminal unit 95 of the circuit board 190 therethrough, and the opening may be formed in the side portion of the housing 140.

The housing 140 may be provided on the upper portion, upper end, or upper surface thereof with at least one first coupling portion 143, which is coupled to a first outer frame 152 of the upper elastic member 150. The housing 140 may be provided on the lower portion, lower end, or lower surface thereof with a second coupling portion, which is coupled and fixed to a second outer frame 162 of the lower elastic member 160. For example, each of the first and second coupling portions of the housing 140 may be formed in the shape of a flat surface, a protrusion, or a recess.

A hole 147, which is a passage through which a wire 220 passes, may be formed in a corner of the housing 140. The hole 147 may be a through-hole formed through the housing 140 in the optical-axis direction. In another embodiment, the hole may be structured so as to be depressed in the outer surface of a corner portion of the housing 140, and at least a portion of the hole may be open to the outer surface of the corner portion. The hole 147 in the housing 140 may be provided in the same number as the number of support members.

The magnet 130 may be disposed on, coupled to, or fixed to the housing 140, which is a fixed unit. In an example, the magnet 130 may be disposed on, coupled to, or fixed to a side portion of the housing 140. The magnet 130 may include an AF driving magnet 71A for AF driving. In addition, the magnet 130 may include an OIS driving magnet 71B for OIS driving. Hereinafter, the AF driving magnet 71A may be referred to as one of the first magnet and the second magnet, and the OIS driving magnet 71B may be referred to as the other of the first magnet and the second magnet.

In another embodiment, the magnet 130 may be disposed on, coupled to, or fixed to the corner portion of the housing.

In an example, the magnet 130 may include a plurality of magnet units. In an example, the magnet 130 may include first to fourth magnet units 130-1 to 130-4 disposed on the housing 140. In another embodiment, the magnet 130 may include two or more magnet units.

The magnet 130 may be disposed on at least one of the side portion or the corner of the housing 140. In an example, at least a portion of the magnet 130 may be disposed on the side portion or the corner of the housing 140. Alternatively, in another example, at least a portion of the magnet 130 may be disposed on the side portion of the housing 140, and the remaining portion thereof may be disposed on the corner of the housing 140.

In an example, each of the magnet units 130-1 to 130-4 may include a first portion disposed on a corresponding corner among the four corners of the housing 140. In addition, each of the magnet units 130-1 to 130-4 may include a second portion disposed on the side portion of the housing 140 that is adjacent to the corresponding corner of the housing 140.

In an example, the first magnet unit 130-1 and the third magnet unit 130-3 may be located on opposite sides of the housing 140 in the first horizontal direction (e.g., the Y-axis direction). In an example, the second magnet unit 130-2 and the fourth magnet unit 130-4 may be located on opposite sides of the housing 140 in the second horizontal direction (e.g., the X-axis direction).

In an example, the first magnet unit 130-1 and the third magnet unit 130-3 may be disposed parallel to each other in the second horizontal direction (e.g., the X-axis direction), and the second magnet unit 130-2 and the fourth magnet unit 130-4 may be disposed parallel to each other in the first horizontal direction (e.g., the Y-axis direction).

At the initial position of the AF driving unit, the magnet 130 may be disposed on the housing 140 such that at least a portion thereof overlaps the first coil 120 in a direction parallel to a straight line that is perpendicular to the optical axis OA and extends through the optical axis OA.

The magnet 130 may include a monopolar-magnetized magnet or a 2-pole magnet including one N-pole area and one S-pole area. In another embodiment, the magnet 130 may include a bipolar-magnetized magnet or a 4-pole magnet including two N-pole areas and two S-pole areas. In another embodiment, the magnet 130 may include a monopolar-magnetized magnet and a bipolar-magnetized magnet.

In an example, the magnet 130 may include a magnet for AF (or AF driving magnet) for implementation of AF operation and a magnet for OIS (or OIS driving magnet) for implementation of OIS operation. In another embodiment, the magnet 130 may be a common magnet for implementation of AF operation and OIS operation.

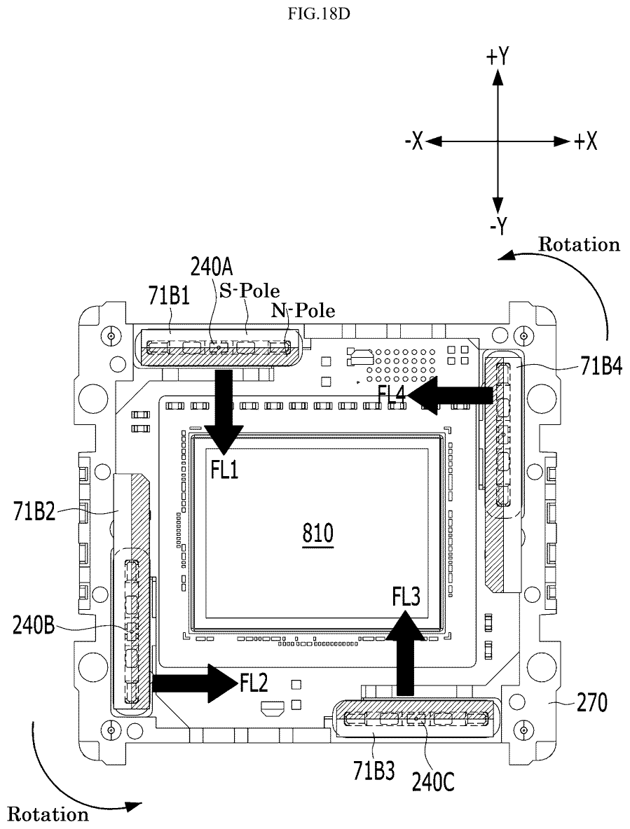

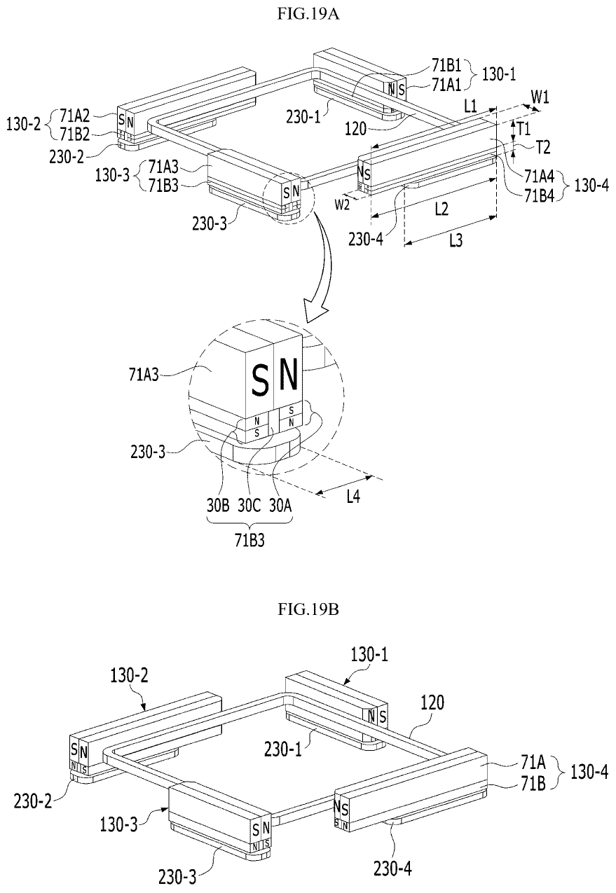

FIG. 19A shows an embodiment of the magnet 130 in FIG. 5.

Referring to FIG. 19A, the magnet 130 may include a first magnet 71A, which is a magnet for AF, and a second magnet 71B, which is a magnet for OIS disposed beneath the first magnet 71A.

The first magnet 71A may be a 2-pole magnet including one N-pole area and one S-pole area. In an example, the N-pole area and the S-pole area of the first magnet 71A may be disposed so as to face or oppose each other in a direction perpendicular to the optical axis. In another embodiment, the first magnet 71A may be a 4-pole magnet including two N-pole areas and two S-pole areas.

The first magnet 71A may include a plurality of magnet units 71A1 to 71A4. As described above, each of the plurality of magnet units 71A1 to 71A4 may be a 2-pole magnet or a 4-pole magnet. In an example, the magnet units 71A1 to 71A4 may have the same size and shape as each other. In an example, two magnet units 71A1 and 71A3 opposing each other in a first diagonal direction may have the same size and shape as each other, and the remaining two magnet units 71A2 and 71A4 opposing each other in a second diagonal direction may have the same size and shape as each other.

In another embodiment, the size and shape of the two magnet units 71A1 and 71A3 may be different from those of the remaining two magnet units 71A2 and 71A4. In an example, the length of the long side of each of the two magnet units 71A1 and 71A3 may be greater than the length of the long side of each of the remaining two magnet units 71A2 and 71A4. In an example, the length of the short side of each of the two magnet units 71A1 and 71A3 may be equal to the length of the short side of each of the remaining two magnet units 71A2 and 71A4.

The second magnet 71B may be a 4-pole magnet including two N-pole areas and two S-pole areas. In an example, the second magnet 71B may include a first magnet part 30A, a second magnet part 30B, and a partition wall 30C disposed between the first magnet part 30A and the second magnet part 30B. In this case, the partition wall 30C may be a non-magnetic material or air, and may be referred to as a “neutral zone” or a “neutral area”. In another embodiment, the second magnet 71B may be a 2-pole magnet including one N-pole area and one S-pole area.

In an example, the first magnet part 30A and the second magnet part 30B may be spaced apart from each other in a direction perpendicular to the first direction (or the optical-axis direction). In an example, the first magnet part 30A may include a first N-pole area and a first S-pole area opposing or facing each other in the optical-axis direction. The second magnet part 30B may include a second N-pole area and a second S-pole area opposing or facing each other in the optical-axis direction. In addition, the first N-pole area (or the first S-pole area) of the first magnet part 30A and the second S-pole area (or the second N-pole area) of the second magnet part 30B may oppose or face each other in a direction perpendicular to the optical axis.

The second magnet 71B may include a plurality of magnet units 71B1 to 71B4. As described above, each of the plurality of magnet units 71B1 to 71B4 may be a 4-pole magnet. In another embodiment, each of the magnet units 71B1 to 71B4 may be a 2-pole magnet. Each of the magnet units 71B 1 to 71B4 may oppose or overlap a corresponding one of the second coil units 230-1 to 230-4 in the optical-axis direction.

In an example, the magnet units 71B1 to 71B4 may have the same size and shape as each other. In an example, two magnet units 71B1 and 71B3 opposing each other in the first diagonal direction may have the same size and shape as each other, and the remaining two magnet units 71B2 and 71B4 opposing each other in the second diagonal direction may have the same size and shape as each other.

In another embodiment, the size and shape of the two magnet units 71B1 and 71B3 may be different from those of the remaining two magnet units 71B2 and 71B4. In an example, the length of the long side of each of the two magnet units 71B1 and 71B3 may be greater than the length of the long side of each of the remaining two magnet units 71B2 and 71B4. In an example, the length of the short side of each of the two magnet units 71B1 and 71B3 may be equal to the length of the short side of each of the remaining two magnet units 71B2 and 71B4.

The second magnet 71B may be disposed beneath the first magnet 71A. The second magnet 71B may be disposed on the lower surface of the first magnet 71A. In an example, the upper surface of the second magnet 71B may be in contact with the lower surface of the first magnet 71A or may be fixed or coupled to the lower surface of the first magnet 71A by means of an adhesive. In an example, at least a portion of the first magnet 71A may overlap at least a portion of the second magnet 71B in the first direction (or the optical-axis direction).

In another embodiment, the second magnet may be spaced apart from the first magnet. In this case, a portion of the housing 140 may be disposed between the first magnet and the second magnet. Alternatively, in another embodiment, a partition wall or a yoke may be disposed between the first magnet and the second magnet spaced apart from each other. In this case, the description of the partition wall 30C may be equally or similarly applied to the partition wall.

In an example, the length T2 of the second magnet 71B in the optical-axis direction may be less than the length T1 of the first magnet 71A in the optical-axis direction (T2<T1). In another embodiment, T2 may be greater than or equal to T1.

In addition, the length L2 of the long side of the second magnet 71B may be less than or equal to the length L1 of the long side of the first magnet 71A (L2≤L1). In another embodiment, L2 may be greater than L1.

In addition, the width W2 (or the length of the short side) of the second magnet 71B may be less than or equal to the width W1 (or the length of the short side) of the first magnet 71A (W2≤W1). In another embodiment, W2 may be greater than W1.

At the initial position of the AF moving unit, the first coil 120 may oppose or overlap the first magnet 71A in a direction perpendicular to the first direction (or the optical-axis direction). In FIG. 19A, the N-pole area of the first magnet 71A may be disposed so as to face the first coil 120, or the N-pole area thereof may be located closer to the first coil 120 than the S-pole area thereof. However, in another embodiment, the position of the N-pole area and the position of the S-pole area may be interchanged.

In an example, at the initial position of the OIS moving unit, at least a portion of the first magnet 130 may overlap at least a portion of the second coil 230 in the first direction (or the optical-axis direction). In an example, at the initial position of the OIS moving unit, at least a portion of the second magnet 71B may overlap at least a portion of the second coil 230 in the first direction (or the optical-axis direction).

The length L2 of the long side of the second magnet 71B may be greater than the length L3 of the long side of the second coil 230 (L2>L3). In another embodiment, the length of the long side of the second magnet 71B may be less than or equal to the length of the long side of the second coil 230.

The width W2 (or the length of the short side) of the second magnet 71B may be greater than the length L4 of the short side of the second coil 230 (W2>L4). In another embodiment, the length of the long side of the second magnet 71B may be less than or equal to the length of the long side of the second coil 230.

In an example, the length of the long side of each of two magnet units 71B1 and 71B3 of the second magnet 71B may be less than the length of the long side of a respective one of the coil units 230-1 and 230-3 of the second coil 230. In another embodiment, the length of the long side of each of the two magnet units 71B1 and 71B3 may be equal to or greater than the length of the long side of a respective one of the coil units 230-1 and 230-3.

In addition, the length of the long side of each of the remaining two magnet units 71B2 and 71B4 of the second magnet 71B may be greater than the length of the long side of a respective one of the coil units 230-2 and 230-4 of the second coil 230. In another embodiment, the length of the long side of each of the magnet units 71B2 and 71B4 may be equal to or less than the length of the long side of a respective one of the coil units 230-2 and 230-4 of the second coil 230.

In an example, the length of the short side of each of the first to fourth magnet units 71B1 to 71B4 of the second magnet 71B may be less than the length of the short side of a respective one of the first to fourth coil units 230-1 to 230-4 of the second coil 230. In another embodiment, the length of the short side of each of the first to fourth magnet units 71B1 to 71B4 may be greater than the length of the short side of a respective one of the first to fourth coil units 230-1 to 230-4.

FIG. 19B shows another embodiment of the magnet 130 in FIG. 5.

Referring to FIG. 19B, the second magnet 71B in FIG. 19B may be a 2-pole magnet including one N-pole area and one S-pole area. The description of the lengths T2, L2, and W2 of the second magnet 71B in FIG. 19A may be equally or similarly applied to the second magnet 71B in FIG. 19B.

The circuit board 190 may be disposed in the housing 140, and the first position sensor 170 may be disposed or mounted on the circuit board 190 and may be conductively connected to the circuit board 190. In an example, the circuit board 190 may be disposed in the mounting groove 14A in the housing 140, and terminals B1 to B4 of the circuit board 190 may be exposed outside the housing 140.

The circuit board 190 may be provided with a terminal unit (or terminal part) 95 including a plurality of terminals B1 to B4 for conductive connection to an external terminal or an external device. The plurality of terminals B1 to B4 of the circuit board 190 may be conductively connected to the first position sensor 170.

The first position sensor 170 may be disposed on the housing 140 and/or the circuit board 190. In an example, the first position sensor 170 may be disposed on a first surface of the circuit board 190, and the plurality of terminals B1 to B4 may be disposed on a second surface of the circuit board 190. Here, the second surface of the circuit board 190 may be a surface opposite the first surface of the circuit board 190. In an example, the first surface of the circuit board 190 may be the surface of the circuit board 190 that faces the bobbin 110 or the sensing magnet 180. For example, the circuit board 190 may be a printed circuit board or an FPCB.

The first position sensor 170 may be conductively connected to the circuit board 190. In an example, the first position sensor 170 may be conductively connected to the first to fourth terminals B1 to B4 of the circuit board 190. In an example, the circuit board 190 may include a circuit pattern or wiring (not shown) for conductive connection between the first to fourth terminals B1 to B4 and the first position sensor 170.

In an example, at the initial position of the AF driving unit, at least a portion of the first position sensor 170 may oppose or overlap the sensing magnet 180 in a direction parallel to a straight line that is perpendicular to the optical axis OA and extends through the optical axis OA. In another embodiment, at the initial position of the AF driving unit, the first position sensor may not oppose or overlap the sensing magnet.

The first position sensor 170 serves to detect movement, displacement, or position of the bobbin 110 in the optical-axis direction. That is, when the bobbin 110 is moved, the first position sensor 170 may detect the magnetic field or the intensity of the magnetic field of the sensing magnet 180 mounted to the bobbin 110 and may output an output signal corresponding to a result of the detection, and the movement, displacement, or position of the bobbin 110 in the optical-axis direction may be detected using the output from the first position sensor 170.

The first position sensor 170 may be a driver IC including a Hall sensor and a driver. The first position sensor 170 may include first to fourth terminals for transmitting and receiving data to and from the outside through data communication using a protocol, such as I2C communication, and fifth and sixth terminals for directly supplying a driving signal to the first coil 120.

In an example, each of the first to fourth terminals of the first position sensor 170 may be conductively connected to a corresponding one of the first to fourth terminals B1 to B4 of the circuit board 190 by means of a solder or a conductive adhesive.

In addition, in an example, the fifth and sixth terminals of the first position sensor 170 may be conductively connected to the first coil 120. In an example, the first position sensor 170 may be conductively connected to the first coil 120 via at least one of the upper elastic member 150 or the lower elastic member 160 and may supply a driving signal to the first coil 120.

In an example, a portion of the first upper elastic unit 150-1 may be connected to one end of the first coil 120, and the other portion of the first upper elastic unit 150-1 may be conductively connected to the circuit board 190. A portion of the second upper elastic unit 150-2 may be connected to the other end of the first coil 120, and the other portion of the second upper elastic unit 150-2 may be conductively connected to the circuit board 190. The circuit board 190 may include a first pad 5A conductively connected to the other portion of the first upper elastic unit 150-1 and a second pad 5B conductively connected to the other portion of the second upper elastic unit 150-2. Each of the fifth and sixth terminals of the first position sensor 170 may be conductively connected to a corresponding one of the first and second pads 5A and 5B of the circuit board 190.

In another embodiment, the first coil 120 may be conductively connected to the circuit board 190 and the fifth and sixth terminals of the first position sensor 170 via two lower elastic members.

In an example, in an embodiment in which the first position sensor 170 is a driver IC, the first and second terminals B1 and B2 of the circuit board 190 may be power terminals for supply of power, the third terminal B3 may be a terminal for transmission and reception of a clock signal, and the fourth terminal B4 may be a terminal for transmission and reception of a data signal.

In another embodiment, the first position sensor 170 may be a Hall sensor. In this case, the first position sensor 170 may include two input terminals for reception of a driving signal or power supplied thereto and two output terminals for output of a sensing voltage (or output voltage). In an example, a driving signal may be supplied to the first position sensor 170 through the first and second terminals B1 and B2 of the circuit board 190, and the output from the first position sensor 170 may be output to the outside through the third and fourth terminals B3 and B4. In addition, the first coil 120 may be conductively connected to the circuit board 190. The circuit board 190 may further include two separate terminals in addition to the first to fourth terminals B1 to B4, and a driving signal may be supplied to the first coil 120 from the outside through the two separate terminals.

In an example, among the power terminals of the first position sensor 170, a ground terminal may be conductively connected to the cover member 300.

The capacitor 195 may be disposed or mounted on the first surface of the circuit board 190. The capacitor 195 may be of a chip type. In this case, the chip may include a first terminal, which corresponds to one end of the capacitor 195, and a second terminal, which corresponds to the other end of the capacitor 195. The capacitor 195 may alternatively be referred to as a “capacitive element” or a condenser.

The capacitor 195 may be conductively connected in parallel to the first and second terminals B1 and B2 of the circuit board 190, through which power (or driving signal) is supplied to the first position sensor 170 from the outside. Alternatively, the capacitor 195 may be conductively connected in parallel to the terminals of the first position sensor 170, which are conductively connected to the first and second terminals B1 and B2 of the circuit board 190.

Because the capacitor 195 is conductively connected in parallel to the first and second terminals B1 and B2 of the circuit board 190, the capacitor 195 may serve as a smoothing circuit for removing ripple components included in power signals GND and VDD, which are supplied to the first position sensor 170 from the outside, and thus may supply stable and consistent power signals to the first position sensor 170.

In another embodiment, the sensing magnet 180 may be disposed on the housing 140, and the first position sensor 170 may be disposed on the bobbin 110. In another embodiment, the balancing magnet 185 may be omitted.

The upper elastic member 150 and the lower elastic member 160 may be coupled to the bobbin 110 and the housing 140. In an example, the upper elastic member 150 may be coupled to the upper portion, upper end, or upper surface of the bobbin 110 and to the upper portion, upper end, or upper surface of the housing 140, and the lower elastic member 160 may be coupled to the lower portion, lower end, or lower surface of the bobbin 110 and to the lower portion, lower end, or lower surface of the housing 140. The upper elastic member 150 and the lower elastic member 160 may elastically support the bobbin 110 with respect to the housing 140.

The upper elastic member 150 may include a plurality of upper elastic units (e.g., 150-1 to 150-4), which are conductively separated or isolated from each other. The lower elastic member 160 is implemented as a single elastic unit. However, in another embodiment, the lower elastic member may include a plurality of lower elastic units, which are conductively separated or isolated from each other. In another embodiment, at least one of the upper elastic member or the lower elastic member may be implemented as a single unit or a single construction.

The upper elastic member 150 may further include a first inner frame 151 coupled or fixed to the upper portion, upper surface, or upper end of the bobbin 110, a second inner frame 152 coupled or fixed to the upper portion, upper surface, or upper end of the housing 140, and a first frame connection portion 153 interconnecting the first inner frame 151 and the first outer frame 152. In addition, the upper elastic member 150 may include the above-described extension portion 155.

The lower elastic member 160 may include a second inner frame 161 coupled or fixed to the lower portion, lower surface, or lower end of the bobbin 110, a second outer frame 162 coupled or fixed to the lower portion, lower surface, or lower end of the housing 140, and a second frame connection portion 163 interconnecting the second inner frame 161 and the second outer frame 162. The inner frame may alternatively be referred to as an inner portion, the outer frame may alternatively be referred to as an outer portion, and the frame connection portion may alternatively be referred to as a connection portion.

Each of the first and second frame connection portions 153 and 163 may be formed so as to be bent or curved (or crooked) at least once to form a pattern having a predetermined shape.

Each of the upper elastic member 150 and the lower elastic member 160 may be made of a conductive material, for example, metal. In addition, each of the upper elastic member 150 and the lower elastic member 160 may be formed as an elastic member, for example, a leaf spring.

Referring to FIGS. 5, 7A, and 7B, in an example, the second outer frame 152 of the first upper elastic unit 150-1 may include a first bonding portion 4A coupled or conductively connected to the first pad 5A of the circuit board 190, and the second outer frame 152 of the second upper elastic unit 150-2 may include a second bonding portion 4B conductively connected to the second pad 5B of the circuit board 190.

In another embodiment, at least one of the upper elastic member 150 or the lower elastic member 160 may include two elastic members. In an example, each of the two elastic members of any one of the upper elastic member 150 and the lower elastic member 160 may be coupled or conductively connected to a corresponding one of the first and second pads of the circuit board 190, and the first coil 120 may be conductively connected to the two elastic members.

The first outer frame 152 of the upper elastic member 150 may include a first coupling portion 510 coupled to the housing 140, a second coupling portion 520 coupled to the wire 220, and a connection portion 530 interconnecting the first coupling portion 510 and the second coupling portion 520. The first coupling portion 510 may include a through-hole or a hole formed therein in order to be coupled to the first coupling portion 143 of the housing 140. The second coupling portion 520 may include a through-hole or a hole formed therein in order to be coupled to the wire 220. In an example, the second coupling portion 520 may be coupled to the wire 220 by means of a conductive adhesive or a solder. In an example, the connection portion 530 may include a bent portion bent at least once or a curved portion curved at least once. However, the disclosure is not limited thereto. In another embodiment, the connection portion 530 may have a straight line shape.

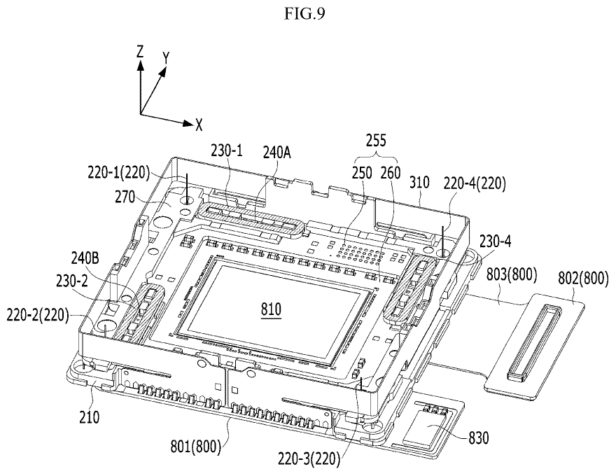

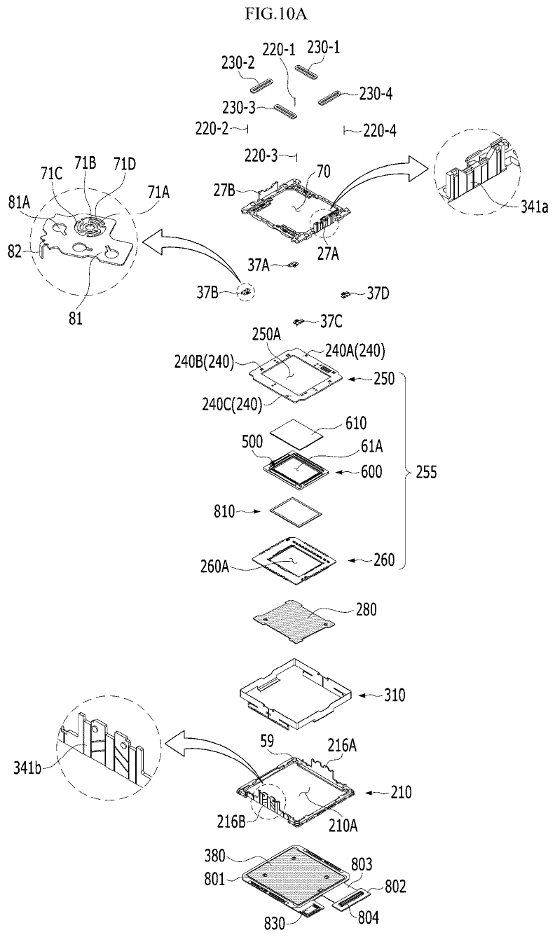

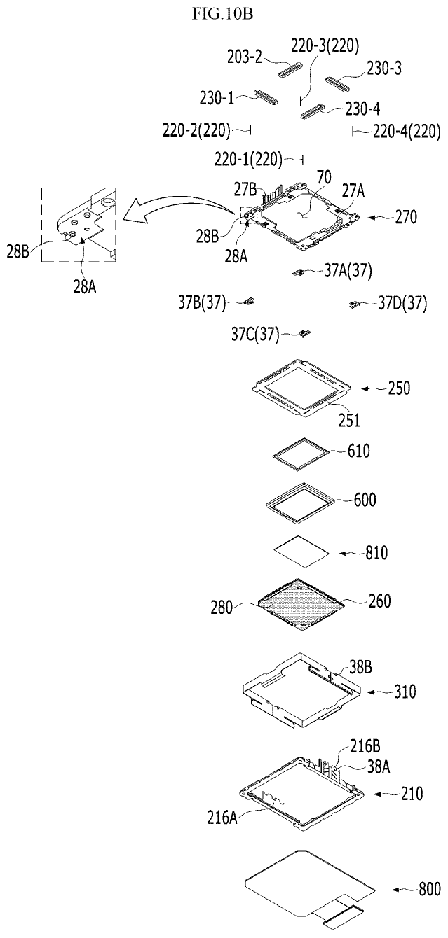

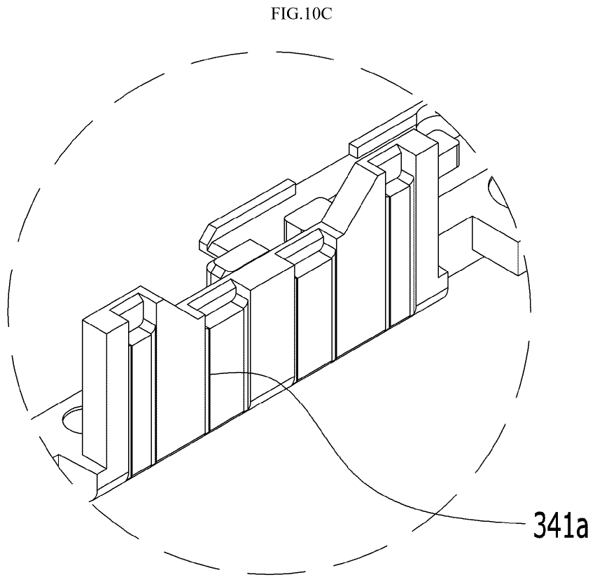

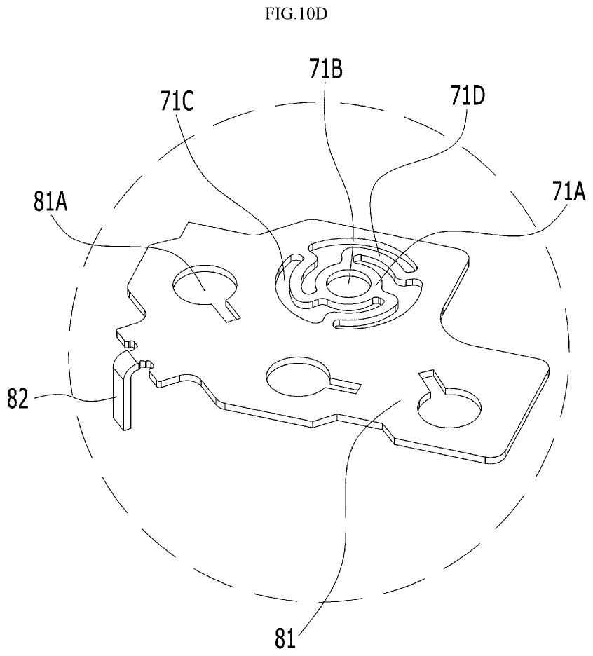

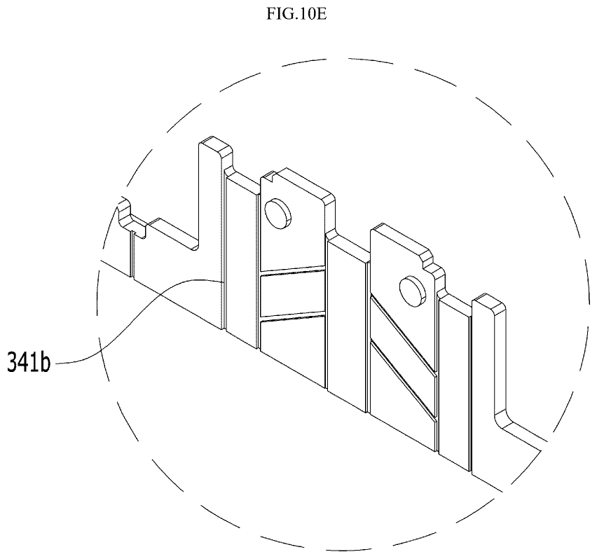

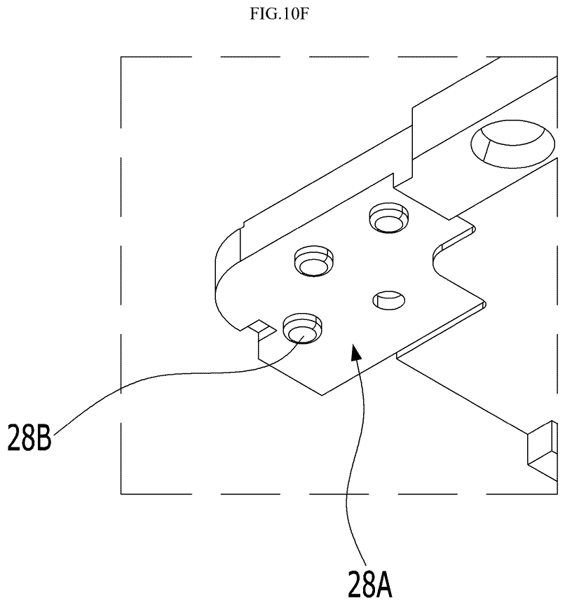

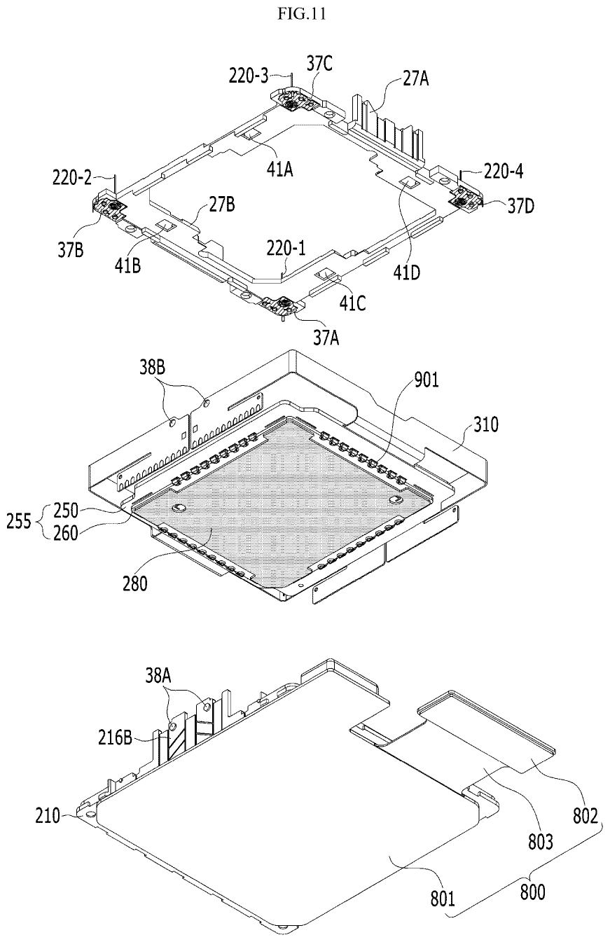

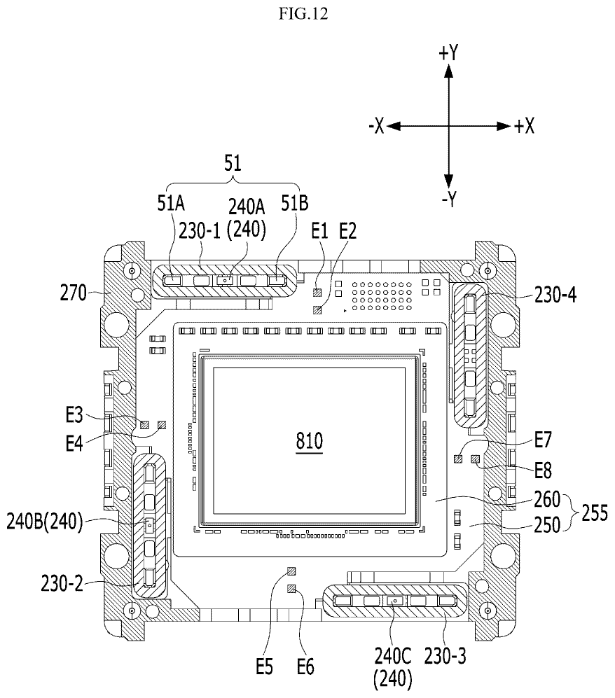

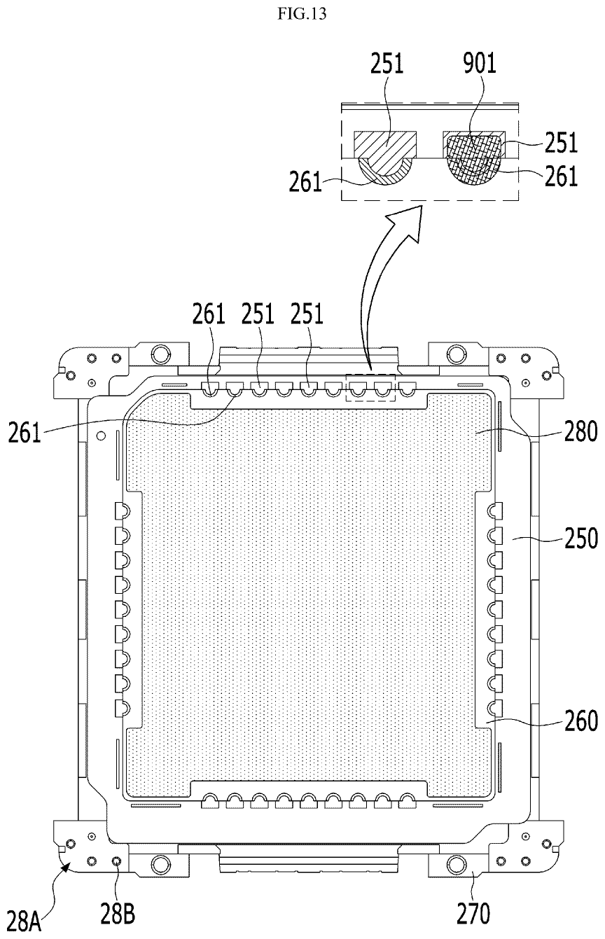

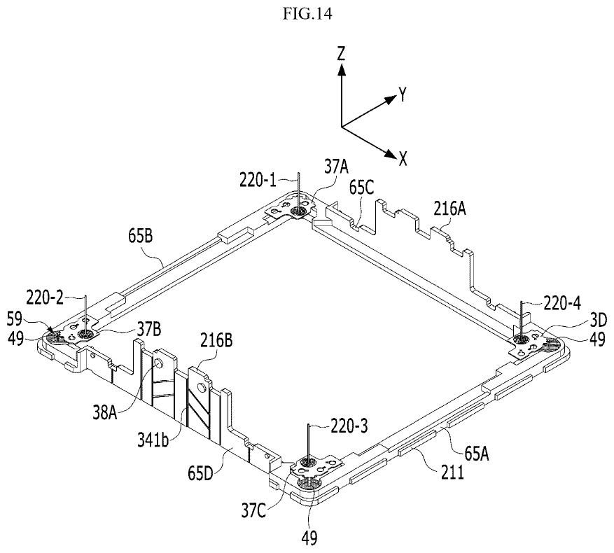

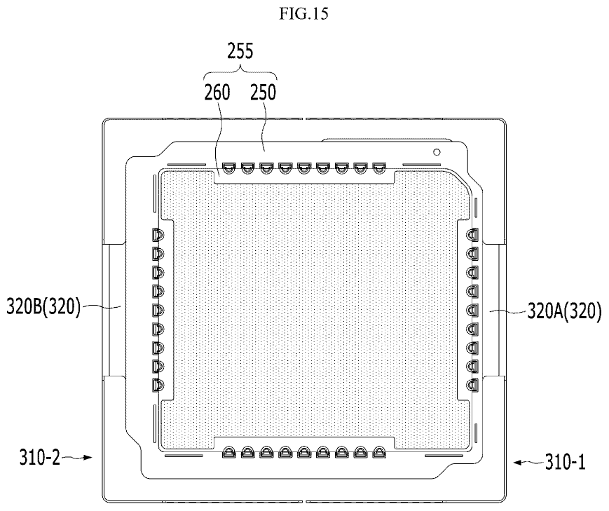

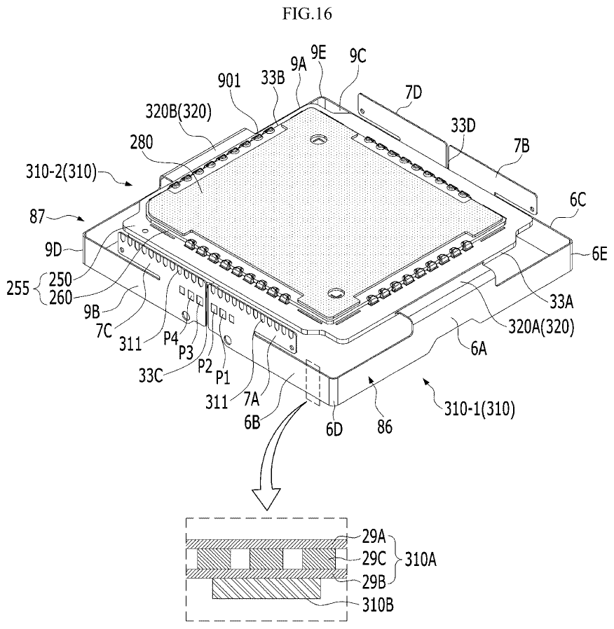

FIG. 9 is a perspective view of the image sensor unit 350, FIG. 10A is a first exploded perspective view of the image sensor unit 350 in FIG. 9, FIG. 10B is a second exploded perspective view of the image sensor unit 350 in FIG. 9, FIG. 11 is a bottom perspective view of a holder 270, a terminal unit 37, a first board unit 255, a support board 310, the base 210, and a second board unit 800 in FIG. 10A, FIG. 12 is a plan view of the holder 270, the first board unit 255, the image sensor 810, the second coil 230, and an OIS position sensor 240, FIG. 13 is a rear perspective view of the holder 270 and the first board unit 255, FIG. 14 is a perspective view of the base 210, the terminal unit 37, and the wire 220, FIG. 15 is a bottom view of the first board unit 255, the support board 310, and a first heat dissipation member 280, FIG. 16 is a perspective view of the first board unit 255, the support board 310, and the first heat dissipation member 280, FIG. 17A is a first perspective view of the support board 310 coupled to the holder 270 and to the base 210, and FIG. 17B is a second perspective view of the support board 310 coupled to the holder 270 and to the base 210.

Referring to FIGS. 9 to 17B, the image sensor unit 350 may include a fixed unit and an OIS moving unit spaced apart from the fixed unit. The image sensor unit 350 may include a support board 310 interconnecting the fixed unit and the OIS moving unit.

The fixed unit may be a fixed unit of the camera device 10 that does not move during OIS operation. In an example, the fixed unit may include a second board unit 800. In an example, the fixed unit may include a base 210 coupled to the second board unit 800. In an example, the fixed unit may include the housing 140 of the AF driving unit and components disposed on the housing 140, for example, the magnet 130, the first position sensor 170, and the circuit board 180. In addition, the fixed unit may include a cover member 300 coupled to the base 210. The OIS moving unit may be disposed inside the cover member 300.

The OIS moving unit may include the image sensor 810. The OIS moving unit may further include a first board unit 255 spaced apart from and conductively connected to the second board unit 800. In addition, in an example, the OIS moving unit may include components disposed on the first board unit 255, for example, at least one of a first heat dissipation member 280, a holder 270, a second coil 230, or a second position sensor 240. The holder 270 may alternatively be referred to as a “spacing member”. In another embodiment, the holder 270 may be omitted, and the second coil 230 may be disposed on the first board unit 255, for example, the first circuit board 250.

The camera device 10 may include an elastic member 220 (hereinafter referred to as a “wire”) to elastically support the OIS moving unit with respect to the fixed unit. The elastic member 220 may take the form of a wire or a spring.

In an example, one end of the wire 220 may be coupled to the upper elastic member 150 (or the housing 140), and the other end of the wire 220 may be coupled to the holder 270. In an example, one end of the wire 220 may be coupled to the first outer frame 152 of the upper elastic member 150 (e.g., the second coupling portion 520) by means of a solder or a conductive adhesive. In an example, the other end of the wire 220 may be disposed on the holder 270 or may be coupled to the terminal unit 37 coupled to the holder 270 by means of a solder or a conductive adhesive.

Referring to FIGS. 7A and 7B, a damper DA may be disposed between one end of the wire 220 passing through the hole 147 in the housing 140 and the hole 147 in the housing 140. In an example, at least a portion of the damper DA may be disposed in the hole 147 in the housing 140 and may be coupled or attached to at least a portion of the wire 220 and the housing 140.

In an example, the wire 220 may be disposed in the optical-axis direction. In an example, the wire 220 may be disposed on a corner of the housing 140 and/or a corner of the holder 270. In an example, the wire 220 may include four wires 220-1 to 220-4. Each of the four wires 220-1 to 220-4 may be disposed on a corresponding one of four corners of the housing 140 and/or four corners of the holder 270.

Referring to FIGS. 10A and 10B, the holder 270 may include a hole 271 formed therein to allow at least a portion of the wire 220 to pass therethrough. In an example, the hole 271, through which the other end of the wire 220 passes, may be formed in the corner of the holder 270. In an example, the hole 271 may be formed in each of the four corners of the holder 270. In an example, the hole 271 may be a through-hole formed through the holder 270 in the optical-axis direction. However, in another embodiment, the hole 271 may take the form of an escape recess.

In an example, the terminal unit 27 may be disposed on or coupled to the upper surface or lower surface of the holder 270. In an example, the terminal unit 27 may be disposed on or coupled to the lower surface of the corner of the holder 270. The holder 270 may include a recess 28A formed therein to allow the terminal unit 37 to be disposed therein. In an example, the recess 28A may be formed in the lower surface of the corner of the holder 270.

The holder 270 may include at least one protrusion 28B, and the terminal unit 37 may include at least one hole 81A formed therein in order to be coupled to the at least one protrusion 28B. The terminal unit 37 and the holder 270 may be coupled to each other by means of an adhesive or thermal fusion. In addition, the terminal unit 37 may include a hole 71B formed therein to allow the other end of the wire 220 to be inserted thereinto or coupled thereto. For example, each of the holes 81A and 71B may be a through-hole.

In an example, the terminal unit 37 may include a body 81 coupled to the holder 270. The body 81 may include a coupling portion 71 coupled to the wire 220. The coupling portion 71 may include a coupling region 71A coupled to the wire 220 and a hole 71B formed in the coupling region 71A. The coupling region 71A may be a region of the body 81 that is coupled to the wire 220 by means of a solder or a conductive adhesive. In an example, the other end of the wire 220 that has passed through the hole 71B may be coupled to the lower portion or lower surface of the coupling region 71A by means of a solder or a conductive adhesive.

In an example, the body 81 may include at least one hole 71C formed therein around the coupling region 71A. In an example, the body 81 may include a plurality of holes 71C formed therein so as to surround the coupling region 71A. In an example, the plurality of holes 71C may be spaced apart from the hole 71B.

In addition, the body 81 may include a support portion 71D, which is located between the plurality of holes 71C and supports the coupling region 71A. The support portion 71D may alternatively be referred to as a “connection portion” or a “bridge”. The support portion 71D may include a plurality of support portions spaced apart from each other. The support portion 71D may be connected to the coupling region 71A.

When soldering is performed, the at least one hole 71C may serve to enable a solder to be primarily formed only in the coupling region 71A by interface tension (e.g., surface tension) of the edge of the coupling region 71A.

In addition, the coupling region 71A needs to be heated in order to perform soldering. The at least one hole 71C may suppress or inhibit transfer of heat from the coupling region 71A to another region of the body 81, thereby inhibiting a solder from being formed in the other region of the body 81 when soldering is performed. As a result, the at least one hole 71C may improve the solderability of a solder.

The terminal unit 37 may include an extension portion 82 extending from the body 81. The extension portion 82 may be bent and extend from the body 81 in the downward direction. In an example, the extension portion 82 may extend toward a hole 59 in the base 210. The extension portion 82 may alternatively be referred to as a “bent portion”.

In an example, the terminal unit 37 may include four terminals 37A to 37D corresponding to the four wires 220-1 to 220-4. Each of the terminals 37A to 37D may be disposed on a corresponding one of the corners of the holder 270 and may be coupled to a corresponding one of the wires 220-1 to 220-4. The description given with reference to FIG. 10A may be equally or similarly applied to the structure of each of the terminals 37A to 37D. The terminal unit 37 may be made of a conductive material, for example, metal. In another embodiment, the terminal unit 37 may be omitted, and the wire 220 may be directly coupled to the holder 270.

Referring to FIG. 14, a damper 49 may be disposed between the terminal unit 37 and the base 210. The damper 49 may be in contact with, coupled to, or attached to the terminal unit 37 and the base 210. In an example, the base 210 may include a hole 59 (or recess) formed at a position corresponding to or opposing the terminal unit 37. In an example, the hole 59 (or the recess) may be formed in the corner of the base 210.

In an example, the damper 59 may be disposed in the hole 59 in the base 210.

Alternatively, at least part of the extension portion 82 of the terminal unit 37 may be disposed in the hole 59 in the base 210, and the damper 59 may be in contact with, coupled to, or attached to the extension portion 82. The damper 59 may serve to absorb or alleviate vibration of the OIS moving unit, thereby inhibiting or suppressing oscillation of the OIS moving unit during OIS driving.

In another embodiment, the extension portion 82 may be omitted from the terminal unit 37, and the camera device 10 may not include the damper 49 in FIG. 14.

The support board 310 may support the OIS moving unit with respect to the fixed unit such that the OIS moving unit is capable of moving in a direction perpendicular to the optical axis or such that the OIS moving unit is capable of tilting or rotating within a predetermined range about the optical axis.

The holder 270 may be disposed below the AF driving unit. In an example, the holder 270 may be embodied as a non-conductive member. In an example, the holder 270 may be made of an injection-molding material, which may be easily shaped through an injection-molding process. In addition, the holder 270 may be formed of an insulating material. In addition, for example, the holder 270 may be formed of resin or plastic.

Referring to FIGS. 10A, 10B, and 12, the holder 270 may include an upper surface, a lower surface formed opposite the upper surface, and a side surface (e.g., outer side surface) interconnecting the upper surface and the lower surface. In an example, the lower surface of the holder 270 may oppose or face the second board unit 800.

The holder 270 may support the first board unit 255 and may be coupled to the first board unit 255. In an example, the first board unit 255 may be disposed beneath the holder 270. In an example, the lower portion, lower surface, or lower end of the holder 270 may be coupled to the upper portion, upper surface, or upper end of the first board unit 255. In an example, the holder 270 may be coupled to the first board unit 255 by means of an adhesive.

The holder 270 may accommodate or support the second coil 230. The holder 270 may support the second coil 230 such that the second coil 230 is spaced apart from the first board unit 255. In an example, at least a portion of the holder 270 may be disposed between the second coil 230 and the first board unit 255.

The holder 270 may include a bore 70 formed therein so as to correspond to one region of the first board unit 255. In an example, the bore 70 in the holder 270 may be a through-hole formed through the holder 270 in the optical-axis direction. In an example, the bore 70 in the holder 270 may correspond to, oppose, or overlap the image sensor 810 in the optical-axis direction.

When viewed from above, the shape of the bore 70 in the holder 270 may be a polygonal shape such as a quadrangular shape, a circular shape, or an elliptical shape. However, the disclosure is not limited thereto. The bore 70 may be formed in any of various shapes.

In an example, the bore 70 in the holder 270 may have a shape or a size suitable for exposing the image sensor 810, a portion of the upper surface of the first circuit board 250, a portion of the upper surface of the second circuit board 260, and other elements. In an example, the area of the bore 70 in the holder 270 may be larger than the area of the image sensor 810 and may be larger than the area of the bore 250A in the first circuit board 250.

The holder 270 may include holes 41A, 41B, and 41C formed therein so as to correspond to the second position sensor 240. In an example, the holder 270 may include holes 41A, 41B, and 41C formed therein at positions corresponding, respectively, to first to third sensors 240A, 240B, and 240C of the second position sensor 240.

In an example, the holes 41A, 41B, and 41C may be disposed adjacent to the corners of the holder 270. The holder 270 may include a dummy hole 41D formed therein at a position adjacent to the corner of the holder 270 that does not correspond to the second position sensor 240. The dummy hole 41D may be formed in order to establish weight equilibrium of the OIS moving unit during OIS driving. The dummy hole 41D may be a through-hole. In another embodiment, the dummy hole 41D may not be formed. The holes 41A, 41B, and 41C may be through-holes formed through the holder 270 in the optical-axis direction. In another embodiment, the holes 41A, 41B, and 41C may be omitted from the holder 270.

The holder 270 may be provided on the upper surface thereof with at least one coupling protrusion 51 in order to be coupled to the second coil 230. The coupling protrusion 51 may protrude from the upper surface of the holder 270 in the upward direction or toward the AF driving unit. In an example, the coupling protrusion 51 may be formed adjacent to each of the holes 41A to 41D in the holder 270.

In an example, two coupling protrusions 51A and 51B may be disposed or arranged so as to correspond to each of the holes 41A, 41B, 41C, and 41D in the holder 270. In an example, each of the holes 41A, 41B, 41C, and 41D in the holder 270 may be located between the two coupling protrusions 51A and 51B.

The holder 270 may include one or more protruding portions 27A and 27B. The protruding portions 27A and 27B may protrude from the upper surface of the holder 270. In an example, the protruding portions 27A and 27B may protrude from the outer side surface of the holder 270 in the optical-axis direction or the upward direction.

In an example, the holder 270 may include two protruding portions 27A and 27B, which oppose or overlap each other in the second horizontal direction (e.g., the X-axis direction).

In an example, the holder 270 may include four side portions (or side plates), and the protruding portions 27A and 27B may be formed on two side portions among the four side portions. In an example, the protruding portions 27A and 27B may be disposed or located at the centers of the side portions (or the side plates) of the holder 270.

The holder 270 may include a groove 341a formed therein. The groove 341a may be an adhesive-receiving groove. The groove 341a may be formed in the outer side surface of each of the protruding portions 27A and 27B of the holder 270. The groove 341a may be formed in the upper surface of each of the protruding portions 27A and 27B of the holder 270. The groove 341a may be formed from the upper surface of each of the protruding portions 27A and 27B of the holder 270 to the lower surface thereof. An adhesive, by which the support board 310 is adhered to the holder 270, may be disposed in the groove 341a. The groove 341a may include a plurality of grooves. In an example, the groove 341a may extend in the optical-axis direction. In another embodiment, the groove in the holder 270 may extend in a direction perpendicular to the optical axis.

The first board unit 255 may include a first circuit board 250 and a second circuit board 260 conductively connected to each other. The second circuit board 260 may alternatively be referred to as a “sensor board”.

The first board unit 255 may be disposed on the lower surface of the holder 270. In an example, the first board unit 255 may be coupled to the lower surface of the holder 270. In an example, the first circuit board 250 may be disposed on and/or coupled to the lower surface of the holder 270. In an example, a first surface of the first circuit board 250 may be coupled or attached to the lower surface of the holder 270 by means of an adhesive member.

In this case, the first surface of the first circuit board 250 may be a surface that faces or opposes the AF driving unit and on which the second position sensor 240 is disposed. In addition, a second surface of the first circuit board 250 may be a surface formed opposite the first surface of the first circuit board 250.

The first circuit board 250 may alternatively be referred to as a sensor board, a main board, a main circuit board, a sensor circuit board, or a moving circuit board. In all of the embodiments, the first circuit board 250 may alternatively be referred to as a “second board” or a “second circuit board”, and the second circuit board 260 may alternatively be referred to as a “first board” or a “first circuit board”.

The second position sensor 240 (240A, 240B, and 240C) may be disposed on the first circuit board 250 in order to detect movement of the OIS moving unit in a direction perpendicular to the optical-axis direction and/or rotation, tilting, or rolling of the OIS moving unit about the optical axis. In addition, a controller 830 and/or a circuit element (e.g., capacitor) may be disposed on the first circuit board 250.

The first circuit board 250 may include first terminals E1 to E8 in order to be conductively connected to the second coil 230. Here, the first terminals E1 to E8 may alternatively be referred to as “first pads” or “first bonding parts”. The first terminals E1 to E8 of the first circuit board 250 may be disposed or arranged on the first surface of the first circuit board 250. For example, the first circuit board 250 may be a printed circuit board or a flexible printed circuit board (FPCB).

The first circuit board 250 may include a bore 250A formed therein so as to correspond to or oppose the lens module 400 and the bore in the bobbin 110. In an example, the bore 250A in the first circuit board 250 may be a through-hole or a cavity formed through the first circuit board 250 in the optical-axis direction and may be formed at the center of the first circuit board 250.

When viewed from above, the shape of the first circuit board 250, for example, the outer circumferential shape thereof, may be a shape coinciding with or corresponding to the shape of the holder 270, for example, a quadrangular shape. In addition, when viewed from above, the shape of the bore 250A in the first circuit board 250 may be a polygonal shape such as a quadrangular shape, a circular shape, or an elliptical shape. In an example, the bore 250A in the first circuit board 250 may open or expose the image sensor 810 and/or a bore 260A in the second circuit board 260.

In addition, the first circuit board 250 may include at least one terminal 251 in order to be conductively connected to the second circuit board 260. Here, the terminal 251 of the first circuit board 250 may alternatively be referred to as a “pad” or a “bonding part”. The terminal 251 of the first circuit board 250 may be disposed or arranged on the lower surface of the first circuit board 250.

In an example, the terminal 251 may be provided in plural, and the plurality of terminals 251 may be disposed or arranged in a region between the bore 250A in the first circuit board 250 and any one side of the first circuit board 250 in a direction parallel to the side of the first circuit board 250. In an example, the plurality of terminals 251 may be arranged around the bore 250A. The second circuit board 260 may be disposed beneath the first circuit board 250.

When viewed from above, the shape of the second circuit board 260 may be a polygonal shape (e.g., quadrangular shape, square shape, or rectangular shape). However, the disclosure is not limited thereto. In another embodiment, the shape of the second circuit board 260 may be a circular shape or an elliptical shape.

In an example, the area of the outer circumferential surface of the second circuit board 260 having a quadrangular shape may be larger than the area of the bore 250A in the first circuit board 250. In an example, the lower side of the bore 250A in the first circuit board 250 may be shielded or blocked by the second circuit board 260.

In an example, when viewed from above or below, the outer side surface (or the side) of the second circuit board 260 may be located between the outer side surface (or the side) of the first circuit board 250 and the bore 250A in the first circuit board 250.

In an example, the second circuit board 260 may include a bore 260A formed therein so as to correspond to the bore 250A in the first circuit board 250 and/or the image sensor 810. The bore 260A in the second circuit board 260 may be a hole or a cavity formed through the second circuit board 260 in the optical-axis direction and may be formed at the center of the second circuit board 260.

In an example, the bore 260A in the second circuit board 260 may open or expose the image sensor 810. In an example, the image sensor 810 may be disposed in the bore 260A in the second circuit board 260.

In another embodiment, the bore 260A may not be formed in the second circuit board 260, and the image sensor 810 may be disposed on the upper surface of the second circuit board 260.

The second circuit board 260 may include at least one terminal 261 conductively connected to the at least one terminal 251 of the first circuit board 250. In an example, the terminal 261 of the second circuit board 260 may be provided in plural.

In an example, the at least one terminal 261 of the second circuit board 260 may be formed on the side surface or the outer side surface of the second circuit board 260 that interconnects the upper surface of the second circuit board 260 and the lower surface thereof. The upper surface of the second circuit board 260 may be a surface facing the first circuit board 250, and the lower surface of the second circuit board 260 may be a surface formed opposite the upper surface of the second circuit board. In an example, the terminal 261 may take the form of a recess depressed in the side surface of the second circuit board 260. Alternatively, for example, the terminal 261 may take the form of a semicircular or semi-elliptical via formed in the side surface of the second circuit board 260. In another embodiment, the at least one terminal of the second circuit board 260 that is conductively connected to the second terminal 251 of the first circuit board 250 may be formed on the upper surface of the second circuit board 260.

In an example, the terminal 261 of the second circuit board 260 may be coupled to the terminal 251 of the first circuit board 250 by means of a solder 901 (refer to FIG. 11) or a conductive adhesive member. Although only one solder 901 coupling any one terminal of the second circuit board 260 to any one terminal 251 of the first circuit board is illustrated in an enlarged portion indicated by a dotted line in FIG. 13, a solder for coupling another terminal of the second circuit board 260 to a terminal of the first circuit board 250 corresponding thereto may be provided.

For example, the first and second circuit boards 250 and 260 may be printed circuit boards or FPCBs. Further, at least one of the first and second circuit boards 250 and 260 may be an organic substrate or a ceramic substrate.

The first heat dissipation member 280 may be disposed on or coupled to the first board unit 255. In an example, the first heat dissipation member 280 may be disposed on or coupled to the second circuit board 260. In an example, the first heat dissipation member 280 may be disposed beneath the second circuit board 260. In an example, the first heat dissipation member 280 may be coupled or fixed to the lower surface of the second circuit board 260.

The bore 260A in the second circuit board 260 may open or expose at least a portion of the first heat dissipation member 280.

The image sensor 810 may be disposed on, attached to, or coupled to at least a portion of the first heat dissipation member 280 that is exposed by the bore 260A. In an example, the image sensor 810 may be fixed, attached, or coupled to the first heat dissipation member 280 by means of an adhesive.

In an example, at least a region of the upper surface of the first heat dissipation member 280 may be exposed by the bore 260A, and the image sensor 810 may be disposed on, attached to, or coupled to at least a region of the upper surface of the first heat dissipation member 280 that is exposed by the bore 260A.

In another embodiment, the second circuit board 260 may include a recess formed in the lower surface thereof to allow the first heat dissipation member 280 to be received or disposed therein.

In another embodiment, the bore 260A may not be formed in the second circuit board 260, and the first heat dissipation member 280 may be fixed, attached, or coupled to the lower surface of the second circuit board 260. In still another embodiment, the first heat dissipation member 280 may be omitted.

In an example, the first heat dissipation member 280 may be formed as a plate-type member having a predetermined thickness and hardness. In addition, the first heat dissipation member 280 may improve effect of dissipating heat generated from the heat source of the first board unit 255 to the outside. In this case, the heat source of the first board unit 255 may be an electronic element (or circuit element) disposed on the first board unit 255, for example, the image sensor 810, the controller 830, the second position sensor 240, and/or the capacitor.

In an example, the first heat dissipation member 280 may include a metallic material having high thermal conductivity and high heat dissipation efficiency, for example, at least one of SUS, aluminum, nickel, phosphorus, bronze, or copper.

In addition, the first heat dissipation member 280 may serve as a reinforcing member stably supporting the image sensor 810 and suppressing the image sensor 810 from being damaged by external impact or contact.

In another embodiment, the first heat dissipation member 280 may be formed of a heat dissipation material having high thermal conductivity, for example, heat dissipation epoxy, heat dissipation plastic (e.g., polyimide), or heat dissipation synthetic resin. In the first heat dissipation member 280, the “heat dissipation member” may alternatively be referred to as a plate, a metal plate, a reinforcing member, or a stiffener.

The first heat dissipation member 280 may include a predetermined pattern including at least one groove or at least one uneven portion in order to improve heat dissipation effect. In an example, a groove or an uneven portion having a predetermined pattern may be formed in the lower surface of the first heat dissipation member 280.

In an example, the predetermined pattern may include a plurality of grooves formed so as to be spaced apart from each other by predetermined intervals. In an example, the predetermined pattern may have a stripe shape. In another embodiment, the predetermined pattern may have a net shape or a mesh shape. In still another embodiment, the predetermined pattern may have a shape including dots spaced apart from each other. For example, the shape of the dot may be a circular shape, an elliptical shape, or a polygonal shape (e.g., quadrangular shape).

In another embodiment, the predetermined pattern may be formed in at least one of the upper surface, lower surface, or outer side surface of the first heat dissipation member 280. In still another embodiment, the heat dissipation member may include a hole or a through-hole in place of the groove or the uneven portion. Because the first heat dissipation member 280 moves together with the OIS moving unit, the first heat dissipation member 280 may be spaced apart from the fixed unit, for example, the second board unit 800. The first heat dissipation member 280 may include at least one escape recess 281 (refer to FIG. 10A) formed therein in order to avoid spatial interference with the solder 901.

The second coil 230 may be disposed on or coupled to the OIS moving unit. In an example, the second coil 230 may be disposed on the holder 270. The second coil 230 may be disposed on the upper surface of the holder 270. The second coil 230 may be disposed beneath the magnet 130.

The second coil 230 may be coupled to the holder 270. In an example, the second coil 230 may be coupled or attached to the upper surface of the holder 270. In an example, the second coil 230 may be coupled to the coupling protrusion 51 of the holder 270. The OIS moving unit may be moved by interaction between the second coil 230 and the magnet 130.

In an example, the second coil 230 may correspond to, oppose, or overlap the magnet 130 disposed on the fixed unit in the direction of the optical axis OA. In another embodiment, the fixed unit may include a separate OIS-dedicated magnet in addition to the magnet of the AF driving unit, and the second coil may correspond to, oppose, or overlap the OIS-dedicated magnet. In this case, the number of OIS-dedicated magnets may be the same as the number of coil units included in the second coil 230.

In still another embodiment, the OIS-dedicated magnet may be disposed on a fixed portion of the second coil 230, and an OIS-dedicated magnet 71B of the magnet 130 may be disposed on the OIS moving unit. In this case, the second coil 230 may be conductively connected to the support board 310 and/or the second board unit 800 via a conductive member.

In an example, the second coil 230 may include a plurality of coil units 230-1 to 230-4. In an example, the second coil 230 may include four coil units 230-1 to 230-4 disposed on the four corners of the holder 270. In an example, at least a portion of each of the coil units 230-1 to 230-4 may be disposed on a corresponding one of the corners of the holder 270. A portion of each of the coil units 230-1 to 230-4 may be disposed on a side portion of the holder 270 that is adjacent to a corresponding one of the corners of the holder 270.

Each of the coil units 230-1 to 230-4 may take the form of a coil block having a closed curve shape or a ring shape. In an example, each coil unit may have a cavity or a hole formed therein. In an example, each of the coil units may be formed as a fine pattern (FP) coil, a wound coil, or a coil block. In an example, the protrusion 51 of the holder 270 may be inserted into or coupled to the cavity or the hole in each of the coil units 230-1 to 230-4.

In another embodiment, the second coil 230 may be disposed on the first circuit board 250 or may be coupled to the first circuit board 250.

The second coil 230 may be conductively connected to the first circuit board 250. In an example, the first coil unit 230-1 may be conductively connected to two terminals E1 and E2 of the first circuit board 250, the second coil unit 230-2 may be conductively connected to two other terminals E3 and E4 of the first circuit board 250, the third coil unit 230-3 may be conductively connected to two other terminals E5 and E6 of the first circuit board 250, and the fourth coil unit 230-4 may be conductively connected to two other terminals E7 and E8 of the first circuit board 250.

Power or a driving signal may be supplied to the first to fourth coil units 230-1 to 230-4 through the first circuit board 250. The power or the driving signal supplied to the second coil 230 may be a direct current signal, an alternating current signal, or a signal containing direct current and alternating current components, and may be of a current type or a voltage type.

The OIS moving unit may be moved in the first horizontal direction or the second horizontal direction or may be rolled about the optical axis by interaction between the first to fourth magnet units 130-1 to 130-4 and the first to fourth coil units 230-1 to 230-4.

In an example, current may be independently applied to at least three coil units among the four coil units 230-1 to 230-4. In another embodiment, current may be independently applied to at least two coil units among the four coil units 230-1 to 230-4.

In an example, a separate independent driving signal, e.g., driving current, may be supplied to each of the four coil units 230-1 to 230-4.

The controller 830 or 780 may supply at least one driving signal to at least one of the first to fourth coil units 230-1 to 230-4 and may control the at least one driving signal such that the OIS moving unit is moved in the X-axis direction and/or the Y-axis direction or is rotated within a predetermined angular range about the optical axis. The “controller” to be described hereinbelow may be at least one of the controller 830 of the camera module 10 or the controller 780 of an optical instrument 200A.

When the second coil 230 is driven in a three-channel drive mode, three independent driving signals may be supplied to the second coil 230. In an example, among the four coil units, two coil units (e.g., 230-2 and 230-4, or 230-1 and 230-3), which face each other in a diagonal direction, may be connected in series to each other. One driving signal may be supplied to two coil units connected in series to each other, and an independent driving signal may be supplied to each of the remaining two coil units among the four coil units.

Alternatively, when the second coil 230 is driven in a four-channel drive mode, an independent driving signal may be supplied to each of the four coil units 230-1 to 230-4, which are separated from each other.

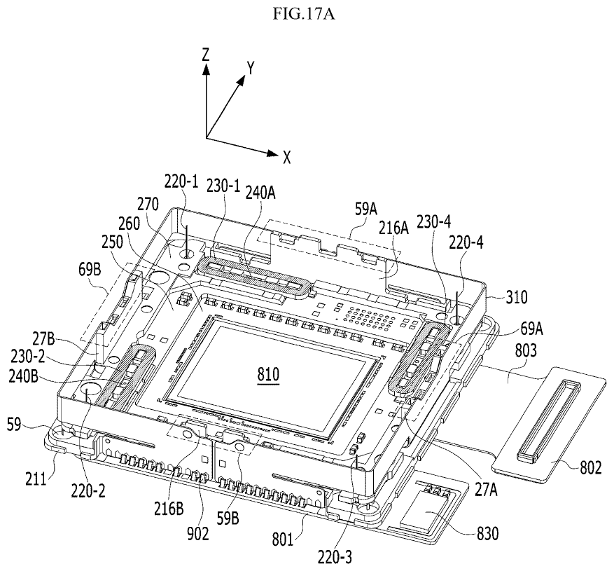

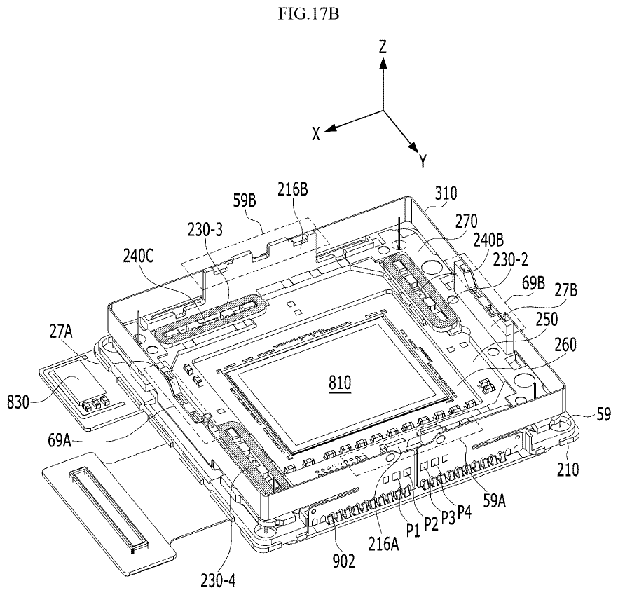

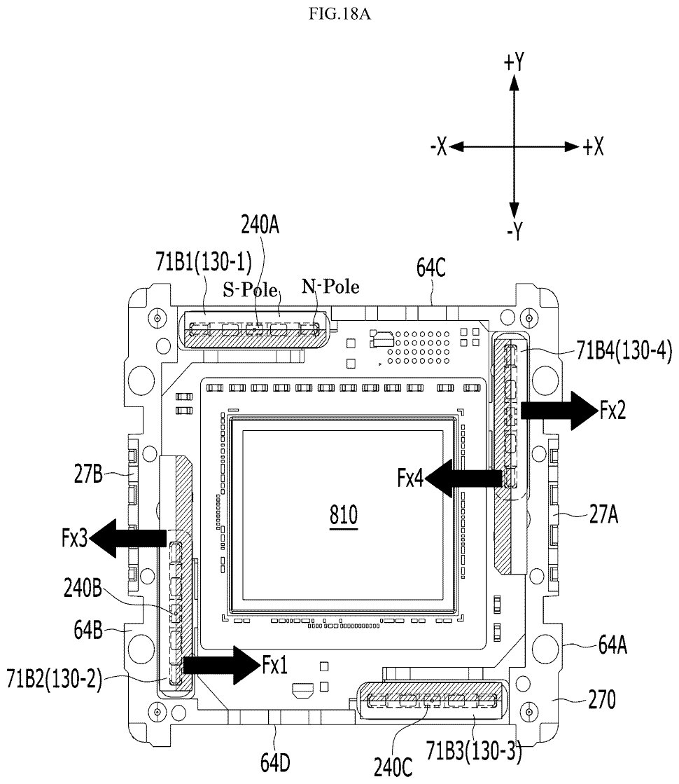

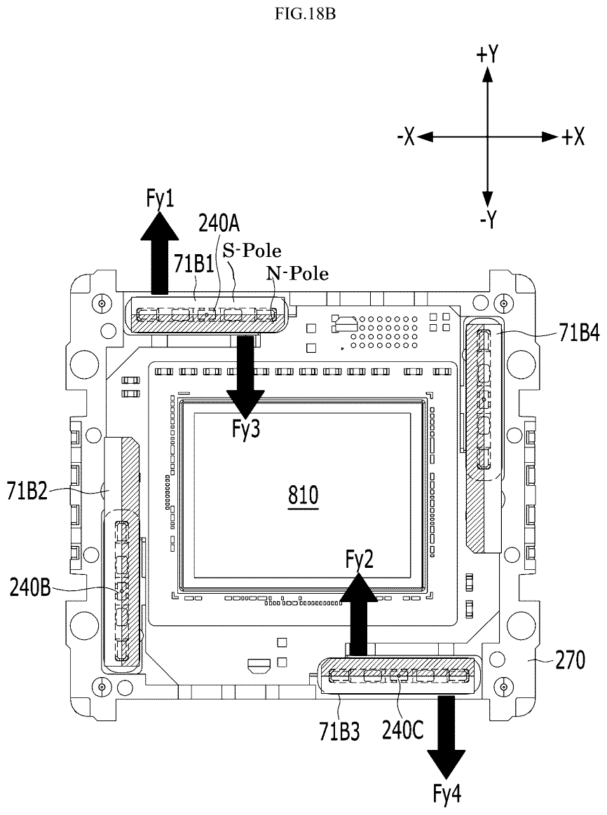

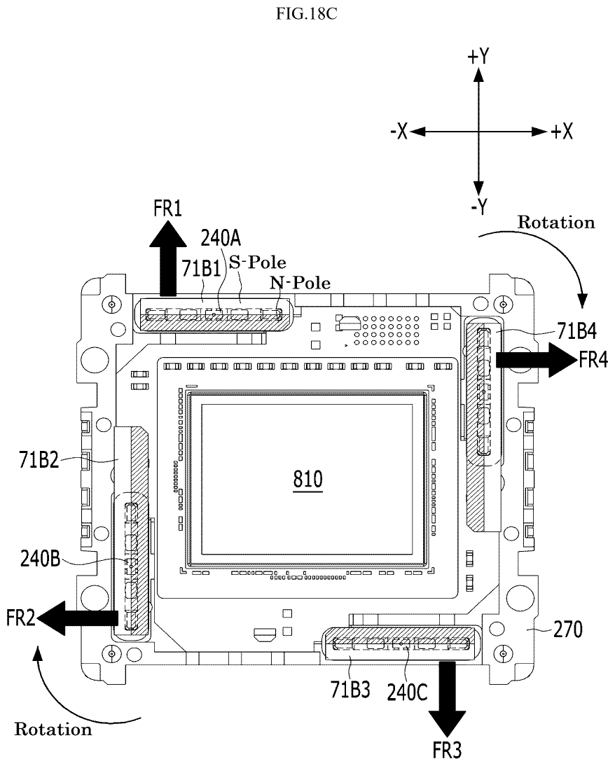

FIG. 18A is a view for explaining movement of the OIS moving unit in the X-axis direction, and FIG. 18B is a view for explaining movement of the OIS moving unit in the y-axis direction.

The N pole and the S pole of each of the first and third magnet units 71B1 and 71B3, which face each other in a first diagonal direction, may be disposed so as to face each other in the first horizontal direction (e.g., the Y-axis direction). In addition, the N pole and the S pole of each of the second and fourth magnet units 71B2 and 71B4, which face each other in a second diagonal direction, which is perpendicular to the first diagonal direction, may be disposed so as to face each other in the second horizontal direction (e.g., the X-axis direction).

That is, the direction in which the N pole and the S pole of the first magnet unit 71B1 face each other may be the same as or parallel to the direction in which the N pole and the S pole of the third magnet unit 71B3 face each other. In addition, the direction in which the N pole and the S pole of the second magnet unit 71B2 face each other may be the same as or parallel to the direction in which the N pole and the S pole of the fourth magnet unit 71B4 face each other.

In another embodiment in which the second magnet 71B is a 2-pole magnet, based on the boundary line (or the interface) between the N pole and the S pole of each of the first to fourth magnet units 71B1 to 71B4, the N pole thereof may be located at an inward position, and the S pole thereof may be located at an outward position. In another embodiment, based on the boundary line between the N pole and the S pole of each of the first to fourth magnet units 71B1 to 71B4, the S pole thereof may be located at an inward position, and the N pole thereof may be located at an outward position. The boundary line (or the interface) may be a portion that separates the N pole and the S pole from each other and has substantially no magnetism and thus almost no polarity.

Referring to FIG. 18A, the OIS moving unit may be moved or shifted in the X-axis direction by first electromagnetic force Fx1 (or Fx3) generated by interaction between the second coil unit 230-2 and the second magnet unit 71B2 and second electromagnetic force Fx2 (or Fx4) generated by interaction between the fourth coil unit 230-4 and the fourth magnet unit 71B4. In an example, the direction of the first electromagnetic force Fx1 (or Fx3) and the direction of the second electromagnetic force Fx2 (or Fx4) may be the same as each other.

Referring to FIG. 18B, the OIS moving unit may be moved or shifted in the y-axis direction by third electromagnetic force Fy1 (or Fy3) generated by interaction between the first coil unit 230-1 and the first magnet unit 71B1 and fourth electromagnetic force Fy2 (or Fy4) generated by interaction between the third coil unit 230-3 and the third magnet unit 71B3. In an example, the direction of the third electromagnetic force Fy1 (or Fy3) and the direction of the fourth electromagnetic force Fy2 (or Fy4) may be the same as each other.

FIG. 18C is a view for explaining rotation of the OIS moving unit in the clockwise direction in the four-channel drive mode, and FIG. 18D is a view for explaining rotation of the OIS moving unit in the counterclockwise direction in the four-channel drive mode.

Referring to FIG. 18C, the OIS moving unit may be rotated, tilted, or rolled in the clockwise direction about the optical axis or with respect to the optical axis by first electromagnetic force FR1 generated by interaction between the first coil unit 230-1 and the first magnet unit 71B1, second electromagnetic force FR2 generated by interaction between the second coil unit 230-2 and the second magnet unit 71B2, third electromagnetic force FR3 generated by interaction between the third coil unit 230-3 and the third magnet unit 71B3, and fourth electromagnetic force FR4 generated by interaction between the fourth coil unit 230-4 and the fourth magnet unit 71B4.

In addition, referring to FIG. 18D, the OIS moving unit may be rotated, tilted, or rolled in the counterclockwise direction about the optical axis or with respect to the optical axis by first electromagnetic force FL1 generated by interaction between the first coil unit 230-1 and the first magnet unit 71B1, second electromagnetic force FL2 generated by interaction between the second coil unit 230-2 and the second magnet unit 71B2, third electromagnetic force FL3 generated by interaction between the third coil unit 230-3 and the third magnet unit 71B3, and fourth electromagnetic force FL4 generated by interaction between the fourth coil unit 230-4 and the fourth magnet unit 71B4.

In an example, the direction of the first electromagnetic force FR1 (or FL1) and the direction of the third electromagnetic force FR3 (or FL3) may be opposite each other. In addition, in an example, the direction of the second electromagnetic force FR2 (or FL2) and the direction of the fourth electromagnetic force FR4 (or FL4) may be opposite each other. In addition, in an example, the direction of the first electromagnetic force FR1 (or FL1) and the direction of the second electromagnetic force FR2 (or FL2) may be perpendicular to each other.

In the case of the three-channel drive mode, a driving signal may not be supplied to two coil units (e.g., 130-1 and 130-3, or 130-2 and 130-4) connected in series to each other, and thus, no electromagnetic force may be generated by the two coil units connected in series to each other. In an example, in the case of the three-channel drive mode, FR2 and FR4 may be omitted, and FR1 and FR3 may be present in FIG. 18C. Alternatively, in the case of the three-channel drive mode, FR2 and FR4 may be present, and FR1 and FR3 may be omitted in FIG. 18C. In addition, in the case of the three-channel drive mode, FL2 and FL4 may be omitted, and FL1 and FL3 may be present in FIG. 18D. Alternatively, in the case of the three-channel drive mode, FL2 and FL4 may be present, and FL1 and FL3 may be omitted in FIG. 18D.

Compared to the three-channel drive mode, according to the four-channel drive mode shown in FIGS. 18C and 18D, the electromagnetic force for rotation of the OIS moving unit may be increased, and accordingly, the amount of driving current required to drive the first to fourth coil units 230-1 to 230-4 may be reduced, and thus, power consumption may be reduced.

In the embodiment shown in FIG. 2, OIS driving for hand-tremor compensation is performed using the second magnet 71B and the second coil 230. However, in another embodiment, OIS driving for hand-tremor compensation may be performed using a shape-memory-alloy member. In an example, the shape-memory-alloy member may be coupled to the fixed unit and the OIS moving unit and may be conductively connected to the first board unit 255. The controller 830 or 780 may supply a driving signal to the shape-memory-alloy member and may move the OIS moving unit in a direction perpendicular to the optical axis or may rotate, tilt, or roll the OIS moving unit about the optical axis using the shape-memory-alloy member.

In still another embodiment, OIS driving may be performed using the second magnet 71B and the second coil 230, and the camera device 10 may include a ball member (not shown), which is disposed between the base 210 and the holder 270 in order to support the OIS moving unit. In this case, the ball member may support the OIS moving unit using frictional force and/or rolling force between the base 210 and the holder 270 so that the OIS moving unit is moved in a direction perpendicular to the optical axis or is rotated, tilted, or rolled about the optical axis. In an example, the ball member may be disposed in the hole 59 in the base 210 and may be in contact with each of the base 210 and the holder 270. In another embodiment, the ball member may be provided, and the terminal unit 37 and the wire 220 may be omitted.

The second position sensor 240 may be disposed on, coupled to, or mounted on the first surface (e.g., the upper surface) of the first circuit board 250. The second position sensor 240 may detect movement or displacement of the OIS moving unit in a direction perpendicular to the optical-axis direction, for example, shift or movement of the OIS moving unit in a direction perpendicular to the optical-axis direction. In addition, the second position sensor 240 may detect rotation, rolling, or tilting of the OIS moving unit within a predetermined range about the optical axis or with respect to the optical axis. The first position sensor 170 may alternatively be referred to as an “AF position sensor”, and the second position sensor 240 may alternatively be referred to as an “OIS position sensor”.

The second position sensor 240 may oppose or overlap the magnet 130 in the optical-axis direction. In an example, the second position sensor 240 may oppose or overlap the second magnet 71B in the optical-axis direction. In an example, the second position sensor 240 may include three or more sensors corresponding to or overlapping three or more magnet units among the four magnet units 71B1 to 71B4 of the second magnet 71B in the optical-axis direction in order to detect movement of the OIS moving unit.

In an example, the second position sensor 240 may be disposed below the second coil 230.

In an example, the second position sensor 240 may not overlap the second coil 230 in a direction perpendicular to the optical axis. In an example, the sensing element of the second position sensor 240 may not overlap the second coil 230 in a direction perpendicular to the optical axis. The sensing element may be a portion that detects a magnetic field.

In an example, the center of the second position sensor 240 may not overlap the second coil 230 in a direction perpendicular to the optical axis. In an example, the center of the second position sensor 240 may be a spatial center in the x-axis and y-axis directions in an xy-coordinate plane perpendicular to the optical axis. Alternatively, the center of the second position sensor 240 may be a spatial center in the x-axis, y-axis, and z-axis directions.

In another embodiment, at least a portion of the second position sensor 240 may overlap the second coil 230 in a direction perpendicular to the optical axis.

In an example, the second position sensor 240 may overlap the holes 41A to 41C in the holder 270 in the optical-axis direction. In addition, in an example, the second position sensor 240 may overlap the cavity in the second coil 230 in the optical-axis direction. In addition, in an example, at least some of the holes 41A to 41C in the holder 270 may overlap the cavity in the second coil 230 in the optical-axis direction.

In an example, at least a portion of the second position sensor 240, for example, the center of the second position sensor 240, may not overlap the second coil 230 in the optical-axis direction.

In an example, the second position sensor 240 may include a first sensor 240A, a second sensor 240B, and a third sensor 240C, which are spaced apart from one another.

For example, each of the first to third sensors 240A, 240B, and 240C may be a Hall sensor. In another embodiment, each of the first to third sensors 240A, 240B, and 240C may be a driver IC including a Hall sensor and a driver. The description of the first position sensor 170 may be equally or similarly applied to the first to third sensors 240A, 240B, and 240C. Each of the first to third sensors 240A, 240B, and 240C may be, for example, a displacement detection sensor, the output voltage of which varies depending on the positional relationship with a magnet unit corresponding thereto.

Each of the first sensor 240A, the second sensor 240B, and the third sensor 240C may be conductively connected to the first circuit board 250.

The second position sensor 240 may be disposed below the cavity in the second coil 230. In another embodiment, when viewed in the optical-axis direction or viewed from above, the second position sensor 240 may be disposed outside the second coil 230.

The second position sensor 240 may not overlap the second coil 230 in a direction perpendicular to the optical-axis direction. In an example, the second position sensor 240 may overlap the holder 270 in a direction perpendicular to the optical-axis direction.

In an example, the first sensor 240A may be disposed below the cavity in the first coil unit 230-1. The first sensor 240A may be disposed in a hole 41A corresponding thereto among the holes 41A to 41C in the holder 270. The second sensor 240B may be disposed below the cavity in the second coil unit 230-2. The second sensor 240B may be disposed in a hole 41B corresponding thereto among the holes 41A to 41C in the holder 270. The third sensor 240C may be disposed below the cavity in the third coil unit 230-3. The third sensor 240C may be disposed in a hole 41C corresponding thereto among the holes 41A to 41C in the holder 270.

In an example, each of the first to third sensors 240A, 240B, and 240C may not overlap a corresponding one of the coil units 230-1 to 230-3 in a direction perpendicular to the optical axis. The first to third sensors 240A, 240B, and 240C may overlap the holder 270 in a direction perpendicular to the optical axis.

Since the first to third sensors 240A, 240B, and 240C are disposed so as not to overlap the OIS coil 230 in a direction perpendicular to the optical axis, the influence of the magnetic field of the OIS coil 230 on the output of the OIS position sensor 240 may be reduced, and accordingly, it is possible to accurately perform OIS feedback driving and to ensure the reliability of OIS operation.

The second position sensor 240 may oppose, correspond to, or overlap the magnet 130 in the optical-axis direction. In an example, at the initial position of the OIS moving unit, at least a portion of the first sensor 240A may overlap the first magnet unit 71B1 of the second magnet 71B in the optical-axis direction. The first sensor 240A may output a first output signal (e.g., first output voltage) corresponding to a result of detection of the magnetic field of the first magnet unit 71B1.

In an example, at the initial position of the OIS moving unit, at least a portion of the second sensor 240B may overlap the second magnet unit 71B2 of the second magnet 71B in the optical-axis direction. The second sensor 240B may output a second output signal (e.g., second output voltage) corresponding to a result of detection of the magnetic field of the second magnet unit 71B2.

In addition, in an example, at the initial position of the OIS moving unit, at least a portion of the third sensor 240C may overlap the third magnet unit 71B3 of the second magnet 71B in the optical-axis direction. The third sensor 240C may output a third output signal (e.g., third output voltage) corresponding to a result of detection of the magnetic field of the third magnet unit 71B3.

The initial position of the OIS moving unit may be the original position of the OIS moving unit in a state in which no power or driving signal is applied to the second coil 230 from the controller 830 or 780 or a position at which the OIS moving unit is located as a result of the support board being elastically deformed due only to the weight of the OIS moving unit. In addition, the initial position of the OIS moving unit may be a position at which the OIS moving unit is located when gravity acts in a direction from the first board unit 255 toward the second board unit 800 or when gravity acts in the opposite direction.

In order to improve the linearity of the relationship between the displacement of the OIS moving unit and the output from the second position sensor 250, each of the sensor units 240A, 240B, and 240C may overlap a corresponding one of the magnet units 71B1, 71B2, and 71B3 within the stroke range of the OIS moving unit in the optical-axis direction.

In an example, the controller 830 or 780 may control rolling of the OIS moving unit using at least one of first output voltage from the first sensor 240A, second output voltage from the second sensor 240B, or third output voltage from the third sensor 240C. In an example, the controller 830 or 780 may control rolling of the OIS moving unit using the first output voltage and the third output voltage.

In an example, the controller 830 or 780 may control or adjust movement or displacement of the OIS moving unit in the first horizontal direction (e.g., the y-axis direction) or the second horizontal direction (e.g., the x-axis direction) using at least one of the first to third output voltages. In an example, the controller 830 or 780 may control or adjust movement or displacement of the OIS moving unit in the first horizontal direction (e.g., the y-axis direction) using the first output voltage from the first sensor 240A and may control or adjust movement or displacement of the OIS moving unit in the second horizontal direction using the second output voltage from the second sensor 240B.

In an example, each of the first to third sensors 240A, 240B, and 240C may be a Hall sensor. In another embodiment, each of the first to third sensors may be a driver IC including a Hall sensor. In still another embodiment, each of the first and second sensors 240A and 240B may be a Hall sensor, and the third sensor 240C may be a tunnel magnetoresistance (TMR) sensor. In this case, the tunnel magnetoresistance (TMR) sensor may be a TMR magnetic angle sensor.

In still another embodiment, each of the first to third sensors 240A, 240B, and 240C may be a tunnel magnetoresistance (TMR) sensor. In this case, the TMR sensor may be a TMR linear magnetic field sensor having a linear output corresponding to the displacement (or the stroke) of the OIS moving unit.

The base 210 may be disposed below the first board unit 255. The base 210 may be spaced apart from the first board unit 255. The base 210 may have a polygonal shape, for example, a quadrangular shape, which coincides with or corresponds to the shape of the cover member 300 or the first board unit 255.

In an example, the base 210 may include a bore 210A formed therein so as to correspond to or oppose the first board unit 255. The bore 210A in the base 210 may be a through-hole formed through the base 210 in the optical-axis direction. In another embodiment, the base may not include a bore therein.

In an example, the base 210 may be coupled to the side plate 302 of the cover member 300. The base 210 may be provided on the side portion or the outer side surface thereof with a stair 211 (refer to FIG. 14), to which an adhesive is applied in order to be adhered to the side plate 302 of the cover member 300. In this case, the stair 211 may guide the side plate 302 of the cover member 300, which is coupled to the upper side thereof. The stair 211 of the base 210 and the lower end of the side plate 302 of the cover member 300 may be adhered and fixed to each other by means of an adhesive or the like.

The base 210 may include at least one protruding portion 216A or 216B protruding from the upper surface thereof. In an example, the protruding portion 216A or 216B may protrude upward from the outer side surface of the base 210. In an example, the base 210 may include two protruding portions 216A and 216B, which oppose or overlap each other in the first horizontal direction (e.g., the Y-axis direction).

In an example, the base 210 may include four side portions (or side plates), and the protruding portions 216A and 216B may be formed on two side portions among the four side portions. In an example, each of the protruding portions 216A and 216B may be disposed or located at the center of a corresponding one of the side portions (or the side plates) of the base 210.

The base 210 may include a groove 341b formed therein. The groove 341b may be an adhesive-receiving groove. The groove 341b may be formed in the outer side surface of each of the protruding portions 216A and 216B of the base 210. The groove 341b may be formed in the upper surface of each of the protruding portions 216A and 216B of the base 210. The groove 341b may be formed from the upper surface of each of the protruding portions 216A and 216B of the base 210 to the lower surface thereof. An adhesive, by which the support board 310 is adhered to the base 210, may be disposed in the groove 341b. The groove 341b may include a plurality of grooves. In an example, the groove 341b may extend in the optical-axis direction. In another embodiment, the groove formed in each of the protruding portions 216A and 216B of the base 210 may extend in a direction perpendicular to the optical axis.

The second board unit 800 may be disposed beneath the base 210. In an example, the second board unit 800 may be disposed so as to be spaced apart from the OIS moving unit, for example, the first board unit 255 and the first heat dissipation member 280, in the optical-axis direction.

In an example, the second board unit 800 may be disposed on the lower surface of the base 210. The second board unit 800 may be coupled to the base 210. In an example, the second board unit 800 may be coupled to the lower surface of the base 210.

The second board unit 800 may serve to supply a signal from the outside to the image sensor unit 350 or to output a signal transmitted from the image sensor unit 350 to the outside.

The second board unit 800 may include a first region (or first board) 801, which corresponds to, opposes, or overlaps the AF driving unit 100 or the image sensor 810 in the optical-axis direction, a second region (or second board) 802, on which the connector 804 is disposed, and a third region (or third board) 803, which interconnects the first region 801 and the second region 802. The connector 804 may be provided with ports in order to be conductively connected to the second region 802 of the second board unit 800 and to be conductively connected to an external device (e.g., the optical instrument 200A). The bore 210A in the base 210 may be closed or blocked by the first region 801 of the second board unit 800.

The first region 801 of the second board unit 800 may correspond to, oppose, or overlap at least one of the cover member 300 or the base 210 in the optical-axis direction. In an example, the first region 801 may overlap the upper plate 301 and the side plate 302 of the cover member 300 in the optical-axis direction.

Each of the first region 801 and the second region 802 of the second board unit 800 may include a rigid substrate. The third region 803 may include a flexible substrate. In addition, each of the first region 801 and the second region 802 may further include a flexible substrate.

In another embodiment, at least one of the first to third regions 801 to 803 of the second board unit 800 may include at least one of a rigid substrate or a flexible substrate.

The second board unit 800 may be disposed behind the first board unit 255. In an example, the first board unit 255 may be disposed between the AF driving unit 100 and the second board unit 800. In another embodiment, the second board unit may be disposed between the AF driving unit and the first board unit.

When viewed from above, the first region 801 of the second board unit 800 may have a polygonal shape (e.g., quadrangular shape, square shape, or rectangular shape). However, the disclosure is not limited thereto. In another embodiment, the first region of the second board unit may have a circular shape.

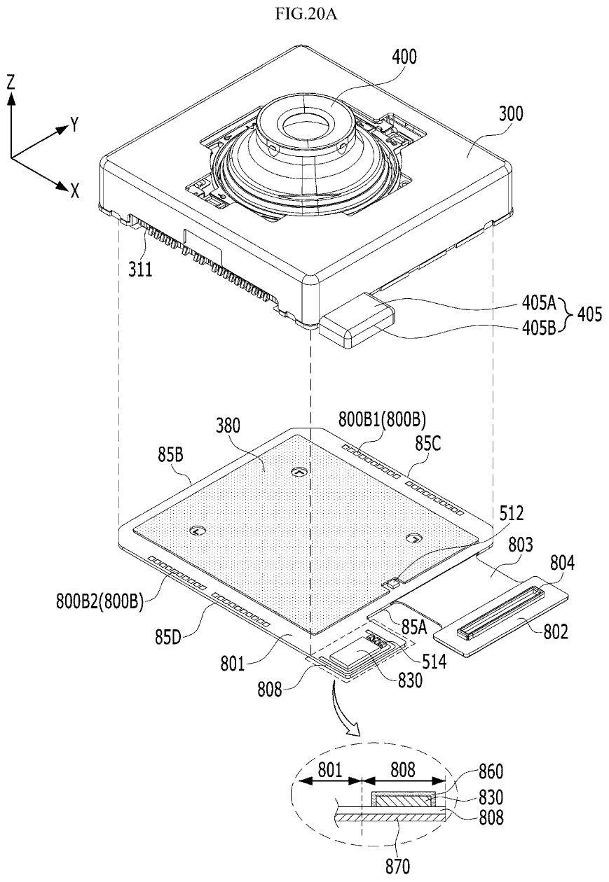

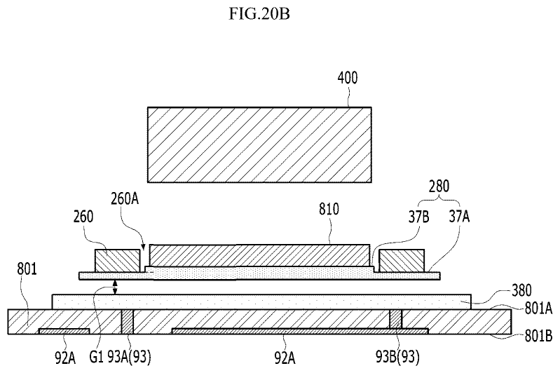

FIG. 20A is a view showing an embodiment of placement of the first to third regions 801 to 803 of the second board unit 800, the extension region 808, the AF moving unit, the OIS moving unit, and the controller 830.

Referring to FIG. 20A, the first region 801 may include four side portions (or side surfaces) 85A to 85D. In an example, the first region 801 may include first and second side portions 85A and 85B, which oppose each other or are located opposite each other in the second horizontal direction (e.g., the X-axis direction), and third and fourth side portions 85C and 85D, which oppose each other or are located opposite each other in the first horizontal direction (e.g., the Y-axis direction).

The second region 802 may be disposed adjacent to the first side portion 85A of the first region 801, and the third region 803 may be connected to the first side portion 85A of the first region 801. In an example, the third region 803 may extend from the first region 801 and may be connected to the side of the second region 802 that opposes the first side portion 85A. In an example, the third region 803 may be spaced apart from the extension region 808.

The second board unit 800 may include a plurality of terminals 800B corresponding to terminals 311 of the support board 310. The plurality of terminals 800B may be formed in the first region 801 of the second board unit 800. In an example, the second board unit 800 may include first terminals 800B1, which are disposed or arranged so as to be spaced apart from each other in the second horizontal direction (e.g., the X-axis direction) along the side of the third side portion 85C of the first region 801, and second terminals 800B2, which are disposed or arranged so as to be spaced apart from each other in the second horizontal direction along the side of the fourth side portion 85D of the first region 801.

In an example, the plurality of terminals 800B may be formed on the first surface (e.g., the upper surface) of the second board unit 800 (e.g., the first region 801), which faces the first board unit 255.

In an example, the controller 830 may be disposed in the extension region extending from any one of the third and fourth side portions 85C and 85D of the first region 801 of the second board unit 800. In another embodiment, the controller may be disposed in the extension region extending from the side portion of the first region 801 of the second board unit 800, on which the plurality of terminals is formed.

A coupling hole (not shown) may be formed in the first region 801, and a coupling protrusion (not shown) may be formed on the base 210 in order to be coupled to the coupling hole in the first region 801.

The camera device 10 may further include a second heat dissipation member 380, which is disposed on, coupled to, or fixed to the second board unit 800. In an example, the second heat dissipation member 380 may be disposed on, coupled to, or fixed to the upper surface of the first region 801 of the second board unit 800. In another embodiment, the second heat dissipation member 380 may be omitted.

The camera device 10 may further include a third heat dissipation member (not shown), which is disposed on, coupled to, or fixed to the second surface (e.g., the lower surface) of the second board unit 800.

In an example, the second heat dissipation member 380 may be a plate-type member having a predetermined thickness and hardness. In addition, the second heat dissipation member 380 may oppose or overlap the first heat dissipation member 280 in the optical-axis direction.

Referring to FIG. 20A, the controller 830 may be disposed on or coupled to the upper surface of the extension region 808. In another embodiment, the controller may be disposed on or coupled to the lower surface of the extension region 808.

Referring to FIG. 20A, the controller 830 may be disposed in the extension region 808 of the second board unit 800, which is located outside the cover member 300. In another embodiment, the controller may be disposed in the first region of the second board unit 800, which is located outside the base 210.

In still another embodiment, the controller may be disposed or mounted on the second circuit board 260, which is a sensor board. In another embodiment, the controller may be disposed or mounted on the upper surface of the second circuit board 260. Since the heat dissipation member 280 is disposed on or coupled to the lower surface of the second circuit board 260, when the controller is disposed on the second circuit board 260, heat generated from the controller may be easily dissipated by the heat dissipation member 280, and accordingly, heat dissipation efficiency may be improved.

FIG. 20B is a schematic cross-sectional view of the lens module 400, the first board unit 255, the image sensor 810, the first heat dissipation member 280, the second board unit 800, and the second heat dissipation member 380 in FIG. 10A.

Referring to FIG. 20B, the image sensor 810 may be disposed in the bore (or the hole) 260A in the second circuit board 260 and may be coupled to the first heat dissipation member 280.

In an example, the first heat dissipation member 280 may include a body 37A, which is disposed beneath the second circuit board 260, and a protruding portion (or protruding region) 37B, which protrudes from the body 37A and is disposed in the bore 260A in the second circuit board 260.

The image sensor 810 may be disposed on, coupled to, or fixed to the protruding portion 37B. In an example, the image sensor 810 may be disposed on, coupled to, or attached to the upper surface of the protruding portion 37B. In an example, the upper surface of the protruding portion 37B may be located at a lower position than the upper surface of the second circuit board 260. In another embodiment, the upper surface of the protruding portion 37B may be located at the same height as the upper surface of the second circuit board 260.

The second heat dissipation member 380 may be disposed on the first surface 801A (or the upper surface) of the first region 801 of the second board unit 800, which opposes the first heat dissipation member 280 in the optical-axis direction.

A spacing distance (or gap) G1 between the first board unit 255 and the second board unit 800 in the optical-axis direction may be 0.05 mm to 0.7 mm. In an example, the spacing distance G1 may be a distance from the lower surface of the first heat dissipation member 280 to the upper surface of the second heat dissipation member 380.

In another embodiment, G1 may be 0.15 mm to 0.5 mm. In still another embodiment, G1 may be 0.15 mm to 0.3 mm. In still another embodiment, G1 may be 0.2 mm to 0.3 mm.

The second board unit 800 may include a first conductive layer 93, which is exposed to the first surface 801A and is in contact with the second heat dissipation member 380, for example, the lower surface of the second heat dissipation member 380. In an example, the first conductive layer 93 may be thermally bonded to the lower surface of the second heat dissipation member 380 or may be coupled to the lower surface of the second heat dissipation member 380 by means of a conductive adhesive, for example, a solder. In addition, in an example, the first conductive layer 93 may be conductively connected to the second heat dissipation member 380.

The second board unit 800 may include a second conductive layer 92A, which is connected to the first conductive layer 93 and is exposed from the second surface 801B (or the lower surface) of the second board unit 800, which is a surface opposite the first surface 801A of the second board unit 800. In an example, the second conductive layer 92A may be conductively connected to the ground of the second board unit 800.

The first conductive layer 93 may take the form of a via, which is formed through at least a portion of the second board unit 800. In an example, the first conductive layer 93 may include a first via 93A formed through the second board unit 800 so as to be open or exposed to the second surface 801B of the second board unit 800. In addition, one end of the first conductive layer 93 may be in contact with the lower surface of the second heat dissipation member 380, and the other end thereof may include a second via 93B formed therein so as to be in contact with, coupled to, or connected to the second conductive layer 92A.

Referring to FIG. 20B, the second conductive layer 92A may be disposed in, coupled to, or attached to a recess formed in the second surface 801B of the second board unit 800. In another embodiment, the second conductive layer may be disposed on, coupled to, or attached to the second surface 801B of the second board unit 800, which is a flat surface in which no recess is formed.

Each of the first conductive layer 93 and the second conductive layer 92A may serve as a heat dissipation pattern or a heat dissipation pad for dissipating heat from the second board unit 800. That is, because the first conductive layer 93 and the second conductive layer 92A are provided only for the purpose of heat dissipation, the first conductive layer 93 and the second conductive layer 92A may not be conductively connected to wires of the second board unit 800 other than the ground of the second board unit. In this case, the other wires may be wires conductively connected to the controller 830 or 780, an electronic element (or circuit element) such as the image sensor 810, or the support board 310.

The second conductive layer 92A may be conductively connected to the cover member 300 (e.g., the side plate 302) via a solder, a conductive adhesive, or a sheet of conductive tape. Alternatively, in another embodiment, the second conductive layer 92A, which is connected to the ground of the second board unit 800, may be conductively connected to the cover member 300 via a bracket. The bracket may be a structure in which the camera device is accommodated or received in order to protect the camera device. In an example, the bracket may be formed of a conductive material. Since the ground of the second board unit 800, the second heat dissipation member 380, and the cover member 300 are conductively connected to one another, it is possible to protect the camera device 10 from static electricity and to improve heat dissipation efficiency.

In another embodiment, at least one of the first conductive layer or the second conductive layer of the second board unit 800 may be equally or similarly applied to the second circuit board 260. In an example, the second circuit board 260 according to another embodiment may include at least one third conductive layer, which is in contact with the first heat dissipation member 280, and at least a portion of the third conductive layer may be exposed from the second circuit board 260.

Since the second heat dissipation member 380 is disposed on the first surface of the second board unit 800, the spacing distance from the first heat dissipation member 280 may be reduced, and accordingly, heat dissipation efficiency may be improved.

The heat dissipated from the first heat dissipation member 280 may be transferred to the second heat dissipation member 380 through convection or radiation, and the transferred heat may be dissipated outside through the second heat dissipation member 380. Accordingly, heat dissipation effect may be improved. Since the upper surface of the second heat dissipation member 380 and the lower surface of the first heat dissipation member 280 are disposed so as to face or overlap each other in the optical-axis direction, heat may be smoothly transferred from the first heat dissipation member 280 to the second heat dissipation member 380.

In an example, the first heat dissipation member 280 and the second heat dissipation member 380 may be formed of the same material. In another embodiment, the first heat dissipation member 280 and the second heat dissipation member 380 may be formed of different materials. In an example, the thermal conductivity of the first heat dissipation member 280 may be equally or similarly applied to the second heat dissipation member 380.

In addition, the second heat dissipation member 380 may serve as a reinforcing member for stably supporting the second board unit 800 and suppressing the second board unit 800 from being damaged by external impact or contact.

In another embodiment, the second heat dissipation member 380 may be formed of a heat dissipation material having high thermal conductivity, for example, heat dissipation epoxy, heat dissipation plastic, or heat dissipation synthetic resin.

The second heat dissipation member 380 may include at least one groove or at least one uneven portion in order to improve heat dissipation effect. In an example, a groove or an uneven portion having a predetermined pattern may be formed in at least one of the upper surface or the lower surface of the second heat dissipation member 380.

In another embodiment, the second heat dissipation member may include a hole or a through-hole in place of the groove. In an example, the second heat dissipation member according to another embodiment may include a plurality of through-holes. The description of the predetermined pattern of the first heat dissipation member 280 may be equally or similarly applied to the second heat dissipation member 380.

The support board 310 may support the OIS moving unit so that the OIS moving unit is moved relative to the fixed unit in a direction perpendicular to the optical-axis direction, and may conductively connect the first board unit 255 to the second board unit 800. The support board 310 may alternatively be referred to as a “support member”, a “connection board”, or a “connection part”. Alternatively, the support board 310 may be referred to as an “interposer”. Alternatively, the first circuit board 250 and the support board 310 may be referred to as an “interposer board”.

The support board 310 may include a flexible substrate or may be a flexible substrate. In an example, the support board 310 may include a flexible printed circuit board (FPCB). At least a portion of the support board 310 may be flexible. The first circuit board 250 and the support board 310 may be connected to each other.

Referring to FIG. 16, in an example, the support board 310 may include a connection portion 320, which is connected to the first circuit board 250. In an example, the first circuit board 250 and the support board 310 may be integrally formed with each other. In another embodiment, the first circuit board 250 and the support board 310 may be provided separately from each other, rather than being integrated, may be connected to each other via the connection portion 320, and may be conductively connected to each other. Alternatively, in another embodiment, the connection portion 320 may be integrally formed with at least one of the support board 310 or the first circuit board 250.

In addition, the support board 310 may be conductively connected to the first circuit board 250. The support board 310 may be conductively connected to the second board unit 800.

The support board 310 may support the OIS moving unit with respect to the fixed unit. In addition, the support board 310 may guide movement of the OIS moving unit. The support board 310 may guide the OIS moving unit to move in a direction perpendicular to the optical-axis direction. The support board 310 may guide the OIS moving unit to rotate, tilt, or roll about the optical axis. The support board 310 may restrict movement of the OIS moving unit in the optical-axis direction.

A portion of the support board 310 may be coupled, attached, or fixed to the base 210, which is the fixed unit, and the other portion of the support board 310 may be coupled, attached, or fixed to the holder 270, which is the OIS moving unit. In an example, the bodies 86 and 87 of the support board 310 may be coupled to the protruding portions 216A and 216B of the base 210 and the protruding portions 27A and 27B of the holder 270. The terminal units 7A to 7D of the support board 310 may be coupled to the terminals 800B of the second board unit 800 and may be conductively connected thereto.

The support board 310 may include a circuit member 310A and an elastic unit 310B coupled to the circuit member 310A. The elastic unit 310B serves to elastically support the OIS moving unit, and may be implemented as an elastic body, for example, a spring. The elastic unit 310B may include metal or may be made of an elastic material. The circuit member serves to conductively connect the first circuit board 250 to the second board unit 800, and may be a flexible substrate or may include at least one of a flexible substrate or a rigid substrate. The circuit member may be, for example, an FPCB.

The support board 310 may be connected to the first board unit 255 (e.g., the first circuit board 250) and may include at least one connection portion 320A or 320B, which is conductively connected to the first board unit 255 (e.g., the first circuit board 250). In addition, the support board 310 may include at least one terminal unit 7A to 7D, which is connected to the second board unit 800 and is conductively connected to the second board unit 800, and the at least one terminal unit 7A to 7D may include a plurality of terminals 311.

The support board 310 may include bodies 86 and 87. In addition, the support board 310 may include extension portions extending from the bodies 86 and 87. In an example, the extension portions of the support board 310 may include portions extending toward the second board unit 800. Here, the extension portions may alternatively be referred to as “protruding portions”.

In addition, in an example, the extension portions of the support board 310 may include terminals units 7A to 7D. Alternatively, in an example, the terminal units 7A to 7D may be disposed or formed on the extension portions of the support board 310. In an example, when the OIS moving unit is moved, at least a portion of each of the bodies 86 and 87 may be moved, and the other portion of each of the bodies 86 and 87 may be fixed to the fixed unit (e.g., the base 210). The terminal units 7A to 7D may be fixed to the fixed unit (e.g., the base 210 and/or the second board unit 800).

In an example, the support board 310 may include a first support board 310-1 and a second support board 310-2, which are spaced apart from each other. The first and second support boards 310-1 and 310-2 may be formed to be bilaterally symmetrical with each other. In another embodiment, the first support board 310-1 and the second support board 310-2 may be integrated into a single board. In still another embodiment, the support board 310 may include three or more support boards.

The first and second support boards 310-1 and 310-2 may be disposed on respective sides of the first circuit board 250. In an example, the first support board 310-1 may include a first body 86 and at least one terminal unit 7A or 7B extending from the first body 86. The at least one terminal unit 7A or 7B of the first support board 310-1 may include a plurality of terminals 311.

The second support board 310-2 may include a second body 87 and at least one terminal unit 7C or 7D extending from the second body 87. The at least one terminal unit 7C or 7D of the second support board 310-2 may include a plurality of terminals 311.

The first circuit board 250 may include a first side portion 33A and a second side portion 33B, which are located opposite each other, and may include a third side portion 33C and a fourth side portion 33D, which are located between the first side portion 33A and the second side portion 33B and are located opposite each other.

In an example, the first connection portion 320A may connect the first body 86 to the first side portion 33A of the first circuit board 250, and the second connection portion 320B may connect the second body 87 to the second side portion 33B of the first circuit board 250.

The first body 86 may include a first portion 6A, which corresponds to or opposes the first side portion 33A of the first circuit board 250, a second portion 6B, which corresponds to a portion (or one side) of the third side portion 33C of the first circuit board 250, and a third portion 6C, which corresponds to a portion (or one side) of the fourth side portion 33D of the first circuit board 250. In addition, the first body 86 may include a first bent portion 6D, which connects one end of the first portion 6A to the second portion 6B and is bent from the end of the first portion 6A, and a second bent portion 6E, which connects the other end of the first portion 6A to the third portion 6C and is bent from the other end of the first portion 6A.

In an example, the first support board 310-1 may include a first terminal unit 7A and a second terminal unit 7B. In an example, the first terminal unit 7A may extend or protrude from the second portion 6B of the first body 86 toward the second board unit 800, and the second terminal unit 7B may extend or protrude from the third portion 6C of the first body 86 toward the second board unit 800. The second terminal unit 7B may be located opposite the first terminal unit 7A with the first board unit 255 (e.g., the first circuit board 250) interposed therebetween.

In an example, the first connection portion 320A may connect the first portion 6A of the first body 86 to the first side portion 33A of the first circuit board 250. The first connection portion 320A may include a bent portion.

The second body 87 may include a first portion 9A, which corresponds to or opposes the second side portion 33B of the first circuit board 250, a second portion 9B, which corresponds to or opposes another portion (or the opposite side) of the third side portion 33C of the first circuit board 250, and a third portion 9C, which corresponds to or opposes another portion (or the opposite side) of the fourth side portion 33D of the first circuit board 250. In addition, the second body 87 may include a first bent portion 9D, which connects one end of the first portion 9A to the second portion 9B and is bent from the end of the first portion 9A, and a second bent portion 9E, which connects the other end of the first portion 9A to the third portion 9C and is bent from the other end of the first portion 9A.

In an example, the second support board 310-2 may include a third terminal unit 7C and a fourth terminal unit 7D. The third terminal unit 7C may extend or protrude from the second portion 9B of the second body 87 toward the second board unit 800, and the fourth terminal unit 7D may extend or protrude from the third portion 9C of the second body 87 toward the second board unit 800. The fourth terminal unit 7D may be located opposite the third terminal unit 7C with the first board unit 255 (e.g., the first circuit board 250) interposed therebetween.

In an example, the second connection portion 320B may connect the first portion 9A of the second body 87 to the second side portion 33B of the first circuit board 250. The second connection portion 320B may include a bent portion.

The terminal units (e.g., 7A and 7C) of the support board 310 may be provided with terminals P1 to P4 in order to be conductively connected to the terminals B1 to B4 of the terminal unit 95 of the circuit board 190 of the AF driving unit 100. The terminals B1 to B4 of the terminal unit 95 of the circuit board 190 and the terminals P1 to P4 of the terminal units 7A and 7C of the support board 310 may be conductively connected to each other by means of a solder or a conductive adhesive. That is, the circuit board 190 of the AF driving unit 100 may be conductively connected to the second board unit 800 via the support board 310.

Referring to FIG. 16, the circuit member 310A of the support board 310 may include a first insulating layer 29A, a second insulating layer 29B, and a conductive layer 29C formed between the first insulating layer 29A and the second insulating layer 29B. The conductive layer 29C may be a wiring layer for transmitting an electrical signal. In an example, the second insulating layer 29B may be located outside the first insulating layer 29A.

Each of the first and second insulating layers 29A and 29B may be formed of an insulating material, such as polyimide, and the conductive layer 29C may be formed of a conductive material, such as copper, gold, or aluminum, or may be formed of an alloy including copper, gold, or aluminum.

The elastic unit 310B of the support board 310 may be disposed on the second layer 29B. The elastic unit 310B may include at least one of copper, titanium, or nickel, or may be formed of an alloy including at least one of copper, titanium, or nickel in order to serve as a spring. In an example, the elastic unit 310B may be formed of an alloy of copper and titanium or an alloy of copper and nickel.

The elastic unit 310B may be conductively connected to the first board unit 255 or the ground of the second board unit 800. The elastic unit 310B may be used for impedance matching of transmission lines (or wires) of the board units 255, 310, and 800, and may reduce loss of transmission signals through impedance matching to reduce the influence of noise. For example, the matching impedance may be 40 ohms to 600 ohms. For example, the matching impedance may be 50 ohms. For example, an EMI member (e.g., a sheet of EMI tape) or a conductive member (e.g., a sheet of conductive tape) may be used for impedance matching.

The support board 310 may include a metal member or a conductive member formed on the outer side surface thereof. For example, the metal member may be an EMI member (e.g., a sheet of EMI tape) or a conductive member (e.g., a sheet of conductive tape). In an example, the EMI member or the conductive member may be disposed on or attached to at least one of the elastic unit 310B or the circuit member 310A. The support board 310 may further include a protective material or an insulating material for surrounding or covering the elastic unit 310B.

FIG. 17A is a first perspective view of the support board 310 coupled to the holder 270 and to the base 210, and FIG. 17B is a second perspective view of the support board 310 coupled to the holder 270 and to the base 210.

Referring to FIGS. 17A and 17B, the holder 270 may include first to fourth side portions 64A to 64D (refer to FIG. 18A) corresponding to or opposing the first to fourth side portions 33A to 33D of the first circuit board 250.

The first and second side portions 64A and 64B of the holder 270 may oppose each other or may be disposed opposite each other in the second horizontal direction (e.g., the X-axis direction). In addition, the third and fourth side portions 64C and 64D of the holder 270 may oppose each other or may be disposed opposite each other in the first horizontal direction (e.g., the Y-axis direction).

At least a portion of the support board 310 may be attached or coupled to the holder 270. In an example, at least one connection portion 320A or 320B of the support board 310 may be coupled to at least one of the first to fourth side portions 64A to 64D of the holder 270 by means of an adhesive. In an example, the first connection portion 320A may be coupled, attached, or fixed to the first side portion 64A of the holder 270 by means of an adhesive, and the second connection portion 320B may be coupled, attached, or fixed to the second side portion 64B of the holder 270.

The holder 270 may be provided on the first side portion 64A thereof with a first protruding portion 27A, and may be provided on the second side portion 64B thereof with a second protruding portion 27B.

The support board 310 may be coupled, attached, or fixed to the protruding portions 27A and 27B of the holder 270. The support board 310 may be coupled, attached, or fixed to the outer side surfaces (or the inner side surfaces) of the protruding portions 27A and 27B of the holder 270.

In an example, a portion of the support board 310 may be coupled, attached, or fixed to the first protruding portion 27A and the second protruding portion 27B of the holder 270. The bodies 86 and 87 of the support board 310 may be coupled, attached, or fixed to the first and second protruding portions 27A and 27B of the holder 270.

In an example, the first support board 310-1 may be coupled, attached, or fixed to the first protruding portion 27A, and the second support board 310-2 may be coupled, attached, or fixed to the second protruding portion 27B. In an example, the first portion 6A of the first body 86 may be coupled, attached, or fixed to the outer side surface (or the inner side surface) of the first protruding portion 27A, and the first portion 9A of the second body 87 may be coupled, attached, or fixed to the outer side surface (or the inner side surface) of the second protruding portion 27B.

The base 210 may include first to fourth side portions 65A to 65D (refer to FIG. 14) corresponding to or opposing the first to fourth side portions 33A to 33D of the first circuit board 250. In addition, the first to fourth side portions 65A to 65D of the base 210 may correspond to or oppose the first to fourth side portions 64A to 64D of the holder 270.

The first and second side portions 65A and 65B of the base 210 may oppose each other or may be disposed opposite each other in the first horizontal direction (e.g., the Y-axis direction). In addition, the third and fourth side portions 65C and 65D of the base 210 may oppose each other or may be disposed opposite each other in the second horizontal direction (e.g., the X-axis direction).

At least a portion of the support board 310 may be coupled, attached, or fixed to the base 210. In an example, the bodies 86 and 87 of the support board 310 may be coupled to the base 210 by means of an adhesive. In an example, portions of the bodies 86 and 87 of the support board 310, which are connected to the terminal units 7A to 7D, may be coupled to the base 210.

In an example, at least a portion of the support board 310 may be coupled, attached, or fixed to the protruding portions 216A and 216B formed on the base 210. In an example, the support board 310 may be coupled, attached, or fixed to the outer side surfaces (or the inner side surfaces) of the protruding portions 216A and 216B of the base 210. The first protruding portion 216A may be formed on the third side portion 65C of the base 210, and the second protruding portion 216B may be formed on the fourth side portion 65D of the base 210.

In an example, the bodies 86 and 87 of the support board 310 may be coupled, attached, or fixed to the first and second protruding portions 216A and 216B of the base 210.

In an example, one end (e.g., the second portion 6B) of the first support board 310-1 may be coupled, attached, or fixed to one region of the first protruding portion 216A of the base 210, and the other end (e.g., the third portion 6C) of the first support board 310-1 may be coupled, attached, or fixed to one region of the second protruding portion 216B of the base 210.

In an example, one end (e.g., the second portion 9B) of the second support board 310-2 may be coupled, attached, or fixed to another region of the first protruding portion 216A of the base 210, and the other end (e.g., the third portion 9C) of the second support board 310-2 may be coupled, attached, or fixed to another region of the second protruding portion 216B of the base 210.

A first coupling region 69A may be formed between the first body 86 of the first support board 310-1 and the first protruding portion 27A of the holder 270, and a second coupling region 69B may be formed between the second body 87 of the second support board 310-2 and the second protruding portion 27B of the holder 270.

In addition, a third coupling region 59A may be formed between one end of each of the first and second support boards 310-1 and 310-2 and the first protruding portion 216A of the base 210. A fourth coupling region 59B may be formed between the other end of each of the first and second support boards 310-1 and 310-2 and the second protruding portion 216B of the base 210.

The OIS moving unit may be elastically supported with respect to the fixed unit by the support board 310 and the first to fourth coupling regions 69A, 69B, 59A, and 59B. The terminals 311 of the support board 310 may be coupled and conductively connected to the terminals 800B of the second board unit 800 by means of a solder 902 (refer to FIGS. 17A and 17B) or a conductive adhesive.

In another embodiment, the support member may be an elastic member including no substrate, for example, a spring, a wire, a shape memory alloy, or a ball member. In an example, in the case in which the support member is a wire, a plurality of wires may be disposed on at least one of the corners or the side portions of the base 210 or the second board unit 800, and may interconnect the first board unit 255 (e.g., the second circuit board 260) and the second board unit 800 (or the base 210). In an example, one end of each of the plurality of wires may be coupled to the first board unit 255 (e.g., the second circuit board 260), and the other end of each of the plurality of wires may be coupled to the second board unit 800 (or the base 210).

The image sensor unit 350 may include at least one of a controller 830, a memory 512, or a capacitor 514.

The controller 830 may be disposed so as to be spaced apart from the first board unit 255. In an example, the controller 830 may be disposed on the second board unit 800.

The memory 512 may be disposed on any one of the first board unit 255 and the second board unit 800. In an example, the memory 512 may be disposed or mounted in the first region 801 of the second board unit 800. In an example, the memory 512 may spatially avoid or be spaced apart from the second heat dissipation member 380. In an example, the second heat dissipation member 380 may include an escape recess or a bore formed therein in order to avoid spatial interference with the memory 512, and the memory 512 may be disposed in the escape recess or the bore in the second heat dissipation member 380. The capacitor 514 may be disposed on at least one of the first board unit 255 or the second board unit 800.

The memory 512 may store a first data value (or code value) corresponding to the output from the second position sensor 240 according to displacement (or stroke) of the OIS moving unit in a direction perpendicular to the optical axis (e.g., the X-axis direction or the Y-axis direction) in order to implement OIS feedback driving. In addition, the memory 512 may store a second data value (or code value) corresponding to the output from the first position sensor 170 according to displacement (or stroke) of the bobbin 110 in the first direction (e.g., the optical-axis direction or the Z-axis direction) in order to implement AF feedback driving.

In an example, each of the first and second data values may be stored in the memory 512 in the form of a look-up table. Alternatively, each of the first and second data values may be stored in the memory 512 in the form of an equation or an algorithm. In addition, the memory 512 may store an equation, an algorithm, or a program for operation of the controller 830. In an example, the memory 512 may be a non-volatile memory, for example, an electrically erasable programmable read-only memory (EEPROM).

The controller 830 may be disposed in one region of the second board unit 800 that is located on the outer side of the cover member 300 or is located outside the cover member 300.

Referring to FIG. 20A, the second board unit 800 may include an extension region 808, which is connected to the first region 801 and extends from the first region 801. The extension region 808 may extend from the first side portion 85A of the first region 801. In an example, the extension region 808 may protrude from the outer side surface of the first side portion 85A of the first region. In an example, the extension region 808 may extend or protrude in the second horizontal direction (e.g., the X-axis direction).

The extension region 808 may be located on the outer side of the cover member 300 or may be located outside the cover member 300.

The extension region 808 may alternatively be referred to as a “fourth region”, a “protruding region”, an “extension portion”, or a “protruding portion”. The extension region 808 does not overlap the AF moving unit or the OIS moving unit in the optical-axis direction. In an example, the extension region 808 may extend in the same direction as the third region 803 (e.g., the second horizontal direction).

The controller 830 may be disposed in the extension region 808 of the second board unit 800. In an example, the controller 830 may be disposed or mounted on the upper surface of the extension region 808 of the second board unit 800. In another embodiment, the controller 830 may be disposed or mounted on the lower surface of the extension region 808. In an example, the controller 830 may not overlap the cover member 300 in the optical-axis direction. In addition, in an example, the extension region 808 may not overlap the cover member 300 in the optical-axis direction.

In an example, the area of the upper surface of the extension region 808 may be larger than or equal to the area of the lower surface of the controller 830.

Since the extension region 808 and the third region 803 are connected to the first side portion 85A of the second board unit 800, the area occupied by the camera device 10 in a direction perpendicular to the optical axis may be reduced. Accordingly, the embodiment may minimize increase in the size of the camera device 10 due to the extension region 808.

In another embodiment, the extension region may be connected to any one of the second to fourth side portions 85B, 85C, and 85D of the first region 801 of the second board unit 800 or may protrude from any one of the second to fourth side portions 85B, 85C, and 85D of the first region 801.

The controller 830 may be located on the outer side of the cover member 300 or may be located outside the cover member 300. In an example, the controller 830 may be located outside the space defined by the cover member 300, the base 210, and the first region 801 of the second board unit 800.

In an example, the controller 830 does not overlap the lens module 400, the AF moving unit, the OIS moving unit, or the first region 801 of the second board unit 255 in the optical-axis direction. At least one capacitor 514 may be disposed or mounted on the upper surface of the extension region 808.

In a sensor shift camera device in which an image sensor moves in order to implement hand-tremor compensation, an OIS moving unit, which includes the image sensor and a first board unit, is disposed so as to be spaced apart from a fixed unit, which includes a second board unit. Therefore, heat generated from the OIS moving unit may not be effectively dissipated outside through the fixed unit. The image sensor, a second coil, and a controller may correspond to heat sources. Here, the “controller” may be a driver IC, which controls AF driving and/or OIS driving.

As the image sensor and the lens increase in size, the stroke (or the moving distance) of the OIS moving unit for compensating for a hand-tremor compensation angle (e.g., 1 degree) may increase, the amount of current consumed by the second coil for implementing OIS driving may increase, and the communication speed of the controller may increase. Therefore, the amount of heat generated from the heat sources may increase, and the temperature of the camera device may rise.

In the case in which all of the image sensor, the second coil, and the controller, which are the heat sources, are disposed in the OIS moving unit (hereinafter referred to as “CASE 1”), the temperature of the camera device may increase due to the above-described poor heat dissipation structure of the sensor shift camera device.

The increase in the temperature of the camera device may cause demagnetization of AF and OIS driving magnets and/or sensing magnets, leading to errors in AF driving and OIS driving. In addition, the increase in the temperature of the camera device may cause changes in output signals from an AF position sensor and an OIS position sensor. Therefore, the accuracy and reliability of AF driving and OIS driving may be deteriorated.

In addition, the increase in the temperature of the controller may cause increase in the temperature of the image sensor, leading to loss of images of the image sensor and deterioration in the quantitative and qualitative quality of images.

In the case in which a shape-memory-alloy member is used for hand-tremor compensation, the driving temperature of the shape-memory-alloy member is about 100 to 110 degrees Celsius, but the temperature of the controller may rise to 160 to 180 degrees Celsius when the controller is driven. The temperature of the shape-memory-alloy member may exceed the driving temperature range thereof due to the increase in the temperature of the controller. Therefore, it may be difficult to control driving of the shape-memory-alloy member. In addition, when the temperature of the shape-memory-alloy member increases, the resistance of the shape-memory-alloy member may decrease, and thus the amount of current flowing through the shape-memory-alloy member may increase, leading to damage to the shape-memory-alloy member. Further, when the temperature of the shape-memory-alloy member increases, the length of the shape-memory-alloy member may be reduced, and thus the stroke of the OIS moving unit may be reduced.

In the embodiment, the image sensor 810 and the second coil 230 are disposed in the OIS moving unit, which is located inside the cover member 300, and the controller 830 is disposed in the extension region 808 of the second board unit 800, which does not overlap the image sensor 810 in the optical-axis direction. Accordingly, the controller 830, which is the heat source, may be separated or isolated from the image sensor 810, with the cover member 300 and/or the base 210 interposed therebetween, and may be disposed far away from the image sensor 810.

Since the controller 830, which is the heat source, is disposed outside the cover member 300 and the base 210, heat may be easily dissipated. In addition, since the heat sources between the controller 830 and the image sensor 810 are isolated or separated from each other by the cover member 300 and the base 210, the influence of the heat generated from the controller 830 on the image sensor 810 may be greatly reduced.

According to simulation results, the temperature of the image sensor in CASE 1 rises to about 100 to 120 degrees Celsius, whereas the temperature of the image sensor 810 of the camera device 10 according to the embodiment is about 65 to 80 degrees Celsius. The embodiment may reduce the temperature of the image sensor 810 by 20 to 55 degrees Celsius compared to CASE

The camera device 10 may include a third heat dissipation member 870, which is disposed in, coupled to, or attached to the extension region 808 in order to improve heat dissipation effect. The third heat dissipation member 870 may be in contact with the extension region 808. In an example, the third heat dissipation member 870 may be disposed beneath the extension region 808. In an example, the third heat dissipation member 870 may be disposed on, coupled to, or fixed to the lower surface of the extension region 808. The third heat dissipation member 870 may be a plate-type member, and the description of the material of the first heat dissipation member 280 may be equally or similarly applied to the third heat dissipation member 870. At least a portion of the third heat dissipation member 870 may overlap the controller 830 in the optical-axis direction.

The camera device 10 may include a cover can 405, which is disposed in the extension region 808 and accommodates the controller 830 therein in order to protect the controller 830 from external impact. The cover can 405 may include an upper plate 405A and a side plate 405B connected to the upper plate 405A and extending from the upper plate 405A toward the extension region 808.

The cover can 405 may be disposed on, coupled to, or fixed to the upper surface of the extension region 808. In an example, the lower portion, lower end, or lower surface of the side plate 405B of the cover can 405 may be coupled, attached, or fixed to the upper surface of the extension region 808.

Since the cover can 405 accommodates the controller 830 therein, the cover can 405 may inhibit the heat generated from the controller 830 from being emitted to the outside of the cover can 405 and transferred to the image sensor. The description of the material of the first heat dissipation member 280 or the material of the cover member 300 may be equally or similarly applied to the cover can 405.

The camera device 10 may further include a heat dissipation layer 860, which is disposed on the controller 830. The heat dissipation layer 860 may cover the surface of the controller 830. In an example, the heat dissipation layer 860 may be disposed so as to surround the surface of the controller 830. In an example, the heat dissipation layer 860 may be in contact with the upper surface and the side surface of the controller 830 and may surround the same. The heat dissipation layer 860 may be formed of heat dissipation plastic or heat dissipation resin, for example, heat dissipation epoxy. The heat dissipation layer 860 may improve the heat dissipation efficiency of the controller 830.

In another embodiment, the heat dissipation layer may be disposed on at least one of the upper surface or the side surface of the controller 830. In an example, the heat dissipation layer may expose at least a portion of the controller 830.

The controller 830 may be conductively connected to the second position sensor 240. The controller 830 may adjust or control a driving signal supplied to the second coil 230 using the output signals received from the sensors 240A, 240B, and 240C of the second position sensor 240 and the first data value stored in the memory 512, and may perform feedback OIS operation.

In addition, the controller 830 may be conductively connected to the first position sensor 170. For example, when the first position sensor 170 is implemented as a Hall sensor alone, the first position sensor 170 may be conductively connected to the controller 830. In this case, the controller 830 may control a driving signal supplied to the first coil 120 using the output signal from the first position sensor 170 and the second data value stored in the memory 512, and may perform feedback autofocus operation.

The controller 830 may be implemented in the form of a driver IC, but the disclosure is not limited thereto. In an example, the controller 830 may be conductively connected to the terminals 800B of the second board unit 800.

The controller 830 may control the first position sensor, which is implemented as a Hall sensor alone, and/or the second position sensor, which is implemented as a Hall sensor alone. In an example, the controller 830 may supply a driving signal to the first position sensor, which is implemented as a Hall sensor alone, and/or the second position sensor, which is implemented as a Hall sensor alone, and may receive an output signal from the first position sensor and/or an output signal from the second position sensor.

In another embodiment, the first position sensor may be implemented as a Hall sensor alone, and the second position sensor may be implemented in the form of a driver IC including a Hall sensor. In this case, the controller 830 may be conductively connected to the first position sensor, may supply a driving signal to the first position sensor, and may receive an output signal from the first position sensor.

In an example, the controller 830 may include a driver for driving at least one of the first position sensor or the second position sensor.

The image sensor unit 350 may further include a motion sensor (not shown), which is disposed on any one of the first board unit 255 and the second board unit 800. The motion sensor may be conductively connected to the controller 830. The motion sensor may output rotational angular speed information regarding movement of the camera device 10. The motion sensor may be implemented as, for example, a two-axis or three-axis gyro sensor or an angular speed sensor. In an example, the motion sensor may output information about the movement amount in the X-axis direction, the movement amount in the y-axis direction, and the rotation amount in response to movement of the camera device 10.

In another embodiment, the motion sensor may be omitted from the camera device 10. In the case in which the motion sensor is omitted from the camera device, the camera device 10 may receive position information from a motion sensor provided in the optical instrument 200A in response to movement of the camera device 10.

The image sensor unit 350 may further include a filter 610, which is disposed between the lens module 400 and the image sensor 810. In addition, the image sensor unit 350 may further include a filter holder 600, in which the filter is disposed, seated, or accommodated. The filter holder 600 may alternatively be referred to as a “sensor base”.

The filter 610 may serve to block or allow introduction of light within a specific frequency band, among the light that has passed through the lens barrel 400, into the image sensor 810. The filter 610 may be, for example, an infrared cut filter. In an example, the filter 610 may be disposed parallel to the xy-plane, which is perpendicular to the optical axis OA. The filter 610 may be disposed below the lens module 400.

The filter holder 600 may be disposed below the AF driving unit 100. In an example, the filter holder 600 may be disposed on the first board unit 255. In an example, the filter holder 600 may be disposed on the upper surface of the second circuit board 260 of the first board unit 255.

The filter holder 600 may be coupled to one region of the second circuit board 260 around the image sensor 810 by means of an adhesive, and may be exposed through the bore 250A in the first circuit board 250. In an example, the bore 250A in the first circuit board 250 may expose the filter holder 600 disposed on the second circuit board 260 and the filter 610 disposed on the filter holder 600. The filter holder 600 may include a bore 61A formed in a portion thereof, on which the filter 610 is mounted or disposed, in order to allow the light passing through the filter 610 to be introduced into the image sensor 810. The bore 61A in the filter holder 600 may be a through-hole formed through the filter holder 600 in the optical-axis direction. In an example, the bore 61A in the filter holder 600 may be formed through the center of the filter holder 600 and may be disposed so as to correspond to or oppose the image sensor 810.

The filter holder 600 may include a seating portion 500, which is depressed in the upper surface thereof to allow the filter 610 to be seated therein, and the filter 610 may be disposed, seated, or mounted in the seating portion 500. The seating portion 500 may be formed so as to surround the bore 61A. In another embodiment, the seating portion of the filter holder may take the form of a protruding portion protruding from the upper surface of the filter.

The image sensor unit 350 may further include an adhesive disposed between the filter 610 and the seating portion 500, and the filter 610 may be coupled or attached to the filter holder 600 by means of the adhesive.

In another embodiment, the filter holder may be coupled to the holder 270 or may be coupled to the AF driving unit 100.

Referring to FIG. 3, the cover member 300 may take the form of a box that has an open lower portion and includes an upper plate 301 and a side plate 302. The lower portion of the side plate 302 of the cover member 300 may be coupled to the base 210. The shape of the upper plate 301 of the cover member 300 may be a polygonal shape, for example, a quadrangular shape or an octagonal shape. The cover member 300 may include a bore 303 formed in the upper plate 301 thereof to expose the lens of the lens module 400 coupled to the bobbin 110 to external light.

Referring to FIGS. 1 and 3, the side plate 302 of the cover member 300 may have a recessed portion 304 formed therein to expose the terminal unit 95 of the circuit board 190 and the terminals 800B of the second board unit corresponding thereto.

In an example, the cover member 300 may be formed of a metallic material. For example, the cover member 300 may be formed of steel use stainless (SUS) (e.g., an SUS-4-based material). In addition, the cover member 300 may be formed of a steel plate cold commercial (SPC). For example, the cover member 300 may be formed of SUS containing an iron (Fe) component in an amount of 50 percent (%) or more. In addition, in an example, an oxidation-resistant metal, for example, nickel, may be plated on the surface of the cover member 300 in order to inhibit oxidation. In addition, in another embodiment, the cover member 300 may be formed of a magnetic material or a magnetic metallic material.

In still another embodiment, the cover member 300 may be formed of an injection-molded material, for example, plastic or resin. In addition, the cover member 300 may be made of an insulating material or a material capable of blocking electromagnetic waves.

The cover member 300 and the base 210 may accommodate the AF driving unit 100 and the OIS moving unit, may protect the AF driving unit 100 and the OIS moving unit from external impact, and may inhibit introduction of external foreign substances thereinto.

In an example, at the initial position of the OIS moving unit, the outer side surface of the holder 270 may be spaced apart from the inner side surface of the base 210 by a predetermined distance. In addition, in an example, at the initial position of the OIS moving unit, the lower surfaces of the holder 270 and the first board unit 255 may be spaced apart from the base 210 by a predetermined distance.

The controller 830 may supply at least one driving signal to at least one of the first to fourth coil units 230-1 to 230-4, and may control the at least one driving signal to move the OIS moving unit in the X-axis direction and/or the Y-axis direction or to rotate, tilt, or roll the OIS moving unit within a predetermined angular range about the optical axis.

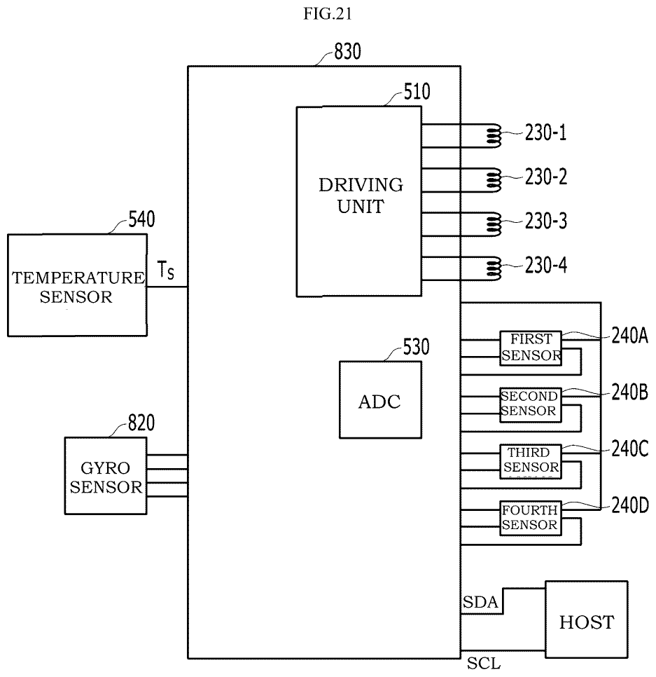

FIG. 21 is a block diagram showing the configuration of the controller 830 and the first to third sensors 240A, 240B, and 240C. The controller 830 may perform communication of transmitting and receiving data to and from a host using a clock signal SCL and a data signal SDA, for example, I2C communication. In an example, the host may be the controller 780 of the optical instrument 200A.

The controller 830 may be conductively connected to the second coil 230. The controller 830 may include a driving unit 510 for supplying a driving signal required to drive the first to fourth coil units 230-1 to 230-4. In an example, the driving unit 510 may include an H bridge circuit or an H bridge driver capable of changing the polarity of the driving signal. In this case, the driving signal may be a PWM signal in order to reduce consumption of current, and the driving frequency of the PWM signal may be 20 kHz or more, which is outside of the audible frequency band. In another embodiment, the driving signal may be a direct current signal.

Each of the first to third sensors 240A to 240C may include two input terminals and two output terminals. The controller 830 may supply power or a driving signal to two input terminals of each of the first to third sensors 240A to 240C. In an example, any one of the two input terminals of each of the first to third sensors 240A to 240C may be commonly connected. In an example, the two input terminals may be a (+) input terminal and a (−) input terminal (e.g., ground terminal).

In an example, the controller 830 may receive a first output voltage from the first sensor 240A, a second output voltage from the second sensor 240B, and a third output voltage from the third sensor 240C, and may control movement (or displacement) of the OIS moving unit in the X-axis direction or the Y-axis direction using the received first to third output voltages. In addition, the controller 830 may control rotation, tilting, or rolling of the OIS moving unit about the optical axis using the received first to third output voltages.

In addition, the controller 830 may include an analog-to-digital converter 530, which receives output voltage from the two output terminals of each of the first to third sensors 240A to 240C and outputs a data value, a digital value, or a code value corresponding to a result of the analog-to-digital conversion of the received output voltage. The controller 830 may control movement (or displacement) of the OIS moving unit in the X-axis direction or the Y-axis direction and rotation, tilting, or rolling of the OIS moving unit about the optical axis using the data values output from the analog-to-digital converter 530.

A temperature sensor 540 may measure the ambient temperature (e.g., the temperature of each of the first to third sensors 240A, 240B, and 240C), and may output a temperature detection signal Ts corresponding to a result of the measurement. The temperature sensor 540 may be, for example, a thermistor.

The resistance value of a resistor included in the temperature sensor 540 may vary depending on changes in the ambient temperature, and accordingly, the value of the temperature detection signal Ts may vary depending on changes in the ambient temperature. An equation or a look-up table relating to the relationship between the ambient temperature and the temperature detection signal Ts may be stored in the memory or the controller 830 or 780 through calibration.

Because the output values from the first to third sensors 240A, 240B, and 240C are also influenced by temperature, it is necessary to compensate for the output values from the first to third sensors 240A, 240B, and 240C according to the ambient temperature in order to accurately and reliably implement OIS feedback driving.

To this end, in an example, the controller 830 or 780 may compensate for the output value (or the data value corresponding to output) from each of the first to third sensors 240A, 240B, and 240C using the ambient temperature measured by the temperature sensor 540 and a temperature compensation algorithm or compensation equation. The temperature compensation algorithm or compensation equation may be stored in the controller 830 or 780 or the memory.

The camera device may further include a fourth sensor 240D, which corresponds to or opposes the fourth magnet unit 130-4 in the optical-axis direction. The fourth sensor 240D may be disposed on the first board unit 255 (e.g., the first circuit board 250). In an example, the fourth sensor 240D may be disposed adjacent to any one corner of the first circuit board 250, on which the first to third sensors 240A to 240C are not disposed. The description of the placement relationship between the first sensor 240A and the first coil unit 230-1 may be equally or similarly applied to the placement relationship between the fourth sensor 240D and the fourth coil unit 230-4.

In an example, the fourth sensor 240D may be located so as to oppose the second sensor 240B in a diagonal direction. In an example, the output voltage from the fourth sensor 240D may be used to detect movement of the OIS moving unit in the X-axis direction or the Y-axis direction. In another embodiment, the fourth sensor 240D may correspond to the first position sensor 170 of the AF driving unit 100.

The controller 830 may be conductively connected to the second coil 230 and the second position sensor 240 via the second board unit 800, the support board 310, and the first board unit 255.

In another embodiment, the controller 830 may be disposed on the first board unit 255. In another embodiment, the controller 830 may be disposed on the first circuit board 250.

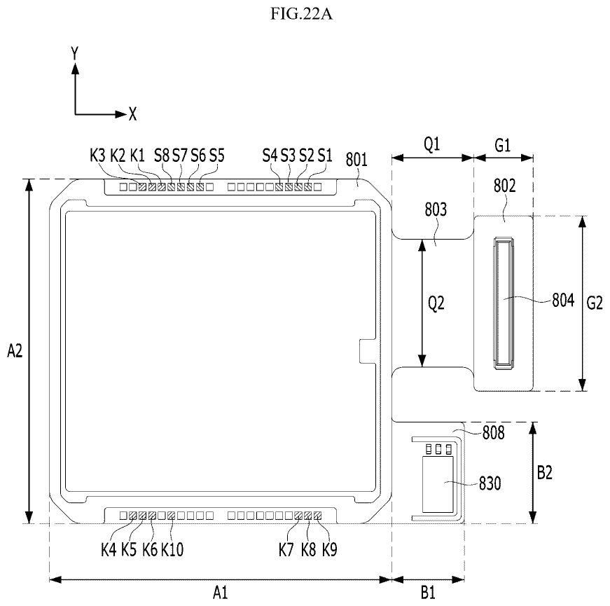

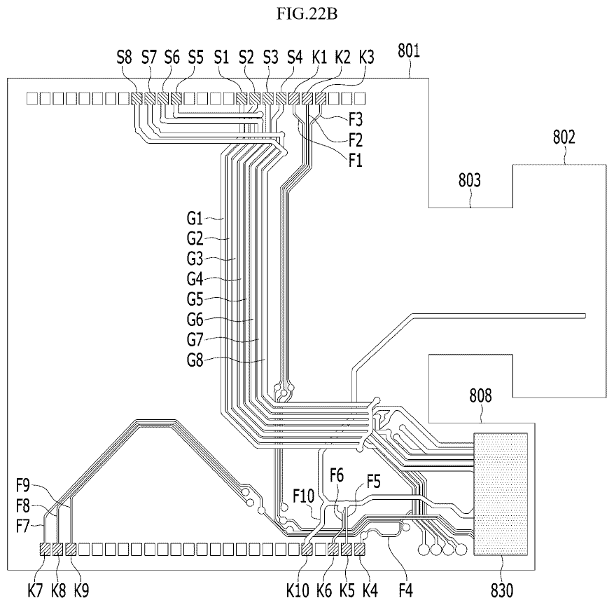

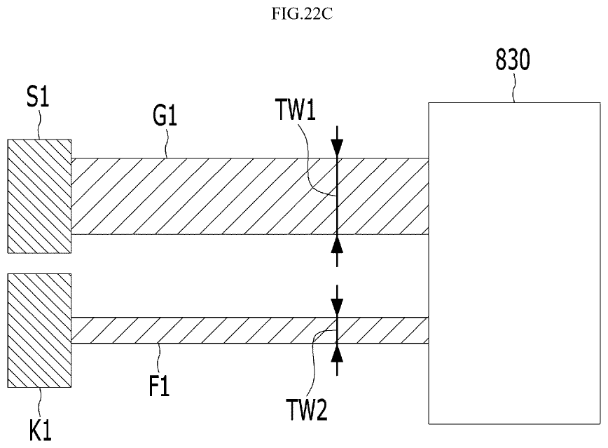

FIG. 22A shows a plurality of terminals S1 to S8 and K1 to K10 of the second board unit 800 conductively connected to the controller 830, and FIG. 22B shows an embodiment of wires G1 to G8 and F1 to F10 of the second board unit 800 conductively connecting the controller 830 to the plurality of terminals S1 to S8 and K1 to K10 of the second board unit 800.

Referring to FIGS. 22A and 22B, the area (or the area of the upper surface) of the first region 801 of the second board unit 800 may be larger than the area (or the area of the upper surface) of the extension region 808.

In an example, the length A1 of the first region 801 of the second board unit 800 in the second horizontal direction (the X-axis direction) may be greater than the length B1 of the extension region 808 in the second horizontal direction (the X-axis direction). In addition, the length A2 of the first region 801 of the second board unit 800 in the first horizontal direction (the Y-axis direction) may be greater than the length B2 of the extension region 808 in the first horizontal direction (the Y-axis direction).

In an example, the length G1 of the second region 802 in the second horizontal direction may be less than the length Q1 of the third region 803 in the second horizontal direction. In another embodiment, the length G1 of the second region 802 in the second horizontal direction may be equal to or greater than the length Q1 of the third region 803 in the second horizontal direction.

In an example, the length G2 of the second region 802 in the first horizontal direction may be greater than the length Q2 of the third region 803 in the first horizontal direction. In another embodiment, the length of the second region 802 in the first horizontal direction may be equal to or less than the length of the third region 803 in the first horizontal direction.

The length B2 of the extension region 808 in the first horizontal direction may be less than the length G2 of the second region 802 in the first horizontal direction. In another embodiment, the length of the extension region 808 in the first horizontal direction may be equal to or greater than the length of the second region 802 in the first horizontal direction.

The length B1 of the extension region 808 in the second horizontal direction may be greater than the length G1 of the second region 802 in the second horizontal direction. In another embodiment, the length of the extension region 808 in the first horizontal direction may be equal to or less than the length of the second region 802 in the second horizontal direction.

The length B1 of the extension region 808 in the second horizontal direction may be less than the length Q1 of the third region 803 in the second horizontal direction. In another embodiment, the length of the extension region 808 in the second horizontal direction may be equal to or greater than the length of the third region 803 in the second horizontal direction.

The length B2 of the extension region 808 in the first horizontal direction may be less than the length Q2 of the third region 803 in the first horizontal direction. In another embodiment, the length of the extension region 808 in the first horizontal direction may be equal to or greater than the length of the third region 803 in the first horizontal direction.

The second board unit 800 may include at least one first terminal S1 to S8 conductively connected to the second coil 230 and at least one second terminal K1 to K10 conductively connected to the second position sensor 240.

In an example, the second board unit 800 may include a plurality of first terminals S1 to S8 conductively connected to the first to fourth coil units 230-1 to 230-4. In the four-channel drive mode, the number of first terminals may be eight, and in the three-channel drive mode, the number of first terminals may be six. For example, two terminals may be needed for each channel.

The second board unit 800 may include first wires G1 to G8 conductively connecting the plurality of first terminals S1 to S8 to the controller 830, respectively. The number of first wires G1 to G8 may be the same as the number of first terminals S1 to S8.

The second board unit 800 may include a plurality of second terminals K1 to K10 conductively connected to the first to third sensing units 240A to 240C.

In an example, the second board unit 800 may include three second terminals K1 to K9 conductively connected to each of the first to third sensor units 240A to 240C and one second terminal K10 (e.g., common terminal) for common connection.

In an example, two output terminals and a first input terminal of the first sensor 240A may be conductively connected to three terminals (e.g., K1, K2, and K3), two output terminals and a first input terminal of the second sensor 240B may be conductively connected to three terminals (e.g., K7, K8, and K9), and two output terminals and a first input terminal of the third sensor 240C may be conductively connected to three terminals (e.g., K4, K5, and K6). In addition, a second input terminal of each of the first to fourth sensors 240A to 240C may be conductively connected to the common terminal K10.

In an example, the first input terminal may be a (−) input terminal (or ground terminal), and the second input terminal may be a (+) input terminal. However, in another embodiment, the second input terminal may be a (−) input terminal (or ground terminal), and the first input terminal may be a (+) input terminal.

The second board unit 800 may include second wires F1 to F10 conductively connecting the plurality of second terminals K1 to K10 to the controller 830, respectively. The number of second wires may be the same as the number of second terminals. The line width of the second wire F10 connected to the common terminal K10 may be greater than or equal to the line widths of the second wires F1 to F9 connected to the other second terminals K1 to K9.

FIG. 22C is a schematic conceptual diagram of the first wire G1 and the second wire K1 of the second board unit 800.

The description of FIG. 22C may be equally or similarly applied to the other first wires G2 to G8 and the other second wires K2 to K10. In FIG. 22C, TW1 represents the line width of one first wire (e.g., G1), and TW2 represents the line width of one second wire (e.g., K1).

Referring to FIG. 22C, the first wire (e.g., G1) may be formed in the first region 801 and the extension region 808 of the second board unit 800 and may conductively connect the first terminal (e.g., S1) to the controller 830. In an example, one end of the first wire G1 may be connected to the first terminal (e.g., S1), and the other end of the first wire G1 may be coupled or bonded to the controller 830 by means of a solder or a conductive adhesive.

The second wire (e.g., F1) may be formed in the first region 801 and the extension region 808 of the second board unit 800 and may conductively connect the second terminal (e.g., K1) to the controller 830. In an example, one end of the second wire F1 may be connected to the second terminal (e.g., K1), and the other end of the second wire F1 may be coupled or bonded to the controller 830 by means of a solder or a conductive adhesive.

The resistance value of the first wire G1 may be 1 ohm or less. This is because, if the resistance value of the first wire G1 exceeds 1 ohm, voltage drop due to the first wire G1 may increase and thus driving voltage supplied to the second coil 230 may be lowered.

For example, the resistance value of the first wire G1 may be 0.1 ohms to 1 ohm. Alternatively, the resistance value of the first wire G1 may be 0.1 ohms to 0.3 ohms.

In addition, the resistance value of the second wire F1 may be 2 ohms or less. This is because, if the resistance value of the second wire F1 exceeds 2 ohms, the amount of power consumed in the second wire F1 may be increased and a large amount of heat may be generated. For example, the resistance value of the second wire F1 may be 0.2 ohms to 2 ohms. Alternatively, for example, the resistance value of the second wire F1 may be 0.2 ohms to 0.3 ohms.

In an example, the resistance value of the second wire F1 may be greater than the resistance value of the first wire G1. In another embodiment, the resistance value of the second wire F1 may be equal to the resistance value of the first wire G1.

The width TW1 of the first wire G1 may be greater than the width TW2 of the second wire F1 (TW1>TW2). For example, the width TW1 of the first wire F1 may be 180 micrometers to 220 micrometers. Alternatively, for example, TW1 may be 190 micrometers to 210 micrometers.

For example, the width TW2 of the second wire F1 may be 70 micrometers to 90 micrometers. Alternatively, for example, TW2 may be 75 micrometers to 85 micrometers. In another embodiment, the width of the first wire G1 may be equal to the width of the second wire F1.

The value (TW1/TW2) obtained by dividing the width TW1 of the first wire G1 by the width TW2 of the second wire F1 may be 2 to 3.14. Alternatively, the divided value may be 2 to 2.5. Alternatively, the divided value (TW1/TW2) may be 2.4 to 2.6.

If the divided value (TW1/TW2) is less than 2, TW1 may be reduced and thus the resistance value of the first wire G1 may increase. Accordingly, voltage drop due to the first wire G1 may increase and thus driving voltage supplied to the second coil 230 may be lowered.

If the divided value (TW1/TW2) exceeds 3.14, TW2 may be reduced and thus the resistance value of the second wire F1 may increase. Accordingly, the amount of power consumed in the second wire F1 may be increased and a large amount of heat may be generated.

FIG. 22D shows placement of wires 224 and 225 connected to the terminals M1 to M8 and R1 to R10 of the support board 310. FIG. 22D is a view showing a state in which the support board 310 and the first circuit board 250 are unfolded parallel to a plane perpendicular to the optical axis.

In FIG. 22D, TW3 represents the line width of one third wire 224, and TW4 represents the line width of one fourth wire 225. The wires 224 and 225 may be formed on the support board 310. In an example, the wires 224 and 225 may be formed on the support board 310 and the first circuit board 250.

Referring to FIG. 22D, the support board 310 may include at least one third terminal M1 to M8 conductively connected to the at least one first terminal S1 to S8 of the second board unit 800 by means of a solder or a conductive adhesive. In an example, the support board 310 may include a plurality of third terminals M1 to M8 conductively connected to the plurality of first terminals S1 to S8 of the second board unit 800. The number of third terminals M1 to M8 of the support board 310 may be the same as the number of first terminals S1 to S8 of the second board unit 800.

In addition, the support board 310 may include at least one fourth terminal R1 to R10 conductively connected to the at least one second terminal K1 to K10 of the second board unit 800 by means of a solder or a conductive adhesive. In an example, the support board 310 may include a plurality of fourth terminals R1 to R10 conductively connected to the plurality of second terminals K1 to K10 of the second board unit 800. The number of fourth terminals R1 to R10 of the support board 310 may be the same as the number of terminals K1 to K10 of the second board unit 800.

In an example, the support board 310 may include four terminal units 7A to 7D.

At least one third terminal conductively connected to the second coil 230 may be formed in at least one of the four terminal units 7A to 7D.

In an example, one terminal unit (e.g., 7C) among the four terminal units 7A to 7D may include third terminals (e.g., M1 to M4) conductively connected to two coil units (e.g., 230-1 and 230-2) among the first to fourth coil units 230-1 to 230-4. In addition, in an example, another terminal unit (e.g., 7A) among the four terminal units 7A to 7D may include third terminals (e.g., M5 and M6) conductively connected to the remaining two coil units (e.g., 230-3 and 230-4) among the first to fourth coil units 230-1 to 230-4.

In another embodiment, each of the four terminal units 7A to 7D may include a third terminal conductively connected to a corresponding one of the first to fourth coil units 230-1 to 230-4.

In still another embodiment, the third terminals conductively connected to the first to fourth coil units 230-1 to 230-4 may be formed in any one of the four terminal units 7A to 7D.

At least one fourth terminal R1 to R10 conductively connected to the second position sensor 240 may be formed in at least one of the four terminal units 7A to 7D.

In an example, each of the three terminal units (e.g., 7B to 7D) among the four terminal units 7A to 7D may include three fourth terminals R1 to R3, R4 to R6, or R7 to R9 conductively connected to a corresponding one of the first to third sensor units 240A to 240C.

One terminal unit (e.g., 7D) among the three terminal units (e.g., 7B to 7D) may include one fourth terminal R10 to which the first to third sensor units 240A to 240C are conductively commonly connected. In another embodiment, one fourth terminal to which the first to third sensor units 240A to 240C are conductively commonly connected may be formed in another terminal unit (e.g., 7A) among the four terminal units 7A to 7D.

The support board 310 may include third wires 224 conductively connecting the third terminals M1 to M8 to the second coil 230 and fourth wires 225 conductively connecting the fourth terminals R1 to R10 to the second position sensor 240. The number of third wires 224 may be the same as the number of third terminals M1 to M8, and the number of fourth wires 225 may be the same as the number of fourth terminals R1 to R10.

In an embodiment in which the support board 310 and the first circuit board 250 are integrally formed with each other, the third wires 224 and the fourth wires 225 may also be formed on the first circuit board 250.

The width TW3 of the third wire 224 may be less than the width TW1 of the first wire G1 (TW3<TW1). The reason for this is to reduce voltage drop caused by the first wire G1 and thus to inhibit the voltage supplied to the third wire 224 of the support board 310 from being lowered.

In another embodiment, the width TW3 of the third wire 224 may be equal to the width TW1 of the first wire G1.

The width TW4 of the fourth wire 225 may be less than the width TW2 of the second wire F1 (TW4<TW2). The reason for this is to reduce voltage drop caused by the second wire F1 and thus to inhibit the voltage supplied to the fourth wire 225 of the support board 310 from being lowered.

In another embodiment, the width TW4 of the fourth wire 225 may be equal to the width TW2 of the second wire F1.

In an example, the resistance value of the fourth wire 225 may be greater than the resistance value of the third wire 224. In another embodiment, the resistance value of the fourth wire 225 may be equal to the resistance value of the third wire 224.

The width TW3 of the third wire 224 may be greater than the width TW4 of the fourth wire 225 (TW3>TW4). For example, the width TW3 of the third wire 224 may be 110 micrometers to 140 micrometers. Alternatively, for example, TW3 may be 120 micrometers to 130 micrometers.

For example, the width TW4 of the fourth wire 225 may be 50 micrometers to 70 micrometers. Alternatively, for example, TW2 may be 60 micrometers to 65 micrometers. In another embodiment, the width of the third wire 224 may be equal to the width of the fourth wire 225.

The value (TW3/TW4) obtained by dividing the width TW3 of the third wire 224 by the width TW4 of the fourth wire 225 may be 1.6 to 2.3. Alternatively, the divided value (TW3/TW4) may be 1.7 to 2.1.

If the divided value (TW3/TW4) is less than 1.6, TW3 may be reduced and thus the resistance value of the third wire 224 may increase. Accordingly, voltage drop due to the third wire 224 may increase and thus driving voltage supplied to the second coil 230 may be lowered.

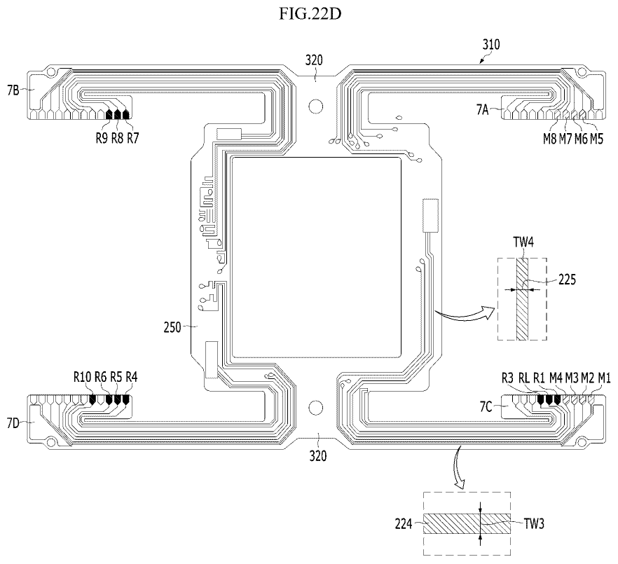

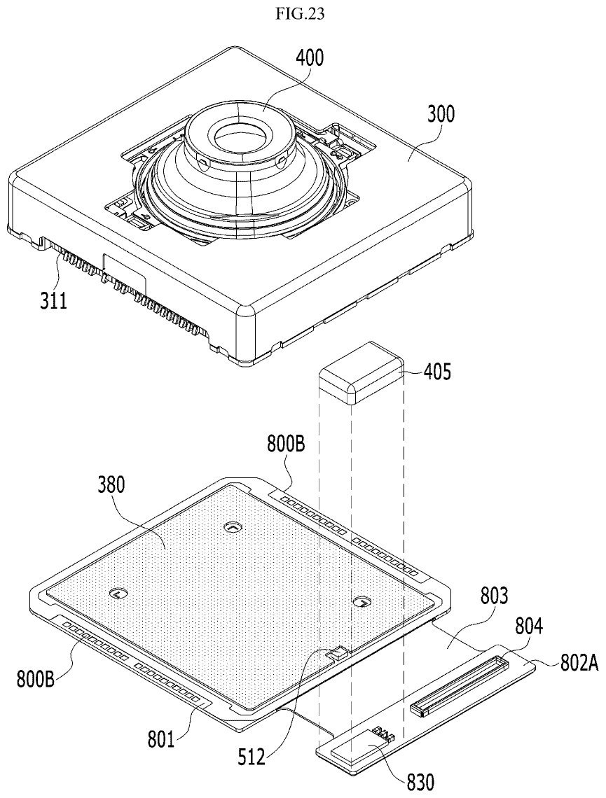

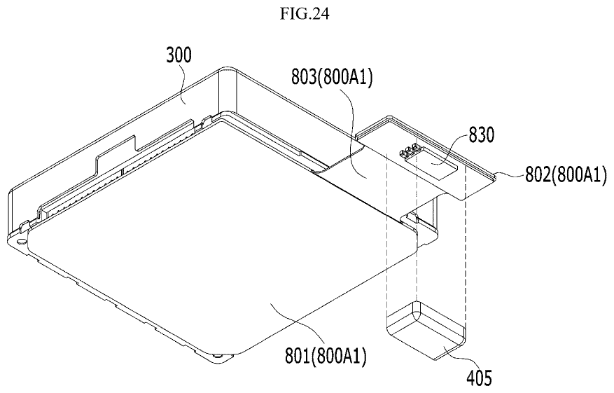

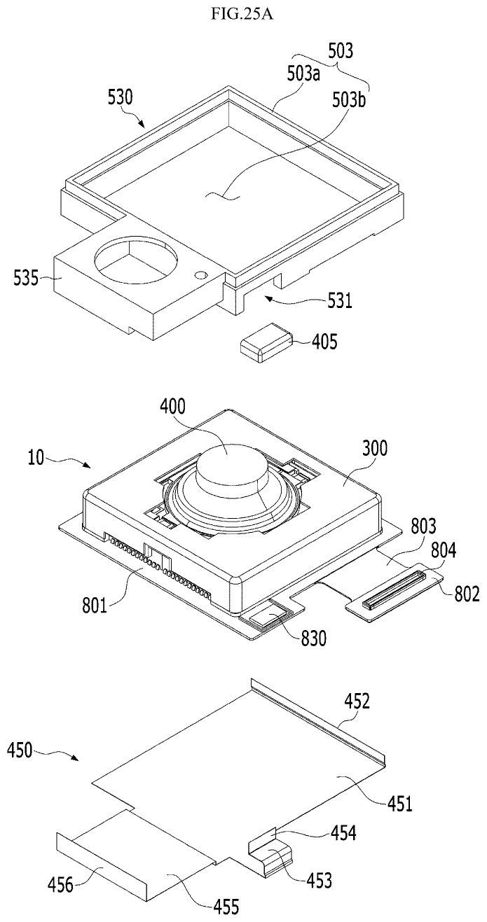

In addition, if the divided value (TW3/TW4) exceeds 2.3, TW4 may be reduced and thus the resistance value of the fourth wire 225 may increase. Accordingly, the amount of power consumed in the fourth wire 225 may be increased and a large amount of heat may be generated. FIG. 23 shows a modified example of placement of the controller 830 in FIG. 20A.

Referring to FIG. 23, the second board unit 800A in FIG. 23 may not include the extension region 808 in FIG. 20A, and the controller 830 may be disposed in the second region 802A of the second board unit 800A. In an example, the controller 830 may be disposed on, coupled to, or mounted on the upper surface of the second region 802A of the second board unit 800A. The controller 830 may be conductively connected to the second region 802A. In an example, a third wire (or third conductive pattern) conductively connected to the controller 830 may be formed in the second region 802A and may be conductively connected to terminals 800B of the second board unit 800A via first wires (or first conductive patterns) of the third region 803 and the first region 801. The description of the width of the first wire may be equally or similarly applied to the third wire.

In addition, in FIG. 23, the cover can 405 may be disposed in, coupled to, or fixed to the second region 802A of the second board unit 800A. In an example, the lower portion, lower end, or lower surface of the side plate 405B of the cover can 405 may be coupled, attached, or fixed to the upper surface of the second region 802A.

FIG. 24 shows another modified example of placement of the controller 830 in FIG. 20A.

Referring to FIG. 24, the second board unit 800A1 in FIG. 24 may not include the extension region 808 in FIG. 20A, and the controller 830 may be disposed on, coupled to, or mounted on the lower surface of the second region 802 of the second board unit 800A1. The controller 830 may be conductively connected to the second region 802. In an example, a fourth wire (or fourth conductive pattern) conductively connected to the controller 830 may be formed in the second region 802 and may be conductively connected to terminals 800B of the second board unit 800A1 via first wires (or first conductive patterns) of the third region 803 and the first region 801. The description of the width of the first wire may be equally or similarly applied to the fourth wire.

In addition, in FIG. 24, the cover can 405 may be disposed on, coupled to, or fixed to the lower surface of the second region 802 of the second board unit 800A1. In an example, the lower portion, lower end, or lower surface of the side plate 405B of the cover can 405 may be coupled, attached, or fixed to the lower surface of the second region 802.

In FIGS. 23 and 24, the connector 804 is disposed on the upper surface of the second region 802 of the second board unit 800A. However, in another embodiment, the connector in FIGS. 23 and 24 may be disposed on the lower surface of the second region of the second board unit 800A.

FIG. 25A is an exploded perspective view of a camera device 1000 according to another embodiment, and FIG. 25B is a coupled perspective view of the camera device 1000 in FIG. 25A.

Referring to FIGS. 25A and 25B, the camera device 1000 may include a first camera device 10, a second camera device (not shown), a bracket 530, and a conductive member 450.

The second camera device may be one of a camera module for autofocus (AF) and a camera module for optical image stabilization (OIS). The camera module for AF refers to a camera module capable of performing only an autofocus function, and the camera module for OIS refers to a camera module capable of performing an autofocus function and an optical image stabilization (OIS) function.

The bracket 530 may be a structure in which the camera device is accommodated or received in order to protect the camera device. The bracket 530 may include a first accommodation portion 503 for accommodating the first camera device 10 and a second accommodation portion 535 for accommodating the second camera device. In an example, the first accommodation portion 503 may include a sidewall 503a and an opening (or through-hole) 503b. In another embodiment, the first accommodation portion may take the form of a box that has an upper plate, a side plate, and an opening formed in the upper plate. In an example, the second accommodation portion 535 may take the form of a box that has an upper plate, a side plate, and an opening formed in the upper plate. In another embodiment, the second accommodation portion 535 may include a sidewall and an opening (or through-hole). The first accommodation 503 may alternatively be referred to as a first bracket or a first housing, and the second accommodation portion 535 may alternatively be referred to as a second bracket or a second housing.

In FIG. 25A, the first accommodation portion 503 and the second accommodation portion 535 may be structured to be coupled to or in contact with each other, or the first accommodation portion 503 and the second accommodation portion 535 may be integrally formed with each other. However, in another embodiment, the first accommodation portion 503 and the second accommodation portion 535 may be spaced apart from each other or may be provided separately from each other.

In an example, the bracket 530 may be implemented as a conductive member. In addition, in an example, the bracket 530 may be formed of a metallic material having high heat dissipation efficiency. For example, the bracket 530 may include at least one of SUS, aluminum, nickel, phosphorus, bronze, or copper.

The bracket 530 may include a side portion (or sidewall) that corresponds to or opposes the side plate 302 of the cover member 300 of the first camera device 10. In an example, the inner surface of the side portion (or the sidewall) of the bracket 530 may be in contact with the outer surface of the side plate 302 of the cover member 300, and the bracket 530 may improve heat dissipation efficiency.

The bracket 530 may include an escape portion 531 formed therein in order to avoid spatial interference with the cover can 405. For example, the escape portion 531 may take the form of an opening, a recess, or a hole. In an example, the escape portion 531 may be formed in the side portion (or the sidewall) of the bracket 530.

The conductive member 450 may be disposed beneath the second board unit 800 and may be in contact with at least one of the second board unit 800, the bracket 530, or the cover can 405.

In an example, the conductive member 450 may be coupled, attached, or fixed to the second board unit 800, the bracket 430, and the cover can 405. In an example, the conductive member 450 may be in contact with, coupled to, or attached to the second conductive layer 92A of the second board unit 800.

The conductive member 450 may transfer heat from the second board unit 800 to the bracket 830 to dissipate the heat, thereby improving the heat dissipation efficiency of the camera device 10.

In addition, the conductive member 450 may conductively connect the second conductive layer 92A, which is conductively connected to the ground of the second board unit 800, to the cover member 300, thereby protecting the camera device 10 from static electricity.

In addition, the conductive member 450 may be in contact with, coupled to, or attached to the cover can 405, and may transfer heat, transferred from the controller 830 to the cover can 405, to the bracket 530, thereby improving the heat dissipation efficiency of the camera device 10.

In an example, the conductive member 450 may include a first portion 451, which is disposed beneath the second board unit 800 and is in contact with and attached to the lower surface of the second board unit 800, a second portion 452, which is connected to the first portion 451 and is in contact with and attached to the bracket 530, a third portion 453, which is connected to the first portion 451 and is in contact with and attached to the cover can 405, and a fourth portion 454, which is connected to the third portion 453 and is in contact with and attached to the bracket 530.

In addition, the conductive member 450 may further include a fifth portion 455, which is connected to the first portion 451 and is in contact with and attached to the second camera device, and a sixth portion 456, which is connected to the fifth portion 455 and is in contact with and attached to the bracket 530.

The conductive member 450 may be formed of a metallic material, such as copper or aluminum. Alternatively, in an example, the description of the material of the first heat dissipation member 280 may be equally or similarly applied to the conductive member 450.

The conductive member 450 may alternatively be referred to as a “conductive tape” or a “heat dissipation tape”.

In another embodiment, the bracket 530 may conductively connect the second conductive layer 92A, which is connected to the ground of the second board unit 800, to the cover member 300, thereby protecting the camera device 10 from static electricity and improving the heat dissipation efficiency thereof.

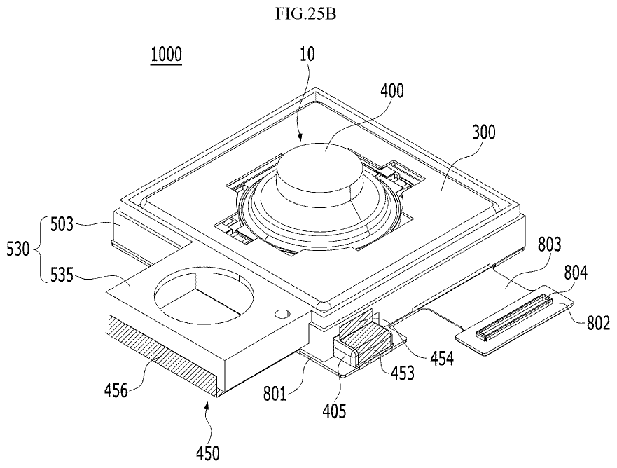

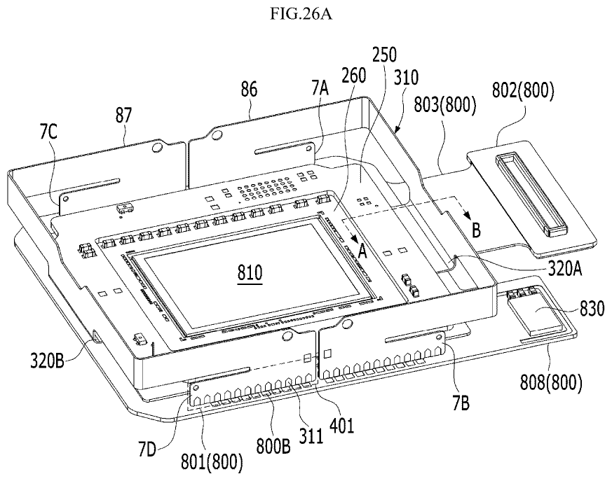

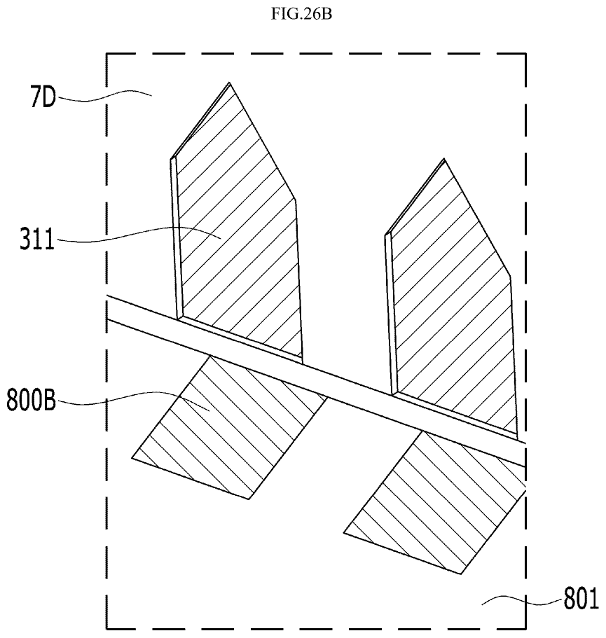

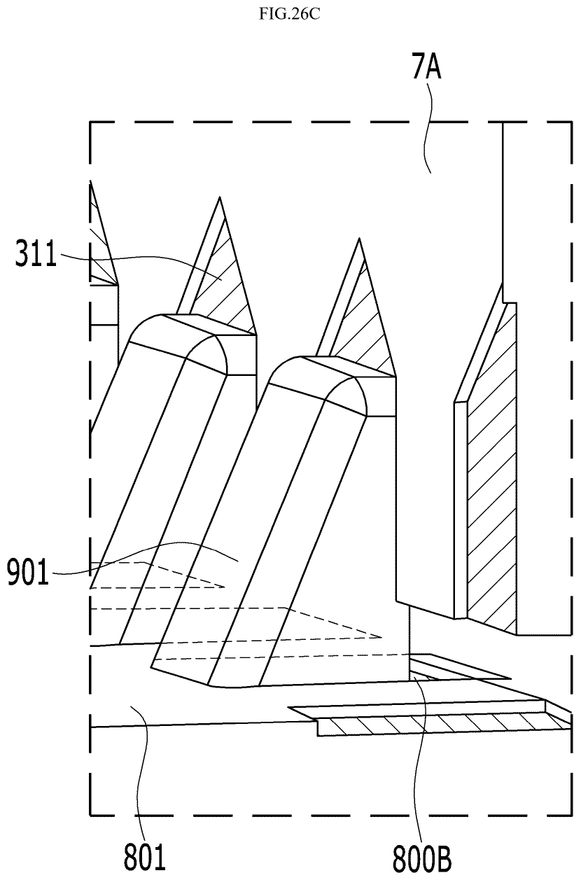

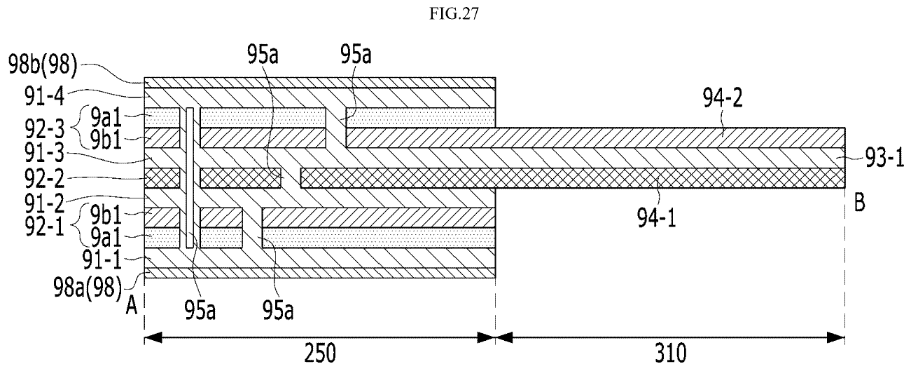

FIG. 26A is a perspective view of the first board unit 255, the support board 310, and the second board unit 800, FIG. 26B is an enlarged view of the terminals 311 of the support board 310 and the terminals 800B of the second board unit 800, FIG. 26C shows solders 901 coupling the terminals 311 of the support board 310 to the terminals 800B of the second board unit 800, and FIG. 27 is a schematic cross-sectional view taken along line AB in the first circuit board 250 and the support board 310 shown in FIG. 26A.

Referring to FIGS. 26A to 27, the first circuit board 250 may be a rigid substrate, and the support board 310 may be a flexible substrate.

In an example, the first circuit board 250 may include a plurality of conductive layers 91-1 to 91-m (m being a natural number greater than 1 (m>1)). Although FIG. 27 illustrates four conductive layers 91-1 to 91-4, which are sequentially stacked one above another, the disclosure is not limited thereto, and the number of conductive layers may be two or more. Each of the conductive layers may be a copper foil, a wire, or a conductive pattern layer for transmitting an electrical signal. For example, the conductive layers 91-1 to 91-4 may be formed of a conductive metal, such as copper, aluminum, gold, silver, or an alloy of at least one thereof. In an example, each of the conductive layers 91-1 to 91-4 may be formed to include at least one of a pattern layer, a wire, or a terminal (or pad).

In addition, in an example, the first circuit board 250 may include insulating layers 92-1 to 92-3, which are disposed between the plurality of conductive layers 91-1 to 91-4. The insulating layers 92-1 to 92-3 are provided for the purpose of electrical insulation between the conductive layers 91-1 to 91-4, thereby inhibiting electrical short circuit between the conductive layers 91-1 to 91-4.

Although FIG. 27 illustrates three insulating layers disposed between the conductive layers, the disclosure is not limited thereto, and the number of insulating layers may be determined depending on the number of conductive layers and may be one or more. The insulating layer may alternatively be referred to as an “insulating membrane” or an “insulating film”.

The first circuit board 250 may include at least one of a rigid insulating layer, which is made of a rigid material, or a flexible insulating layer, which is made of a flexible material. In this case, the flexible insulating layer may be flexibly bendable, and the rigid insulating layer may have greater strength or hardness than the flexible insulating layer.

In an example, the flexible insulating layer may include a flexible resin, e.g., polyimide. In an example, the rigid insulating layer may include a rigid resin, e.g., prepreg. In addition, in an example, the rigid insulating layer may include prepreg and coverlay. In an example, the coverlay may include a resin. In addition, in an example, the coverlay may include a resin and an adhesive. The resin may be, for example, polyimide. In an example, the coverlay may be formed in a film or sheet type.

In an example, at least one of the plurality of insulating layers 92-1 to 92-3 of the first circuit board 250 may be a rigid insulating layer, and at least one of the plurality of insulating layers 92-1 to 92-3 may be a flexible insulating layer.

In an example, the first circuit board 250 may include a first insulating layer 92-1 disposed between the first conductive layer 91-1 and the second conductive layer 91-2, a second insulating layer 92-2 disposed between the second conductive layer 91-2 and the third conductive layer 91-3, and a third insulating layer 92-3 disposed between the third conductive layer 91-3 and the fourth conductive layer 91-4.

In an example, each of the first insulating layer 92-1 and the third insulating layer 92-3 may be a rigid insulating layer. In an example, each of the first insulating layer 92-1 and the third insulating layer 92-3 may include prepreg 9al and coverlay 9b1.

In addition, the second insulating layer 92-2 may be a flexible insulating layer. In an example, the second insulating layer 92-2 may include polyimide.

The first circuit board 250 may include cover layers 98, which are disposed on the outermost conductive layers (e.g., 91-1 and 91-4) in order to protect the conductive layers 91-1 to 91-4 from external impact. In an example, the cover layers 98 may include a first cover layer 98a disposed beneath the first conductive layer 91-1, which is the lowermost conductive layer, and a second cover layer 98b disposed on the fourth conductive layer 91-4, which is the uppermost conductive layer.

Each of the cover layers 98 may be an insulating material, such as solder resist (SR). Each of the cover layers 98 may be, for example, photo solder resist (PSR) or dry-film-type solder resist (DFSR).

The bodies 86 and 87 of the support board 310 may include a conductive layer 93-1, a first insulating layer 94-1 disposed beneath the conductive layer 93-1, and a second insulating layer 94-2 disposed on the conductive layer 93-1. The first and second insulating layers 94-1 and 94-2 may surround the conductive layer 93-1 and may be formed for the purpose of electrical insulation of the conductive layer 93-1.

For example, the first insulating layer 94-1 may alternatively be referred to as a “base member” or a “base layer”.

The conductive layer 93-1 may be formed to include at least one of a pattern layer, a wiring layer, or a terminal (or pad). In an example, the conductive layer 93-1 may be formed to include terminals 311.

Each of the first and second insulating layers 94-1 and 94-2 may be a flexible insulating layer. For example, the first insulating layer 94-1 may be polyimide, and the second insulating layer 94-2 may be coverlay. In an example, the first insulating layer 94-1 of the support board 310 may be the same layer as the second insulating layer 92-2 of the first circuit board 250. For example, the same layer may be a layer formed of the same material through the same process. In addition, in an example, the first insulating layer 94-1 of the support board 310 and the second insulating layer 92-2 of the first circuit board 250 may be connected to each other.

In addition, the conductive layer 93-1 of the support board 310 may be the same layer as the third conductive layer 91-3 of the first circuit board 250. In addition, the second insulating layer 94-2 of the support board 310 may be the same layer as the coverlay 9b1 included in the third insulating layer 92-3 of the first circuit board 250.

In addition, the first circuit board 250 may include a via 95a for conductive connection between two conductive layers among the plurality of conductive layers. Here, the “via” may alternatively be referred to as a contact or a “contact via”. The via may penetrate insulating layers located between two conductive layers to be conductively connected to each other.

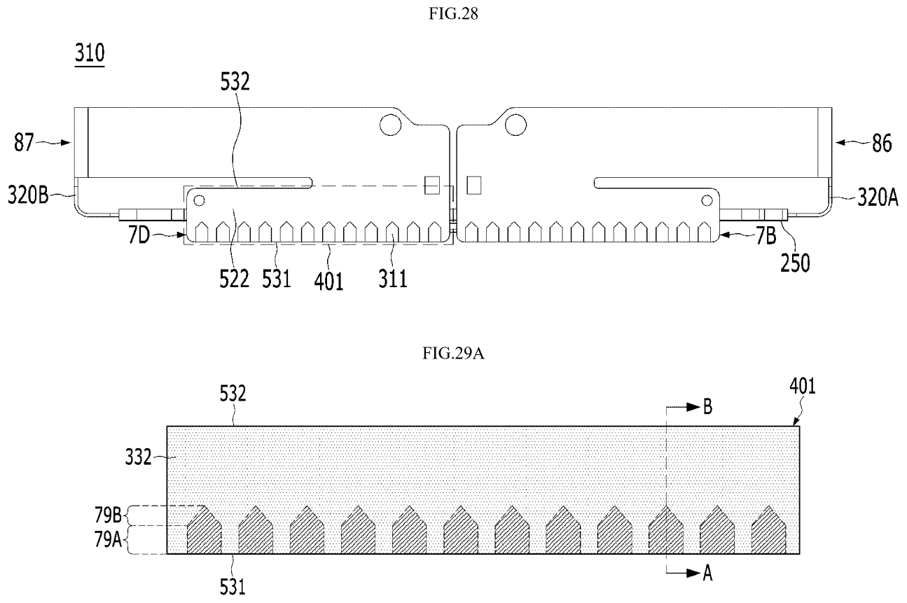

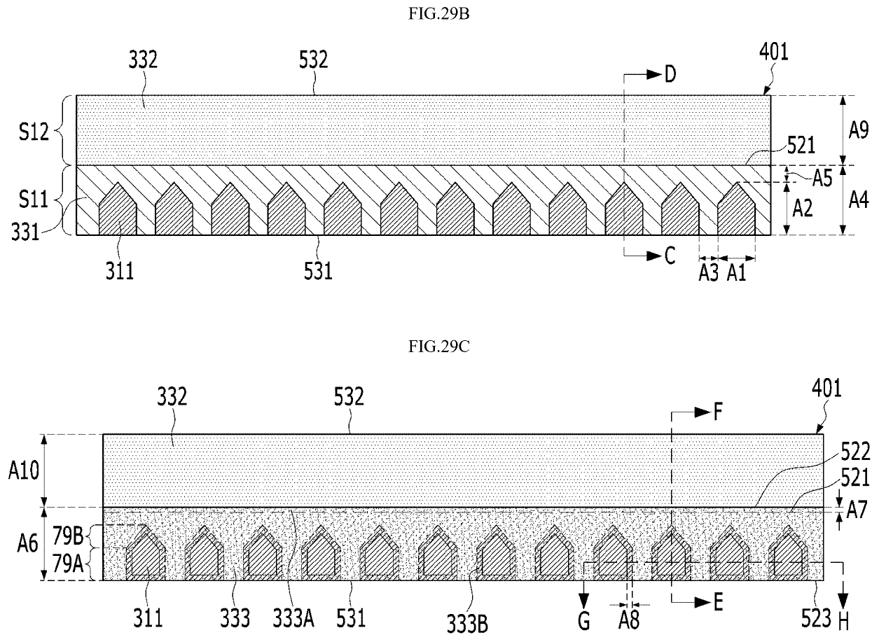

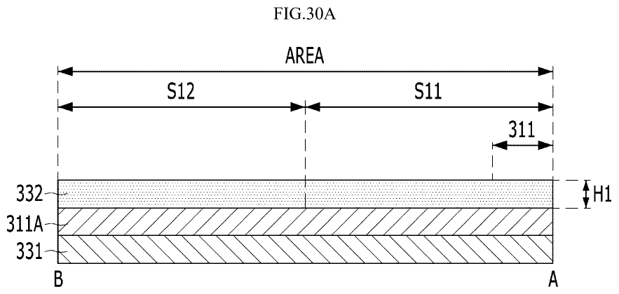

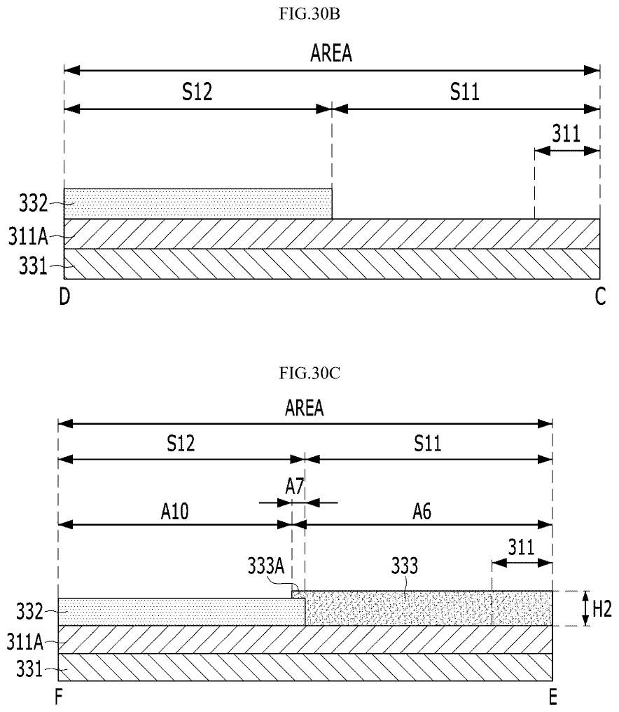

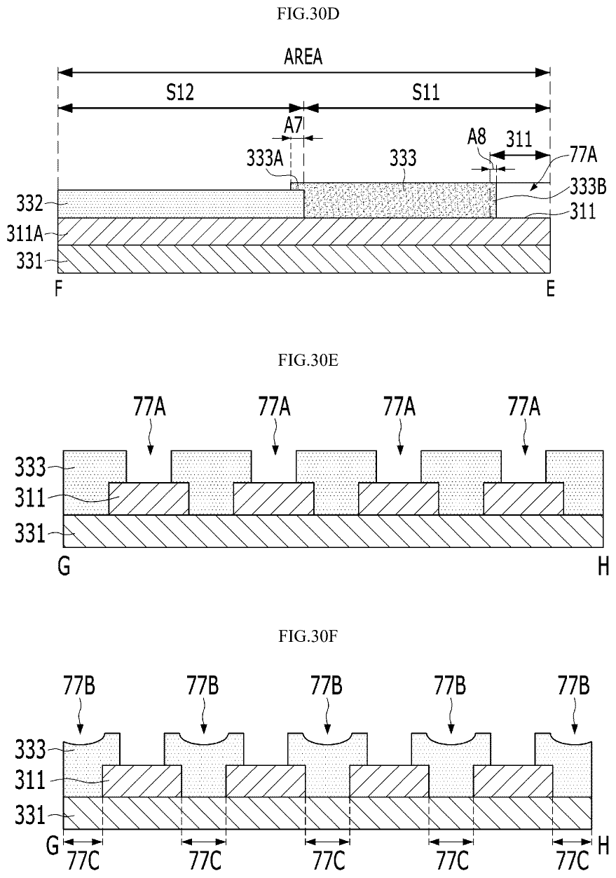

FIG. 28 is a front view of the terminal units (e.g., 7B and 7D) of the support board 310, FIGS. 29A to 29C show a method of forming the terminal unit (e.g., 7D) of the support board 310, FIG. 30A is a cross-sectional view taken along line AB in FIG. 29A, FIG. 30B is a cross-sectional view taken along line CD in FIG. 29B, FIG. 30C is a cross-sectional view taken along line EF in FIG. 29C before formation of a bore 77A, and FIG. 30D is a cross-sectional view taken along line EF in FIG. 29C after formation of the bore 77A. FIG. 30E is a cross-sectional view taken along line GH in FIG. 29C. FIG. 30F shows a modified example of FIG. 30E.

FIGS. 29A to 29C are schematic diagrams of one terminal unit (e.g., 7D) indicated by the dotted line 401 in FIG. 28. The description given with reference to FIGS. 28 to 30D may be equally or similarly applied to the other terminal units 7A, 7B, and 7C.

Referring to FIGS. 29A and 30A, the terminal units 7A to 7D of the support board 310 may include a conductive layer 311A, a first insulating layer 331 formed under the conductive layer 311A, and a second insulating layer 332 formed on the conductive layer 311A.

The bodies 86 and 87 and the terminal units 7A to 7D may be integrally formed through the same process, and therefore, the conductive layer 311A of the terminal units 7A to 7D may correspond to or be the same layer as the conductive layer 93-1 of the bodies 86 and 87. The first insulating layer 331 of the terminal units 7A to 7D may correspond to or be the same layer as the first insulating layer 94-1 of the bodies 86 and 87. The second insulating layer 332 of the terminal units 7A to 7D may correspond to or be the same layer as the second insulating layer 94-2 of the bodies 86 and 87. For example, the first insulating layer 331 of the terminal units 7A to 7D may be polyimide, and the second insulating layer 332 thereof may be coverlay.

The thickness H1 of the second insulating layer 332 may be 10 micrometers to 50 micrometers. For example, H1 may be 30 micrometers to 40 micrometers. For example, H1 may be 35 micrometers to 37.5 micrometers. For example, H1 may be the sum of the thickness of the polyimide and the thickness of the adhesive.

Next, referring to FIGS. 29B and 30B, the second insulating layer 332 is selectively removed to expose the terminals 311 (or the pads) of the terminal units 7A to 7D.

In an example, the entire area AREA of the terminal units 7A to 7D may include a first area S11 in which the terminal (or the pad) is formed and a second area S12 connected to the first area S11.

In an example, the second area S12 may be disposed adjacent to the bodies 86 and 87. In an example, the second area S12 may be connected to the bodies 86 and 87. Alternatively, in an example, the second area S12 may connect the first area S11 to the bodies 86 and 87.

In an example, the second insulating layer 332 formed in the first area S11 may be selectively removed.

In an example, as the second insulating layer 332 is selectively removed, the conductive layer 311A, the terminals 311, and a portion of the first insulating layer 331 in the first area S11 may be exposed.

The first area S11 may be an area within a predetermined distance A4 from one end 531 of each of the terminal units 7A to 7D or one end of each of the terminals 311. In an example, A4 may be the length of the first area S11 in the vertical direction. In an example, the length of the first area S11 in the horizontal direction may be equal to or less than the length of the terminal units 7A to 7D in the horizontal direction.

For example, the length A1 of the terminals 311 (or the pads) in the horizontal direction may be 100 micrometers to 500 micrometers. Alternatively, for example, A1 may be 200 micrometers to 450 micrometers. Alternatively, for example, A1 may be 300 micrometers to 400 micrometers.

For example, the length A2 of the terminals 311 (or the pads) in the vertical direction may be 300 micrometers to 500 micrometers. Alternatively, for example, A2 may be 400 micrometers to 500 micrometers. Alternatively, for example, A2 may be 425 micrometers to 500 micrometers.

If A1 is less than 100 micrometers or if A2 is less than 300 micrometers, a soldering area may be excessively reduced, and thus the conductive connection characteristics obtained by performing soldering on the terminals 800B of the second board unit 800 may deteriorate. In addition, if A1 exceeds 500 micrometers or if A2 exceeds 500 micrometers, the length (or the area) of the terminal units 7A to 7D may excessively increase, leading to increase in the size of the camera module.

For example, the spacing distance A3 between two adjacent terminals may be 150 micrometers or more. For example, the spacing distance A3 between two adjacent terminals may be 150 micrometers to 450 micrometers. Alternatively, for example, A3 may be 150 micrometers to 350 micrometers. Alternatively, for example, A3 may be 150 micrometers to 200 micrometers.

If A3 is less than 150 micrometers, electrical short circuit may occur between two adjacent terminals during soldering. If A3 exceeds 450 micrometers, the gap between two adjacent terminals may increase, leading to increase in the size of the terminal units and resultant increase in the size of the camera module.

For example, the length A4 of the first area S11 in the vertical direction may be 400 micrometers to 600 micrometers. Alternatively, for example, A4 may be 500 micrometers to 600 micrometers. Alternatively, for example, A4 may be 525 micrometers to 600 micrometers.

In an example, in FIGS. 29B and 30B, because the second insulating layer 332 is selectively removed to expose the terminals 311, A4 may be greater than A2.

The shortest distance A5 between the terminals 311 (or the pads) at a boundary 521 between the first area S11 and the second area S12 may be 50 micrometers or more. For example, A5 may be 50 micrometers to 300 micrometers. Alternatively, for example, A5 may be 100 micrometers to 250 micrometers. Alternatively, for example, A5 may be 100 micrometers to 200 micrometers.

If A5 is less than 50 micrometers, it may be difficult to perform a process of patterning a third insulating layer 333, which will be described later. If A5 exceeds 300 micrometers, an area in which the third insulating layer 333 is formed may increase, leading to increase in cost.

In an example, the length A4 of the first area S11 in the vertical direction and the length A9 of the second area S12 in the vertical direction may be different from each other. In an example, A9 may be the length from the boundary 521 to the other end 532 of each of the terminal units 7A to 7D. In an example, the length A4 of the first area S11 in the vertical direction may be greater than the length A9 of the second area S12 in the vertical direction. In another embodiment, the length A4 of the first area S11 in the vertical direction may be less than or equal to the length A9 of the second area S12 in the vertical direction.

Next, referring to FIG. 30C, a third insulating layer 333 is formed on the first area S11 from which the second insulating layer 332 has been selectively removed. In an example, the third insulating layer 333 may be formed on the conductive layer 311A in the first area S11. The third insulating layer 333 may serve to electrically insulate the terminals 311 or to inhibit wear of the terminals 311.

In addition, the third insulating layer 333 may serve to inhibit lead from being attached to unnecessary parts during a soldering process and to inhibit the circuit patterns or the terminals formed at the terminal units 7A to 7D of the support board 310 from being directly exposed to air and thus oxidized or deteriorated by oxygen and moisture.

In an example, the third insulating layer 333 may be formed on the conductive layer 311A, the terminals 311, and a portion of the first insulating layer 331 in the first area S11. In an example, the third insulating layer may be formed on the entirety of the first area.

In an example, the third insulating layer 333 may include solder resist. For example, the third insulating layer 333 may be ink-type solder resist or film-type solder resist. In an example, the third insulating layer 333 may include photo solder resist (PSR) or dry-film-type solder resist (DFSR). In an example, the third insulating layer 333 may have matte properties. Alternatively, the third insulating layer 333 may be a transparent layer. Alternatively, the third insulating layer 333 may have glossy properties. In an example, the third insulating layer 333 may be an opaque layer.

The thickness H2 of the third insulating layer 333 may be 15 micrometers to 100 micrometers. For example, H2 may be 20 micrometers to 50 micrometers. Alternatively, for example, H2 may be 25 micrometers to 30 micrometers. In an example, H2 may be greater than H1.

Referring to FIG. 30C, a portion of the third insulating layer 333 may be formed on the second area S12. The reason for this is to consider a deviation or a margin in a process of selectively forming the third insulating layer 333 in the first area S11, thereby inhibiting occurrence of electrical short circuit due to exposure of the conductive layer 311A from the third insulating layer 333.

In an example, the third insulating layer 333 may include an area 333A that overlaps the second insulating layer 332 in the vertical direction. Here, the vertical direction may be a direction perpendicular to the terminal unit or a direction perpendicular to the upper surface of the terminal 311. Alternatively, in an example, the vertical direction may be a direction from the first insulating layer 331 toward the second insulating layer 332 (or the third insulating layer 333). Alternatively, in an example, the vertical direction may be a direction from the lower surface of the terminal units 7A and 7B toward the upper surface thereof. Alternatively, in an example, the vertical direction may be a direction perpendicular to the third insulating layer 333.

In an example, a portion of the third insulating layer 333 may be disposed on a portion of the second insulating layer 332 that is adjacent to the boundary 521 between the first area S11 and the second area S12.

Referring to FIG. 30E, in an example, the third insulating layer 333 may include a portion disposed in an area between the plurality of terminals 311. In an example, the third insulating layer 333 may include a portion disposed on a portion of the first insulating layer 331 that corresponds to an area between the plurality of terminals 311 in order to electrically insulate the plurality of terminals from each other. In an example, the third insulating layer 333 may include a portion disposed between two adjacent terminals 311 in order to electrically insulate the plurality of terminals 311 from each other.

In addition, in an example, referring to FIG. 30F, the third insulating layer 333 may include a groove 77B (or concave portion) depressed in the upper surface thereof so as to correspond to or oppose an area 77C between the plurality of terminals 311. In an example, when the third insulating layer 333 is formed, a portion of the insulating layer may be inserted into or placed in the space between the plurality of terminals, whereby the groove 77B may be formed.

In an example, the third insulating layer 333 may include an area 333A overlapping a portion of the second insulating layer 332 that is adjacent to the boundary 521 in the vertical direction. In this case, the overlapping area 333A may be disposed or located on the second insulating layer 332.

In an example, the length A7 of the overlapping area 333A in a direction from one end 531 of each of the terminal units 7A to 7D toward the other end 532 thereof may be less than A5. In another embodiment, A7 may be equal to or greater than A5.

In an example, A7 may be less than A10, which will be described later. In another embodiment, A7 may be equal to or greater than A10.

For example, the length A7 of the overlapping area 333A in a direction from one end 531 of each of the terminal units 7A to 7D toward the other end 532 thereof may be 50 micrometers or more. In another embodiment, A7 may be 50 micrometers to 200 micrometers. In still another embodiment, A7 may be 50 micrometers to 100 micrometers.

The length A6 of the third insulating layer 333 in the vertical direction may be 450 micrometers to 650 micrometers. For example, A6 may be the distance from one end 522 of the third insulating layer 333 to the other end 523 thereof. Alternatively, for example, A6 may be 550 micrometers to 650 micrometers. Alternatively, for example, A6 may be 575 micrometers to 650 micrometers.

For example, the value (A6/A2) obtained by dividing the length A6 of the third insulating layer 333 in the vertical direction by the length A2 of the terminals 311 in the vertical direction may be greater than 1 and less than or equal to 2.16. Alternatively, the divided value (A6/A2) may be greater than 1 and less than or equal to 2. Alternatively, the divided value (A6/A2) may be greater than or equal to 1.5 and less than or equal to 2. If the divided value (A6/A2) is less than or equal to 1, A6 may become less than A2, and thus the third insulating layer 333 may not sufficiently insulate the terminals 311, leading to occurrence of electrical short circuit between adjacent terminals during soldering. On the other hand, if the divided value (A6/A2) is greater than 2.16, the length of the terminals 311 in the vertical direction may be excessively reduced, leading to deterioration in soldering efficiency and deterioration in conductive connection characteristics.

In an example, when viewed from above (or when viewed from the front), the length A6 of the third insulating layer 333 in the vertical direction and the distance A10 from the other end 532 of each of the terminal units 7A to 7D to one end 522 of the third insulating layer 333 may be different from each other.

In an example, A10 may be the length of a portion of the second insulating layer 332 that does not overlap the third insulating layer 333 in the vertical direction. Alternatively, in an example, A10 may be the distance from the overlapping area 333A to the other end 532 of each of the terminal units 7A to 7D. In an example, A6 may be greater than A10. In another embodiment, A6 may be less than or equal to A10.

In another embodiment, the third insulating layer 333 may not overlap the second insulating layer 332.

Next, referring to FIGS. 29C and 30D, the third insulating layer 333 is selectively removed to expose the terminals 311 (or the pads). In an example, a bore 77A for exposing or opening at least a portion of each of the terminals 311 (or the pads) may be formed in the third insulating layer 333. In an example, the bore 77A may be formed corresponding to each of the plurality of terminals 311.

The third insulating layer 333 may be formed to surround the terminal 311 so that a portion of the surface (e.g., the upper surface) of the terminal 311 is exposed.

In an example, a portion of the third insulating layer 333 may be selectively removed through exposure, development, and etching processes to expose the terminal 311 (or the pad).

In an example, the bore 77A may expose a portion of the entire area of the upper surface (or the front surface) of the terminal 311 (or the pad). Accordingly, a portion of the third insulating layer 333 may be disposed or remain on the edge area of the terminal 311.

A portion of the third insulating layer 333 may be disposed on the terminal 311. In an example, a portion of the third insulating layer 333 may be disposed on the upper surface of the terminal 311. In an example, a portion of the third insulating layer 333 may be formed on the edge of the upper surface of the terminal 311 (or the pad). The reason for this is to consider a deviation or a margin in exposure, development, and etching processes for selectively removing the third insulating layer 333 in order to expose the upper surface of the terminal 311 (or the pad). If this process margin is not considered, a portion of the third insulating layer 333 that is located between two adjacent terminals 311 may be removed, which may cause electrical short circuit between the two adjacent terminals.

In an example, another portion of the third insulating layer 333 may overlap the terminal 311 (or the pad) in the vertical direction. In an example, the third insulating layer 333 may include an area 333B overlapping the upper surface of the terminal 311 (or the pad) in the vertical direction.

In an example, the overlapping area 333B of the third insulating layer 333 may be disposed on the upper surface (or the front surface) of the terminal 311 (or the pad). In an example, the overlapping area 333B of the third insulating layer 333 may be formed to have a predetermined line width A8 from the edge of the terminal 311.

The predetermined width A8 may be the width of a portion of the third insulating layer 333 that overlaps the terminal 311. A8 may be 25 micrometers to 50 micrometers.

In an example, A8 may be less than A1 and A2. In an example, A8 may be less than A3. In an example, A8 may be less than or equal to A7. If A8 is greater than A7, the exposed area of the terminal may decrease and thus the soldering area may excessively decrease, leading to deterioration in characteristics of conductive connection to the terminal 800B of the second board unit 800.

In FIGS. 29A to 29C, the terminal 311 may include a portion that is reduced in width in a direction from one end 531 of each of the terminal units 7A to 7D toward the other end 532 thereof. In an example, the terminal 311 may include a first portion 79A and a second portion 79B. The first portion 79A may be adjacent to one end 531 of each of the terminal units 7A to 7D (or an end 523 of the third insulating layer 333), and the second portion 79B may be connected to the first portion 79A and may be adjacent to the other end 532 of each of the terminal units 7A to 7D (or another end 522 of the third insulating layer 333).

In an example, the width of the second portion 79B may gradually decrease in a direction from the first portion 79A toward the second portion 79B. In an example, an end of the second portion 79B may include a sharp apex 66.

For example, when viewed from above or from the front, the terminal 311 may have a pentagonal shape.

In an example, the width of the second portion 79B may be less than the width of the first portion 79A. In this case, the width of the second portion 79B may be the length of the second portion 79B in a direction perpendicular to the direction from one end 531 of each of the terminal units 7A to 7D toward the other end 532 thereof. In an example, the width may be the length of the terminal in the horizontal direction. Here, the horizontal direction may be a direction in which the terminals are arranged in a row. Alternatively, the horizontal direction may be a direction parallel to the long side of the terminal unit.

In an example, the length of the first portion 79A in the direction from one end 531 of each of the terminal units 7A to 7D toward the other end 532 thereof may be greater than the length of the second portion 79B in the direction from one end 531 of each of the terminal units 7A to 7D toward the other end 532 thereof. In another embodiment, the length of the first portion 79A and the length of the second portion 79B may be equal to each other.

Referring to FIG. 29C, a boundary 66A may be formed between the third insulating layer 333 and the terminal 311. The boundary 66A may have the same shape as the terminal, for example, a pentagonal shape. The boundary 66A may be the boundary between the overlapping area 333B of the third insulating layer 333 and the upper surface of the terminal 311.

As a comparative example, an insulating layer that opens a terminal (or pad) of a terminal unit of a support board may be formed as follows. First, a coverlay sheet may be patterned through molding processing or laser processing to form a bore for opening or exposing the terminal (or the pad) of the terminal unit, and the coverlay sheet having the bore formed therein may be stacked on or attached to the terminal unit including the terminal.

In the comparative example, when the coverlay sheet having the bore formed therein is attached to the terminal unit, mismatch may occur between the bore in the coverlay and the terminal, which may cause eccentricity therebetween.

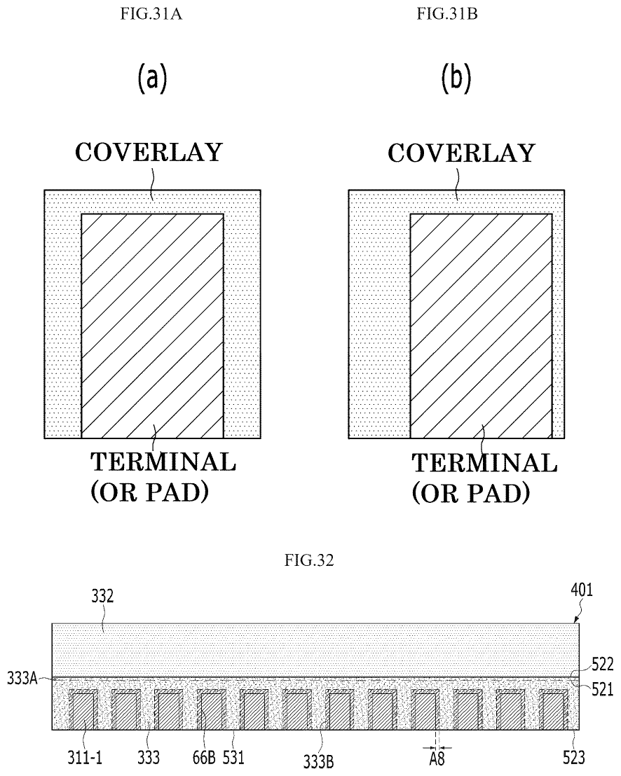

FIGS. 31A and 31B show a case in which the coverlay sheet is normally attached and a case in which eccentricity occurs. FIG. 31A shows a case in which the coverlay sheet is normally attached, and FIG. 31B shows a case in which eccentricity occurs.

Referring to FIGS. 31A and 31B, if the coverlay sheet is attached abnormally and thus eccentricity occurs, insulation and protection performance for the terminal may deteriorate. In addition, due to eccentricity, positions for soldering between the terminal of the support board and the terminal of the second board unit may be misaligned, leading to deterioration in soldering efficiency and deterioration in conductive connection characteristics.

In the comparative example, when the coverlay sheet is attached to the terminal unit, resin may leak to the terminal through the bore in the coverlay sheet, a soldering area of the terminal may be reduced due to the leaked resin, and a solder application area may be reduced. Such reduction in soldering area may deteriorate soldering efficiency and conductive connection characteristics.

In the embodiment, as described with reference to FIGS. 29A to 29C, after the second insulating layer 332 (e.g., coverlay) formed on the first area S11 of the terminal units 7A to 7D for formation of the terminal 311 is removed, the third insulating layer 333 (e.g., PSR or DFSR) is formed in the first area S11. Subsequently, a portion of the third insulating layer 333 may be selectively removed through a selective etching process to form a bore for exposing the terminal 311.

Therefore, unlike the comparative example, the embodiment inhibits reduction in the soldering area of the terminal due to leakage of resin.

In addition, in the embodiment, since solder resist is used for the third insulating layer 333 and a bore for exposing the terminal 311 is formed through exposure, development, and etching processes, precise patterning for formation of the bore is possible. Accordingly, in the embodiment, a processing tolerance (or process margin) for forming the bore may be reduced, and the size of an open area of the terminal 311 may be accurately patterned so that the terminal 311 has a soldering area according to design specifications. Here, the open area refers to an area that is open in the third insulating layer 333.

In addition, in the embodiment, eccentricity due to mismatch between the terminal of the support board and the bore may be inhibited, and deterioration in insulation and protection performance caused by the eccentricity may be inhibited. In addition, in the embodiment, misalignment between positions for soldering between the terminal of the support board and the terminal of the second board unit may be inhibited, and thus soldering efficiency and conductive connection characteristics may be improved.

For example, the processing tolerance (or process margin) of the coverlay may be about 100 micrometers, and the processing tolerance (or process margin) of the solder resist may be about 50 micrometers. That is, the embodiment may reduce the processing tolerance to about half compared to the comparative example.

FIG. 32 shows a modified example of FIG. 29C.

Referring to FIG. 32, when viewed from above or from the front, the terminals 311-1 of the terminal units 7A to 7D may have a polygonal shape, for example, a quadrangular shape. In addition, a first boundary 66B may be formed between the third insulating layer 333 and the terminal 311-1. In this case, the first boundary 66B may have the same shape as the terminal 311-1, for example, a quadrangular shape. For example, the first boundary 66B may have a rectangular or square shape. The description of A1 to A10 given with reference to FIGS. 29A to 29C may be equally or similarly applied to the modified example in FIG. 32.

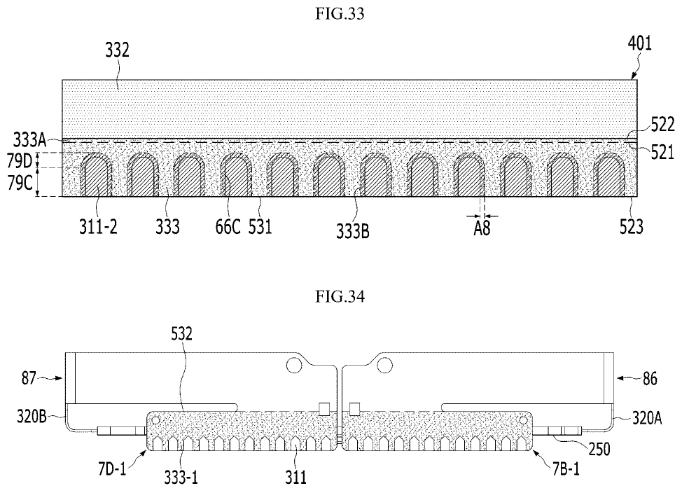

FIG. 33 shows a support board 310 according to still another modified example of FIG. 29C.

Referring to FIG. 33, when viewed from above or from the front, the terminals 311-2 of the terminal units 7A to 7D may include at least one of a round shape, an arc shape, a semicircular shape, or a wave shape.

In an example, the terminal 311-2 may include a first portion 79C and a second portion 79D. The first portion 79C may be adjacent to one end 531 of each of the terminal units 7A to 7D (or an end 523 of the third insulating layer 333), and the second portion 79D may be connected to the first portion 79C and may be adjacent to the other end 532 of each of the terminal units 7A to 7D (or another end 522 of the third insulating layer 333).

For example, when viewed from above or from the front, the second portion 79D of the terminal 311-2 may have a round shape, an arc shape, a semicircular shape, or a wave shape.

In addition, a second boundary 66C may be formed between the third insulating layer 333 and the terminal 311-2. In this case, the second boundary 66C may have the same shape as the terminal 311-2. The description of A1 to A10 given with reference to FIGS. 29A to 29C may be equally or similarly applied to the modified example in FIG. 33.

FIG. 34 shows terminal units (e.g., 7D-1 and 7B-1) according to another embodiment. Hereinafter, for convenience of description, one terminal unit (e.g., 7D-1) will be described, and the description of the terminal unit may be equally or similarly applied to the other terminal units.

FIG. 34 shows a modified example of the third insulating layer 333 in FIG. 29C, and the third insulating layer 333-1 in FIG. 34 may be formed in the entire area of the terminal units 7D-1 and 7B-1.

In an example, as described with reference to FIG. 27, the bodies 86 and 87 of the support board 310 may include a conductive layer 93-1, a first insulating layer 94-1 (e.g., polyimide) disposed beneath the conductive layer 93-1, and a second insulating layer 94-2 (e.g., coverlay) disposed on the conductive layer 93-1.

In an example, the third insulating layer 333-1 may be formed in place of the second insulating layer 332 in the entire area of the terminal units 7D-1 and 7B-1 except for the bodies 86 and 87 of the support board 310.

As described above, in the embodiment, the support board 310 may be formed as a flexible substrate, and solder resist may be formed instead of coverlay on a portion or the entirety of the terminal units 7A to 7D of the support board 310 in order to insulate the terminals 311 of the terminal units 7A to 7D. Accordingly, eccentricity due to mismatch between the terminal and the bore may be inhibited, and deterioration in insulation and protection performance caused by the eccentricity may be inhibited. In addition, in the embodiment, misalignment between positions for soldering between the terminal 311 of the support board 310 and the terminal 800B of the second board unit 800 may be inhibited, and thus soldering efficiency and conductive connection characteristics may be improved.

In addition, in the embodiment, since the bore in the third insulating layer 333 that matches the terminal 311 is formed through exposure, development, and etching, it is possible to inhibit reduction in the soldering area of the terminal due to leakage of resin of coverlay, thereby improving soldering efficiency and conductive connection characteristics.

In addition, the camera device according to the embodiment may be included in an optical instrument for the purpose of forming an image of an object present in a space using reflection, refraction, absorption, interference, and diffraction, which are characteristics of light, for the purpose of increasing visibility, for the purpose of recording and reproduction of an image using a lens, or for the purpose of optical measurement or image propagation or transmission. For example, the optical instrument according to the embodiment may be a cellular phone, a mobile phone, a smartphone, a portable smart device, a digital camera, a laptop computer, a digital broadcasting terminal, a personal digital assistant (PDA), a portable multimedia player (PMP), a navigation device, etc., without being limited thereto, and may also be any of devices for capturing images or pictures.

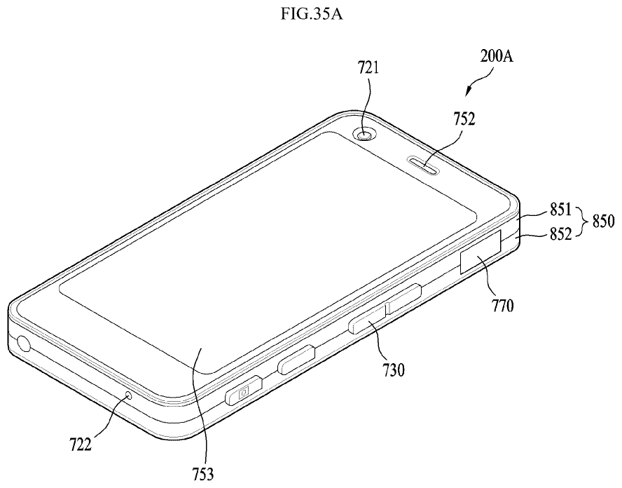

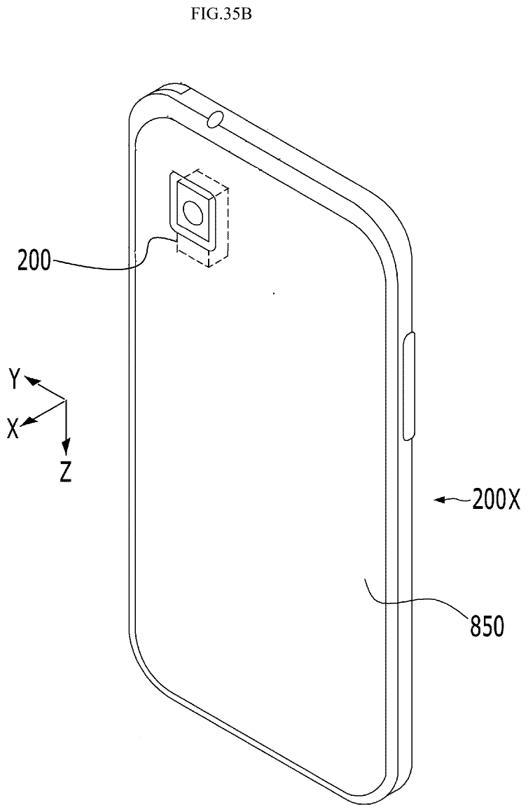

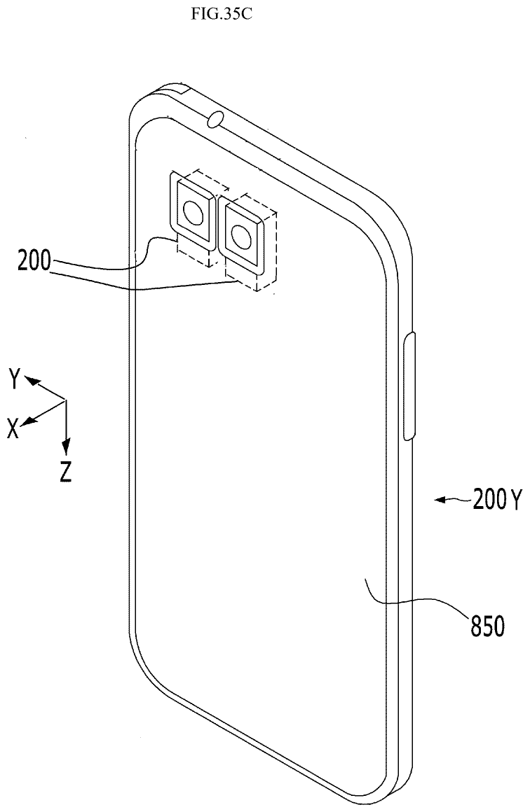

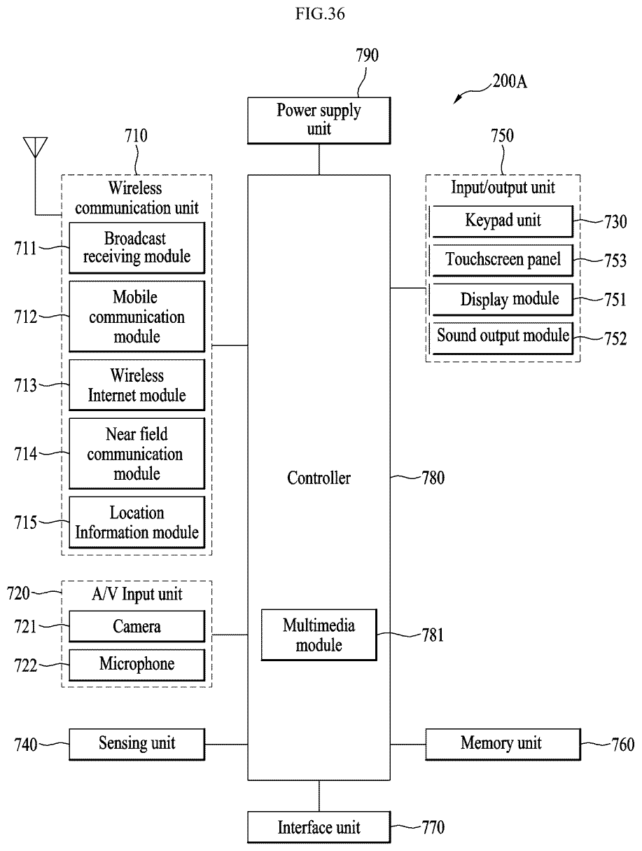

FIG. 35A is a perspective view of an optical instrument 200A according to an embodiment, FIG. 35B is a perspective view of an optical instrument 200X according to another embodiment, FIG. 35C is a perspective view of an optical instrument 200Y according to still another embodiment, and FIG. 36 is a configuration diagram of the optical instruments 200A, 200X, and 200Y shown in FIGS. 35A to 35C.

For example, the embodiment in FIG. 35A may be a front-view camera of the optical instrument 200A in which the lens module 400 of the camera module 200 is disposed so as to face the front surface of the body 850, and the optical instrument 200X according to the embodiment in FIG. 35B may be a rear-view camera in which the lens module 400 of the camera module 200 is disposed so as to face the rear surface of the body 850 of the optical instrument 200X. In addition, the optical instrument 200Y according to the embodiment in FIG. 35C may be an example in which two rear-view cameras are disposed. An optical instrument according to still another embodiment may include three or more rear-view cameras. An optical instrument according to still another embodiment may include a front-view camera and a rear-view camera, and at least one of the front-view camera or the rear-view camera may include the camera module 200.

Referring to FIGS. 35A to 35C and 36, the optical instrument 200A may include a body 850, a wireless communication unit 710, an A/V input unit 720, a sensing unit 740, an input/output unit 750, a memory unit 760, an interface unit 770, a controller 780, and a power supply unit 790.

The body 850 shown in FIGS. 35A to 35C may have a bar shape, without being limited thereto, and may be any of various types such as, for example, a slide type, a folder type, a swing type, or a swivel type, in which two or more sub-bodies are coupled so as to be movable relative to each other.

The body 850 may include a case (a casing, a housing, a cover, or the like) defining the external appearance thereof. In an example, the body 850 may be divided into a front case 851 and a rear case 852. A variety of electronic components of the terminal may be mounted in the space defined between the front case 851 and the rear case 852.

The wireless communication unit 710 may include one or more modules that enable wireless communication between the optical instrument 200A and a wireless communication system or between the optical instrument 200A and a network in which the optical instrument 200A is located. In an example, the wireless communication unit 710 may include a broadcast receiving module 711, a mobile communication module 712, a wireless Internet module 713, a nearfield communication module 714, and a location information module 715.

The audio/video (A/V) input unit 720 serves to input audio signals or video signals and may include a camera 721 and a microphone 722.

The camera 721 may include the camera device according to the embodiment.

The sensing unit 740 may sense the current state of the optical instrument 200A, such as the open or closed state of the optical instrument 200A, the position of the optical instrument 200A, the presence or absence of a user's touch, the orientation of the optical instrument 200A, or the acceleration/deceleration of the optical instrument 200A, and may generate a sensing signal to control the operation of the optical instrument 200A. For example, when the optical instrument 200A is a slide-type phone, whether the slide-type phone is open or closed may be detected. In addition, the sensing unit 740 serves to sense whether power is supplied from the power supply unit 790 or whether the interface unit 770 is coupled to an external device.

The input/output unit 750 serves to generate visual, audible, or tactile input or output. The input/output unit 750 may generate input data to control the operation of the optical instrument 200A and may display information processed in the optical instrument 200A.

The input/output unit 750 may include a keypad unit 730, a display module 751, a sound output module 752, and a touchscreen panel 753. The keypad unit 730 may generate input data in response to input to a keypad.

The display module 751 may include a plurality of pixels, the color of which varies in response to electrical signals. In an example, the display module 751 may include at least one of a liquid crystal display, a thin-film transistor liquid crystal display, an organic light-emitting diode, a flexible display, or a 3D display.

The sound output module 752 may output audio data received from the wireless communication unit 710 in a call-signal reception mode, a call mode, a recording mode, a voice recognition mode, or a broadcast reception mode, or may output audio data stored in the memory unit 760.

The touchscreen panel 753 may convert variation in capacitance, caused by a user's touch on a specific region of a touchscreen, into electrical input signals.

The memory unit 760 may store programs for the processing and control of the controller 780, and may temporarily store input/output data (e.g., a phone book, messages, audio, still images, pictures, and moving images). For example, the memory unit 760 may store images captured by the camera 721, for example, pictures or moving images. For example, the memory unit 760 may store software, an algorithm, or an equation for implementation of hand-tremor compensation described above.

The interface unit 770 serves as a passage for connection between the optical instrument 200A and an external device. The interface unit 770 may receive data or power from the external device and may transmit the same to respective components provided in the optical instrument 200A, or may transmit data inside the optical instrument 200A to the external device. For example, the interface unit 770 may include a wired/wireless headset port, an external charger port, a wired/wireless data port, a memory card port, a port for connection of a device having an identification module, an audio input/output (I/O) port, a video input/output (I/O) port, and an earphone port.

The controller 780 may control the overall operation of the optical instrument 200A. For example, the controller 780 may perform control and processing related to voice calls, data communication, and video calls.

The controller 780 may include a multimedia module 781 for multimedia playback. The multimedia module 781 may be provided in the controller 180 or may be provided separately from the controller 780.

The controller 780 may perform pattern recognition processing, by which writing or drawing input to the touchscreen is perceived as characters and images.

The power supply unit 790 may supply power required to operate the respective components upon receiving external power or internal power under the control of the controller 780.

The features, structures, effects, and the like described above in the embodiments are included in at least one embodiment of the present disclosure, but are not necessarily limited to only one embodiment. Furthermore, the features, structures, effects, and the like exemplified in the respective embodiments may be combined with other embodiments or modified by those skilled in the art. Therefore, content related to such combinations and modifications should be construed as falling within the scope of the present disclosure.

### INDUSTRIAL APPLICABILITY

Embodiments may be used for a camera device capable of inhibiting deterioration in quality of an image of an image sensor, which is caused by heat generated from a heat source, and an optical instrument.

1. A camera device comprising:
a cover member;
a moving unit disposed inside the cover member and comprising a first board and an image sensor disposed on the first board;
a fixed unit comprising a second board spaced apart from the first board;
a support board configured to support the moving unit so that the moving unit moves relative to the fixed unit in a direction perpendicular to an optical-axis direction and to conductively connect the first board to the second board; and
a controller disposed outside the cover member.

2. The camera device according to claim 1, wherein the controller is disposed on the second board.

3. The camera device according to claim 1, wherein the controller does not overlap the cover member in the optical-axis direction.

4. The camera device according to claim 1, wherein the second board comprises an extension region not overlapping the cover member in the optical-axis direction, and
wherein the controller is disposed on the extension region.

5. The camera device according to claim 1, wherein the second board comprises:
a first region corresponding to the cover member in the optical-axis direction;
a second region on which a connector is disposed;
a third region connecting the first region to the second region; and
an extension region extending from the first region, and
wherein the controller is disposed on an upper surface of the extension region.

6. The camera device according to claim 5, wherein the extension region extends from a first side portion of the first region, and
wherein the third region connects the first side portion of the first region to the second region.

7. The camera device according to claim 5, wherein the extension region extends from a first side portion of the first region, and
wherein the third region extends from the first side portion of the first region and is spaced apart from the extension region.

8. The camera device according to claim 5, comprising a cover disposed on the extension region to accommodate the controller.

9. The camera device according to claim 5, comprising a heat dissipation member provided in contact with the extension region.

10. The camera device according to claim 9, wherein the heat dissipation member is disposed on a lower surface of the extension region.

11. The camera device according to claim 5, comprising a heat dissipation layer disposed on at least one of an upper surface or a side surface of the controller.

12. The camera device according to claim 11, wherein the heat dissipation layer is formed of heat dissipation epoxy.

13. The camera device according to claim 1, comprising:
a coil conductively connected to the first board; and
a position sensor disposed on the first board and configured to detect movement or displacement of the moving unit, and
wherein the controller is conductively connected to the coil and the position sensor.

14. The camera device according to claim 13, comprising a magnet disposed on the fixed unit so as to oppose the coil and configured to move the moving unit in a direction perpendicular to the optical axis through interaction with the coil.

15. The camera device according to claim 14, wherein the second board comprises a first terminal, a second terminal, a first wire conductively connecting the first terminal to the controller, and a second wire conductively connecting the second terminal to the control, and
wherein the support board comprises a third terminal conductively connected to the first terminal and a fourth terminal conductively connected to the second terminal.

16. The camera device according to claim 15, wherein the second board comprises a third wire conductively connecting the third terminal to the coil and a fourth wire conductively connecting the fourth terminal to the position sensor.

17. The camera device according to claim 16, wherein a line width of the first wire is greater than a line width of the second wire and,
wherein a line width of the third wire is greater than a line width of the fourth wire.

18. The camera device according to claim 1, wherein the second board comprises a first region corresponding to the cover member in the optical-axis direction, a second region in which a connector is disposed, and a third region connecting the first region to the second region, and
wherein the controller may be disposed in the second region.

19. A camera device comprising:
a moving unit disposed inside the cover member and comprising a first board and an image sensor disposed on the first board;
a fixed unit comprising a second board spaced apart from the first board;
a support board configured to support and conductively connect the first board to the second board; and
a controller disposed on the second board and configured to move the moving unit relative to the fixed unit in a direction perpendicular to an optical-axis direction, and
wherein the controller does not overlap the cover member in the optical-axis direction.

20. An optical instrument comprising the camera module according to claim 1.
